(19) United States
(12) Patent Application Publication
(10) Pub. No.: US 2025/0373156 A1
(43) Pub. Date: Dec. 4, 2025

(54) METHODS OF PROVIDING MULTI-LEVEL AMPLIFICATION AND DEVICES AND SYSTEMS THEREFOR

(71) Applicant: Meta Platforms Technologies, LLC, Menlo Park, CA (US)

(72) Inventors: Chai Yong Lim, Santa Clara, CA (US); David Breece III, Houston, TX (US); Daniel Villamizar, Woodinville, WA (US)

(21) Appl. No.: 19/227,387

(22) Filed: Jun. 3, 2025

Related U.S. Application Data
(60) Provisional application No. 63/655,592, filed on Jun. 3, 2024.

(51) Int. Cl. H02M 3/155; H03F 3/183

(52) U.S. Cl. CPC H02M 3/155; H03F 3/183

(57) ABSTRACT

A circuit comprises a first half-bridge power stage including a first set of switches and a second half-bridge power stage including a second set of switches. The circuit further comprises a first power source and a second power source that are coupled to the first and second half-bridge power stages for supplying a first direct current (DC) voltage and a second DC voltage, respectively. The circuit further comprises an output interface coupled to the first and second half-bridge power stages and configured to couple to a speaker load. The first and second half-bridge power stages are configured to generate a five-level differential signal for driving the speaker load. Each set of switches includes a respective first subset of switches configured to operate at a first voltage level and a respective second subset of switches configured to operate at a second voltage level.

### PRIORITY AND RELATED APPLICATIONS

This application claims priority to U.S. Provisional Application Ser. No. 63/655,592, filed Jun. 3, 2024, entitled “Multilevel Class D Amplifier,” which is incorporated herein by reference.

### TECHNICAL FIELD

This relates generally to methods, devices, and systems for providing multi-level amplification, including but not limited to methods, devices, and systems providing class D multi-level amplification.

### BACKGROUND

Extending battery life is critical to hardware products, especially smart glasses and augmented reality (AR) products. Multi-level amplification can improve battery life in audio-centric use cases like music playback and phone calls, as well as with conversation focus and hearing enhancement. Conventional multi-level speaker amplifier topologies require a large total solution size (e.g., more external components), suffer from high voltage swings during dead time in between certain switching states, and/or require large transistor area to implement in silicon.

As such, there is a need to address one or more of the above-identified challenges. A brief summary of solutions to the issues noted above are described below.

### SUMMARY

The methods, circuits, devices and systems described herein address at least some of the limitations described above. Some embodiments include a multi-level (e.g., five-level, seven-level) amplifier with a smaller silicon area and/or fewer external components than conventional multi-level designs. For example, multi-level (five-level or higher) amplifiers can offer improved efficiency (e.g., lower power consumption and longer battery life) over two- and three-level amplifiers. For example, seven-level amplifiers enable usage of a higher voltage rail for “smoothing” power consumption from the battery and/or offering higher output without sacrificing efficiency when running from the regular battery rail (e.g., PVDD).

An example circuit described herein is configured as a multi-level class D amplifier (e.g., a five-level class D amplifier). In this example, the circuit comprises a first half-bridge power stage including a first set of switches. The circuit further comprises a second half-bridge power stage including a second set of switches. The circuit further comprises a first power source coupled to the first and second half-bridge power stages and configured to supply a first direct current (DC) voltage. The circuit further comprises a second power source coupled to the first and second half-bridge power stages and configured to supply a second DC voltage. The circuit further comprises an output interface coupled to the first and second half-bridge power stages and configured to couple to a speaker load. The first and second half-bridge power stages are configured to generate a five-level differential signal for driving the speaker load. Each set of the first set of switches and the second set of switches includes (i) a respective first subset of switches configured to operate at a first voltage level corresponding to the first DC voltage and (ii) a respective second subset of switches configured to operate at a second voltage level corresponding to the second DC voltage.

The circuits, devices, and/or systems described herein can be configured to include instructions that cause the performance of methods and operations associated with the presentation and/or interaction with an extended-reality (XR) headset. These methods and operations can be stored on a non-transitory computer-readable storage medium of a device or a system. It is also noted that the devices and systems described herein can be part of a larger, overarching system that includes multiple devices. A non-exhaustive of list of electronic devices that can, either alone or in combination (e.g., a system), include instructions that cause the performance of methods and operations associated with the presentation and/or interaction with an XR experience include an extended-reality headset (e.g., a mixed-reality (MR) headset or a pair of augmented-reality (AR) glasses as two examples), a wrist-wearable device, an intermediary processing device, a smart textile-based garment, etc. For example, when an XR headset is described, it is understood that the XR headset can be in communication with one or more other devices (e.g., a wrist-wearable device, a server, intermediary processing device) which together can include instructions for performing methods and operations associated with the presentation and/or interaction with an extended-reality system (i.e., the XR headset would be part of a system that includes one or more additional devices). Multiple combinations with different related devices are envisioned, but not recited for brevity.

The features and advantages described in the specification are not necessarily all inclusive and, in particular, certain additional features and advantages will be apparent to one of ordinary skill in the art in view of the drawings, specification, and claims. Moreover, it should be noted that the language used in the specification has been principally selected for readability and instructional purposes.

Having summarized the above example aspects, a brief description of the drawings will now be presented.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIG. 1 illustrates an example multi-level amplification circuit, in accordance with some embodiments.

FIGS. 2A-2I illustrate example operating states of the circuit of FIG. 1, in accordance with some embodiments.

FIG. 3 illustrates an example transient state that occurs during a transition between voltage levels of the circuit of FIG. 1, in accordance with some embodiments.

FIG. 4 illustrates example output signals generated by different amplifier topologies, in accordance with some embodiments.

FIG. 5 illustrates another example multi-level amplification circuit, in accordance with some embodiments.

FIGS. 6A and 6B illustrate example multi-level amplification circuits in which a power source is configured as a boosted rail, in accordance with some embodiments.

FIGS. 7A-7G illustrate example operating states of the circuit of FIG. 5, in accordance with some embodiments.

FIG. 8 illustrates another example multi-level amplification circuit, in accordance with some embodiments.

FIG. 9 illustrates an example multi-level amplification circuit in which a power source is configured as a boosted rail, in accordance with some embodiments.

FIGS. 10A-10C illustrate example outputs generated by the circuit of FIG. 5, in accordance with some embodiments.

FIG. 11 illustrates other example outputs generated by the circuit of FIG. 5, in accordance with some embodiments.

FIG. 12 illustrates a flow diagram of an example method of operating a multi-level amplification circuit, in accordance with some embodiments.

FIG. 13 illustrates a flow diagram of another example method of operating a multi-level amplification circuit, in accordance with some embodiments.

FIGS. 14A, 14B, 14C-1, and 14C-2 illustrate example MR and AR systems, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method, or device. Finally, like reference numerals may be used to denote like features throughout the specification and figures.

### DETAILED DESCRIPTION

Numerous details are described herein to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not necessarily been described in exhaustive detail so as to avoid obscuring pertinent aspects of the embodiments described herein.

### Overview

Embodiments of this disclosure can include or be implemented in conjunction with various types of extended-realities (XRs) such as mixed-reality (MR) and augmented-reality (AR) systems. MRs and ARs, as described herein, are any superimposed functionality and/or sensory-detectable presentation provided by MR and AR systems within a user's physical surroundings. Such MRs can include and/or represent virtual realities (VRs) and VRs in which at least some aspects of the surrounding environment are reconstructed within the virtual environment (e.g., displaying virtual reconstructions of physical objects in a physical environment to avoid the user colliding with the physical objects in a surrounding physical environment). In the case of MRs, the surrounding environment that is presented through a display is captured via one or more sensors configured to capture the surrounding environment (e.g., a camera sensor, time-of-flight (ToF) sensor). While a wearer of an MR headset can see the surrounding environment in full detail, they are seeing a reconstruction of the environment reproduced using data from the one or more sensors (i.e., the physical objects are not directly viewed by the user). An MR headset can also forgo displaying reconstructions of objects in the physical environment, thereby providing a user with an entirely VR experience. An AR system, on the other hand, provides an experience in which information is provided, e.g., through the use of a waveguide, in conjunction with the direct viewing of at least some of the surrounding environment through a transparent or semi-transparent waveguide(s) and/or lens(es) of the AR glasses. Throughout this application, the term “extended reality (XR)” is used as a catchall term to cover both ARs and MRs. In addition, this application also uses, at times, a head-wearable device or headset device as a catchall term that covers XR headsets such as AR glasses and MR headsets.

As alluded to above, an MR environment, as described herein, can include, but is not limited to, non-immersive, semi-immersive, and fully immersive VR environments. As also alluded to above, AR environments can include marker-based AR environments, markerless AR environments, location-based AR environments, and projection-based AR environments. The above descriptions are not exhaustive and any other environment that allows for intentional environmental lighting to pass through to the user would fall within the scope of an AR, and any other environment that does not allow for intentional environmental lighting to pass through to the user would fall within the scope of an MR.

The AR and MR content can include video, audio, haptic events, sensory events, or some combination thereof, any of which can be presented in a single channel or in multiple channels (such as stereo video that produces a three-dimensional effect to a viewer). Additionally, AR and MR can also be associated with applications, products, accessories, services, or some combination thereof, which are used, for example, to create content in an AR or MR environment and/or are otherwise used in (e.g., to perform activities in) AR and MR environments.

Interacting with these AR and MR environments described herein can occur using multiple different modalities and the resulting outputs can also occur across multiple different modalities. In one example AR or MR system, a user can perform a swiping in-air hand gesture to cause a song to be skipped by a song-providing application programming interface (API) providing playback at, for example, a home speaker.

A hand gesture, as described herein, can include an in-air gesture, a surface-contact gesture, and or other gestures that can be detected and determined based on movements of a single hand (e.g., a one-handed gesture performed with a user's hand that is detected by one or more sensors of a wearable device (e.g., electromyography (EMG) and/or inertial measurement units (IMUs) of a wrist-wearable device, and/or one or more sensors included in a smart textile wearable device) and/or detected via image data captured by an imaging device of a wearable device (e.g., a camera of a head-wearable device, an external tracking camera setup in the surrounding environment)). “In-air” generally includes gestures in which the user's hand does not contact a surface, object, or portion of an electronic device (e.g., a head-wearable device or other communicatively coupled device, such as the wrist-wearable device), in other words the gesture is performed in open air in 3D space and without contacting a surface, an object, or an electronic device. Surface-contact gestures (contacts at a surface, object, body part of the user, or electronic device) more generally are also contemplated in which a contact (or an intention to contact) is detected at a surface (e.g., a single- or double-finger tap on a table, on a user's hand or another finger, on the user's leg, a couch, a steering wheel). The different hand gestures disclosed herein can be detected using image data and/or sensor data (e.g., neuromuscular signals sensed by one or more biopotential sensors (e.g., EMG sensors) or other types of data from other sensors, such as proximity sensors, ToF sensors, sensors of an IMU, capacitive sensors, strain sensors) detected by a wearable device worn by the user and/or other electronic devices in the user's possession (e.g., smartphones, laptops, imaging devices, intermediary devices, and/or other devices described herein).

The input modalities as alluded to above can be varied and are dependent on a user's experience. For example, in an interaction in which a wrist-wearable device is used, a user can provide inputs using in-air or surface-contact gestures that are detected using neuromuscular signal sensors of the wrist-wearable device. In the event that a wrist-wearable device is not used, alternative and entirely interchangeable input modalities can be used instead, such as camera(s) located on the headset/glasses or elsewhere to detect in-air or surface-contact gestures or inputs at an intermediary processing device (e.g., through physical input components (e.g., buttons and trackpads)). These different input modalities can be interchanged based on both desired user experiences, portability, and/or a feature set of the product (e.g., a low-cost product may not include hand-tracking cameras).

While the inputs are varied, the resulting outputs stemming from the inputs are also varied. For example, an in-air gesture input detected by a camera of a head-wearable device can cause an output to occur at a head-wearable device or control another electronic device different from the head-wearable device. In another example, an input detected using data from a neuromuscular signal sensor can also cause an output to occur at a head-wearable device or control another electronic device different from the head-wearable device. While only a couple examples are described above, one skilled in the art would understand that different input modalities are interchangeable along with different output modalities in response to the inputs.

Specific operations described above may occur as a result of specific hardware. The devices described are not limiting and features on these devices can be removed or additional features can be added to these devices. The different devices can include one or more analogous hardware components. For brevity, analogous devices and components are described herein. Any differences in the devices and components are described below in their respective sections.

As described herein, a processor (e.g., a central processing unit (CPU) or microcontroller unit (MCU)), is an electronic component that is responsible for executing instructions and controlling the operation of an electronic device (e.g., a wrist-wearable device, a head-wearable device, a handheld intermediary processing device (HIPD), a smart textile-based garment, or other computer system). There are various types of processors that may be used interchangeably or specifically required by embodiments described herein. For example, a processor may be (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) a graphics processing unit (GPU) designed to accelerate the creation and rendering of images, videos, and animations (e.g., VR animations, such as three-dimensional modeling); (iv) a field-programmable gate array (FPGA) that can be programmed and reconfigured after manufacturing and/or customized to perform specific tasks, such as signal processing, cryptography, and machine learning; or (v) a digital signal processor (DSP) designed to perform mathematical operations on signals such as audio, video, and radio waves. One of skill in the art will understand that one or more processors of one or more electronic devices may be used in various embodiments described herein.

As described herein, controllers are electronic components that manage and coordinate the operation of other components within an electronic device (e.g., controlling inputs, processing data, and/or generating outputs). Examples of controllers can include (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; (iii) system-on-a-chip (SoC) controllers that integrate multiple components such as processors, memory, I/O interfaces, and other peripherals into a single chip; and/or (iv) DSPs. As described herein, a graphics module is a component or software module that is designed to handle graphical operations and/or processes and can include a hardware module and/or a software module.

As described herein, memory refers to electronic components in a computer or electronic device that store data and instructions for the processor to access and manipulate. The devices described herein can include volatile and non-volatile memory. Examples of memory can include (i) random access memory (RAM), such as DRAM, SRAM, DDR RAM or other random access solid state memory devices, configured to store data and instructions temporarily; (ii) read-only memory (ROM) configured to store data and instructions permanently (e.g., one or more portions of system firmware and/or boot loaders); (iii) flash memory, magnetic disk storage devices, optical disk storage devices, other non-volatile solid state storage devices, which can be configured to store data in electronic devices (e.g., universal serial bus (USB) drives, memory cards, and/or solid-state drives (SSDs)); and (iv) cache memory configured to temporarily store frequently accessed data and instructions. Memory, as described herein, can include structured data (e.g., SQL databases, MongoDB databases, GraphQL data, or JSON data). Other examples of memory can include (i) profile data, including user account data, user settings, and/or other user data stored by the user; (ii) sensor data detected and/or otherwise obtained by one or more sensors; (iii) media content data including stored image data, audio data, documents, and the like; (iv) application data, which can include data collected and/or otherwise obtained and stored during use of an application; and/or (v) any other types of data described herein.

As described herein, a power system of an electronic device is configured to convert incoming electrical power into a form that can be used to operate the device. A power system can include various components, including (i) a power source, which can be an alternating current (AC) adapter or a direct current (DC) adapter power supply; (ii) a charger input that can be configured to use a wired and/or wireless connection (which may be part of a peripheral interface, such as a USB, micro-USB interface, near-field magnetic coupling, magnetic inductive and magnetic resonance charging, and/or radio frequency (RF) charging); (iii) a power-management integrated circuit, configured to distribute power to various components of the device and ensure that the device operates within safe limits (e.g., regulating voltage, controlling current flow, and/or managing heat dissipation); and/or (iv) a battery configured to store power to provide usable power to components of one or more electronic devices.

As described herein, peripheral interfaces are electronic components (e.g., of electronic devices) that allow electronic devices to communicate with other devices or peripherals and can provide a means for input and output of data and signals. Examples of peripheral interfaces can include (i) USB and/or micro-USB interfaces configured for connecting devices to an electronic device; (ii) Bluetooth interfaces configured to allow devices to communicate with each other, including Bluetooth low energy (BLE); (iii) near-field communication (NFC) interfaces configured to be short-range wireless interfaces for operations such as access control; (iv) pogo pins, which may be small, spring-loaded pins configured to provide a charging interface; (v) wireless charging interfaces; (vi) global-positioning system (GPS) interfaces; (vii) Wi-Fi interfaces for providing a connection between a device and a wireless network; and (viii) sensor interfaces.

As described herein, sensors are electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device, such as a simultaneous localization and mapping (SLAM) camera); (ii) biopotential-signal sensors; (iii) IMUs for detecting, for example, angular rate, force, magnetic field, and/or changes in acceleration; (iv) heart rate sensors for measuring a user's heart rate; (v) peripheral oxygen saturation (SpO₂) sensors for measuring blood oxygen saturation and/or other biometric data of a user; (vi) capacitive sensors for detecting changes in potential at a portion of a user's body (e.g., a sensor-skin interface) and/or the proximity of other devices or objects; (vii) sensors for detecting some inputs (e.g., capacitive and force sensors); and (viii) light sensors (e.g., ToF sensors, infrared light sensors, or visible light sensors), and/or sensors for sensing data from the user or the user's environment. As described herein biopotential-signal-sensing components are devices used to measure electrical activity within the body (e.g., biopotential-signal sensors). Some types of biopotential-signal sensors include (i) electroencephalography (EEG) sensors configured to measure electrical activity in the brain to diagnose neurological disorders; (ii) electrocardiography (ECG or EKG) sensors configured to measure electrical activity of the heart to diagnose heart problems; (iii) EMG sensors configured to measure the electrical activity of muscles and diagnose neuromuscular disorders; (iv) electrooculography (EOG) sensors configured to measure the electrical activity of eye muscles to detect eye movement and diagnose eye disorders.

As described herein, an application stored in memory of an electronic device (e.g., software) includes instructions stored in the memory. Examples of such applications include (i) games; (ii) word processors; (iii) messaging applications; (iv) media-streaming applications; (v) financial applications; (vi) calendars; (vii) clocks; (viii) web browsers; (ix) social media applications; (x) camera applications; (xi) web-based applications; (xii) health applications; (xiii) AR and MR applications; and/or (xiv) any other applications that can be stored in memory. The applications can operate in conjunction with data and/or one or more components of a device or communicatively coupled devices to perform one or more operations and/or functions.

As described herein, communication interface modules can include hardware and/or software capable of data communications using any of a variety of custom or standard wireless protocols (e.g., IEEE 802.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocol, including communication protocols not yet developed as of the filing date of this document. A communication interface is a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, or Bluetooth). A communication interface can refer to a software layer that enables different software programs to communicate with each other (e.g., APIs and protocols such as HTTP and TCP/IP).

As described herein, a graphics module is a component or software module that is designed to handle graphical operations and/or processes and can include a hardware module and/or a software module.

As described herein, non-transitory computer-readable storage media are physical devices or storage medium that can be used to store electronic data in a non-transitory form (e.g., such that the data is stored permanently until it is intentionally deleted and/or modified).

### Multi-level Amplifiers

Various embodiments of this application include methods, circuits, devices, and systems for providing multi-level amplification (e.g., five-level class D amplifiers, seven-level class D amplifiers, and/or other types of multi-level amplification), e.g., in audio-centric use cases. These example circuits offer several benefits, including (i) reduced silicon area, (2) fewer external connections on integrated circuit package(s), and (3) minimized voltage ripples/swings (e.g., with a deviation of only one diode drop) during dead time when transitioning between states (e.g., voltage levels) when compared with conventional multi-level amplification circuits.

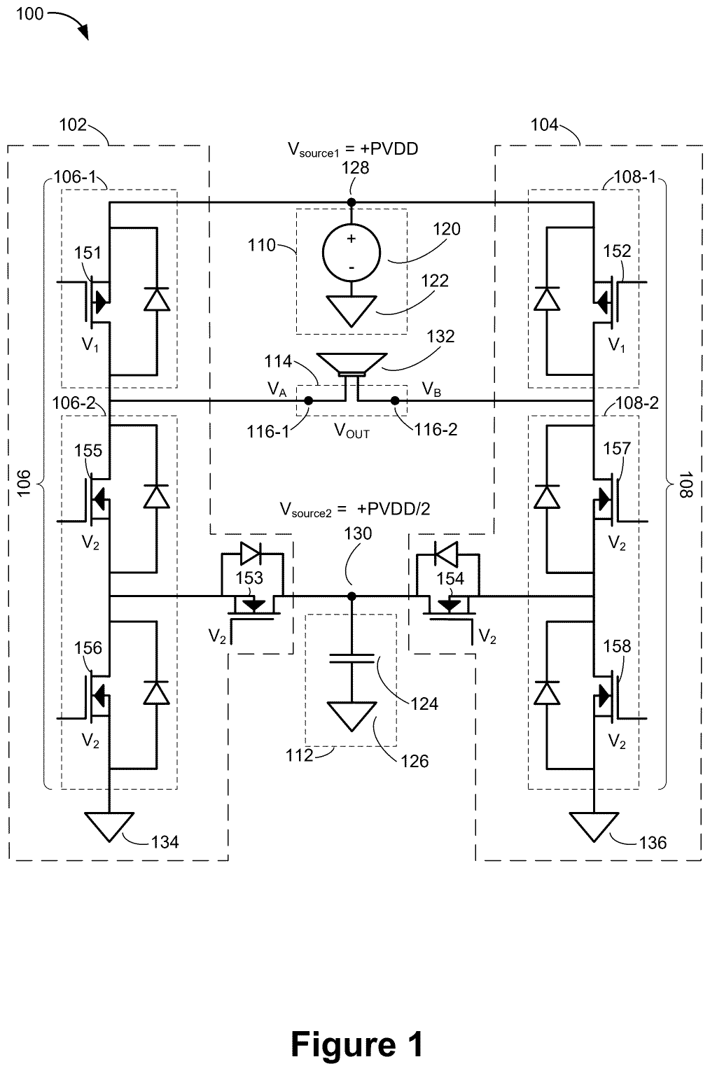

FIG. 1 illustrates a multi-level amplification circuit 100 (e.g., corresponding to a multi-level class D amplifier), in accordance with some embodiments. In some embodiments, the circuit 100 is configured as a five-level class D amplifier to provide a five-level output, e.g., five distinct voltage levels of +PVDD, +PVDD/2, 0, −PVDD/2, −PVDD. This circuit topology allows for finer resolution in output waveform synthesis as compared to conventional two-level or three-level class D amplifiers, and is extensible and scalable for generating additional intermediate voltage levels as required for higher-resolution or lower-distortion audio-centric implementations.

In some embodiments, the circuit 100 comprises a half-bridge power stage 102 and a half-bridge power stage 104. The half-bridge power stage 102 includes a set of switches 106 (e.g., transistors), and the half-bridge power stage 104 includes a set of switches 108 (e.g., transistors). A power source 110 is coupled to the half-bridge power stages 102 and 104 and configured to supply a DC voltage V_{source1} 128 (e.g., through a voltage rail). Similarly, a power source 112 is coupled to the half-bridge power stages 102 and 104 and configured to supply a DC voltage V_{source2} 130 (e.g., through a voltage rail). An output interface 114 is coupled to the half-bridge power stages 102 and 104 and configured to couple to a load 132 (e.g., a speaker). The half-bridge power stages 102 and 104 of the circuit 100 are configured to generate a five-level differential signal for driving the load 132. The set of switches 106 of the half-bridge power stage 102 includes a subset of switches 106-1 and a subset of switches 106-2. Each switch of the subset of switches 106-1 is configured to operate at a voltage level V1 (e.g., a maximum voltage level and/or a target voltage level) corresponding to the DC voltage V_{source1} 128, whereas at least some of the subset of switches 106-2 may be configured to operate at a voltage level V2 (e.g., a maximum voltage level and/or a target voltage level) corresponding to the DC voltage V_{source2} 130. Similarly, the set of switches 108 of the half-bridge power stage 104 includes a subset of switches 108-1 and a subset of switches 108-2. Each switch of the subset of switches 108-1 is configured to operate at the voltage level V1 corresponding to the DC voltage V_{source1} 128, whereas at least some of the subset of switches 108-2 may be configured to operate at the voltage level V2 corresponding to the DC voltage V_{source2} 130. In some embodiments, the load 132 comprises a speaker load coupled to the output interface 114. In some embodiments, the half-bridge power stage 102 includes an electrical ground 134, and the half-bridge power stage 104 includes an electrical ground 136. In some embodiments, the electrical ground 134 is the same as the electrical ground 136. In some embodiments, a voltage level (e.g., V1 and/or V2) is also referred to as a voltage rating (e.g., a voltage rating of a transistor). In some embodiments, a voltage level (e.g., V1 and/or V2) is also referred to as a maximum voltage level, e.g., the highest voltage applied to a switch. In some embodiments, a voltage level (e.g., V1 and/or V2) is also referred to as to a target voltage level, e.g., a predetermined voltage level to be maintained for a switch.

In some embodiments, the output interface 114 comprises terminals 116-1 and 116-2 that are coupled to the half-bridge power stages 102 and 104, respectively. In some embodiments, the terminal 116-1 receives a voltage V_{A} via the half-bridge power stage 102 and the terminal 116-2 receives a voltage V_{B} via the half-bridge power stage 104, such that the load 132 is powered by a differential voltage V_{OUT} (e.g., V_{OUT}=V_{A}−V_{B}) applied across the terminals 116-1 and 116-2.

In some embodiments, the power source 110 comprises a power supply 120 (e.g., a voltage source, a battery, etc.) and an electrical ground 122 (e.g., GND). In some embodiments, the power source 112 comprises a capacitor 124 and an electrical ground 126 (e.g., GND). In some circumstances, the capacitor 124 is constrained by an upper bound and a lower bound. In some embodiments, the capacitor 124 has a capacitance in a range from 1 μF to 30 μF (e.g., 1 μF to 22 μF). For example, a capacitance that is too low can lead to ripples, e.g., significant variations in change in the DC voltage V_{source2} 130. In another example, a capacitance that is too high can lead to extended duration of each cycle (e.g., slow charging effect). Additionally, a capacitance that is too high can result in an increase in size and cost of the capacitor 124. In some embodiments, the capacitance of the capacitor 124 is determined based on factors including available footprint (e.g., form factor required by design specifications) and cost considerations. In some embodiments, the power source 110 is configured as a battery rail.

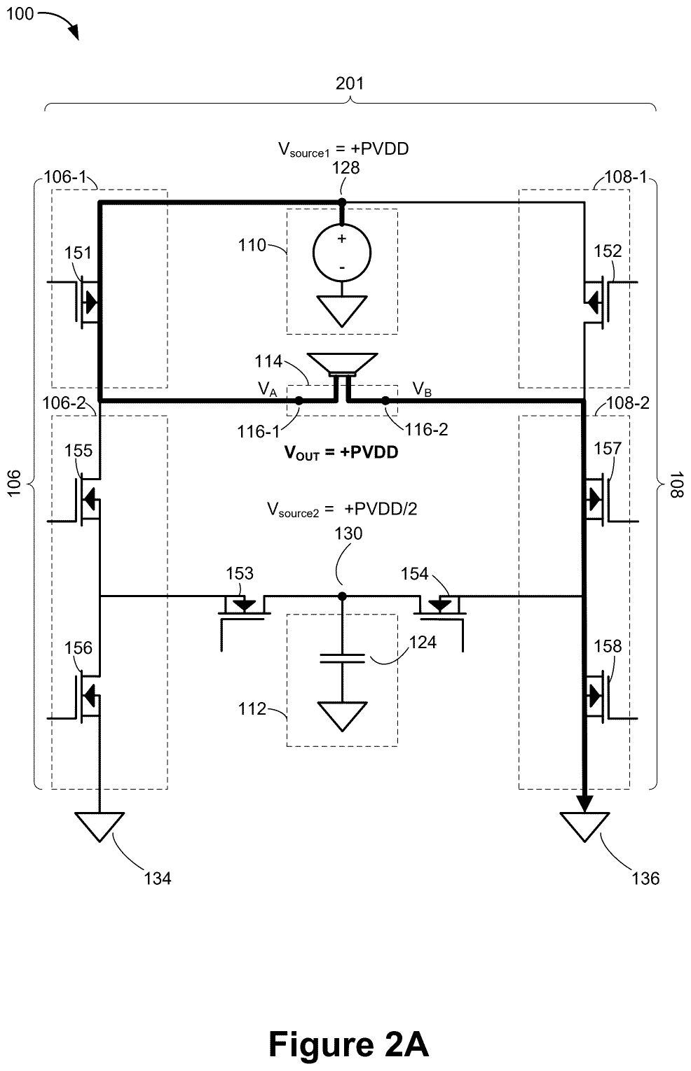

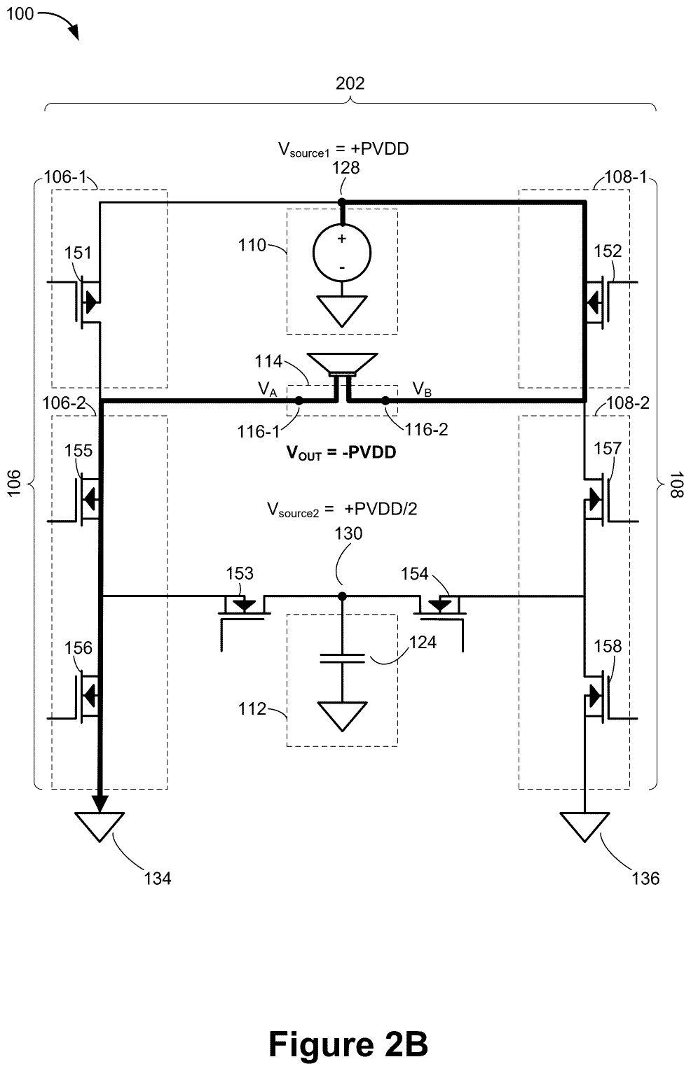

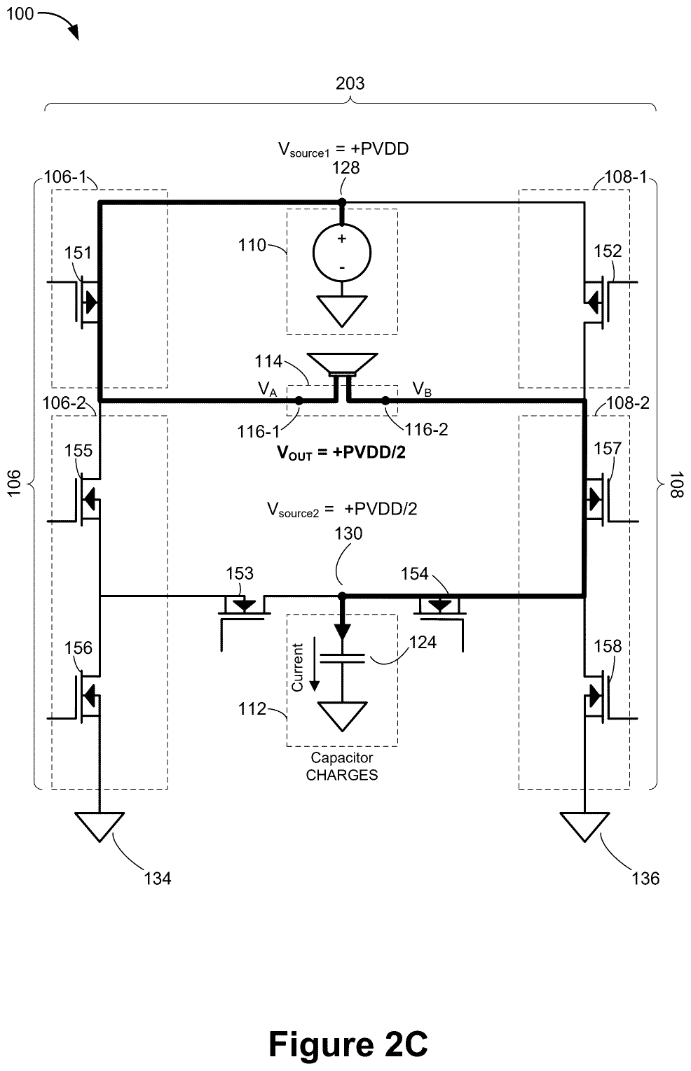

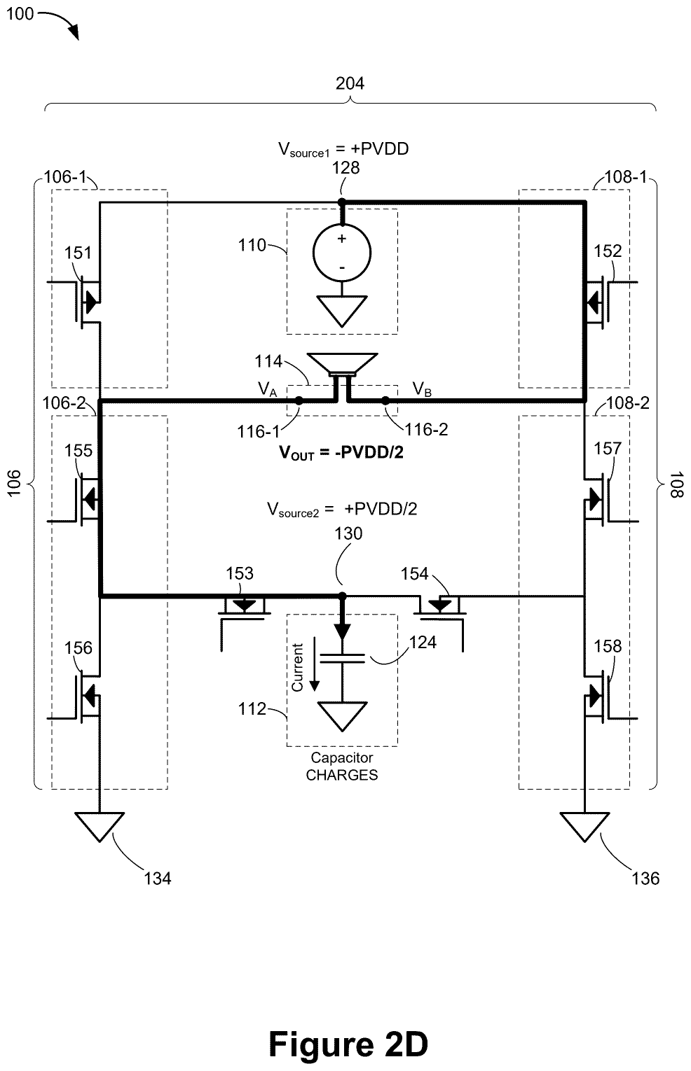

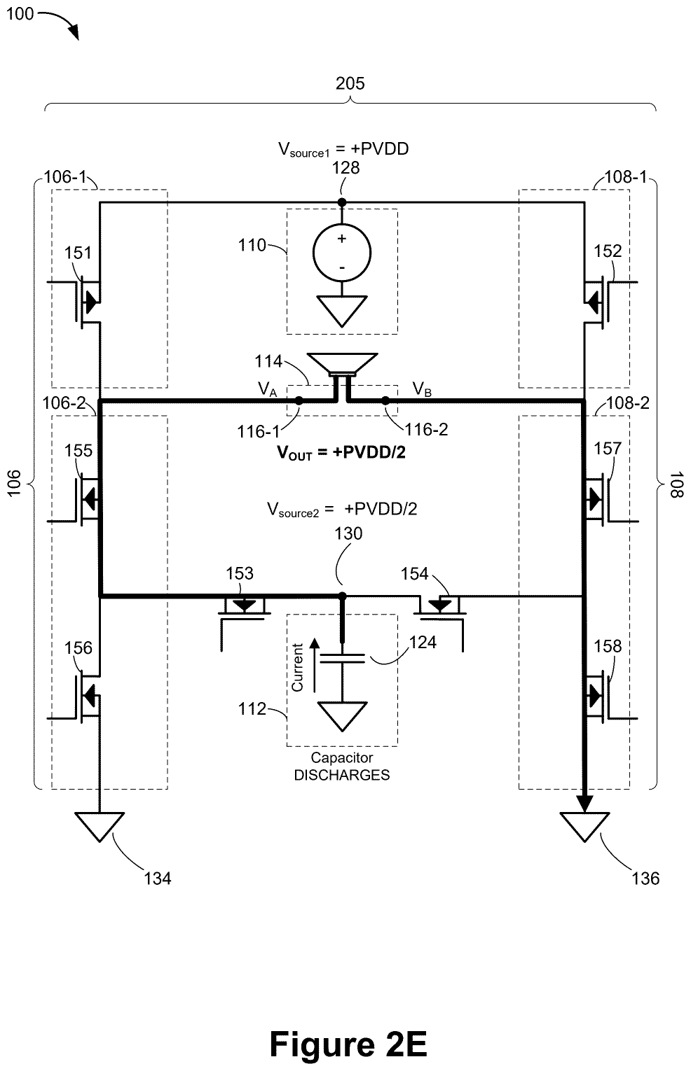

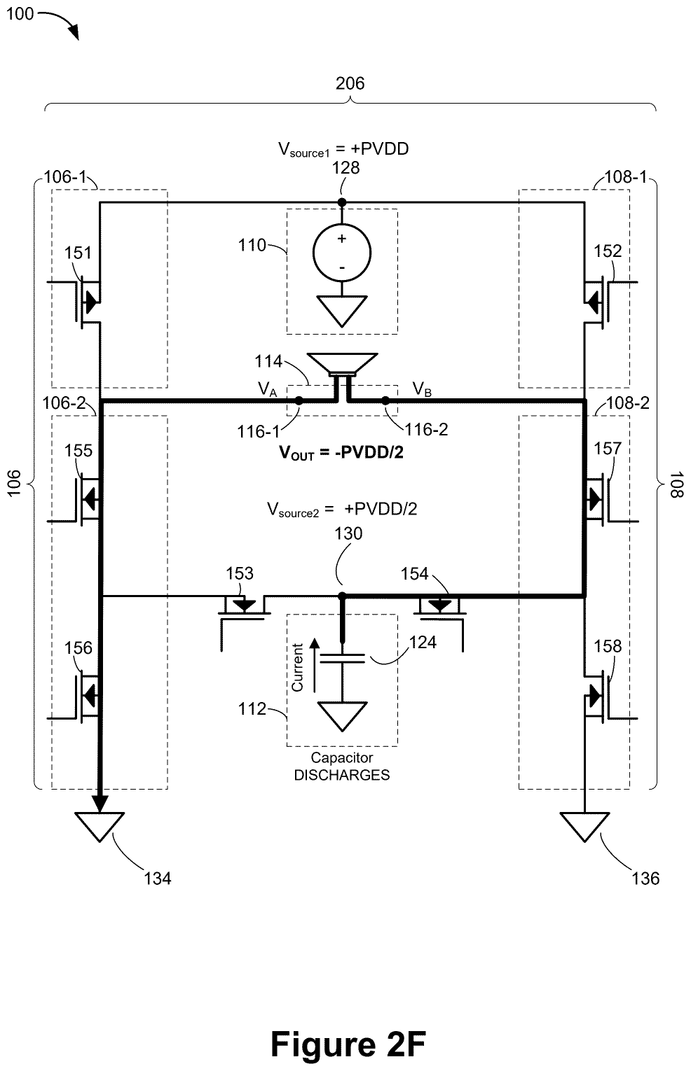

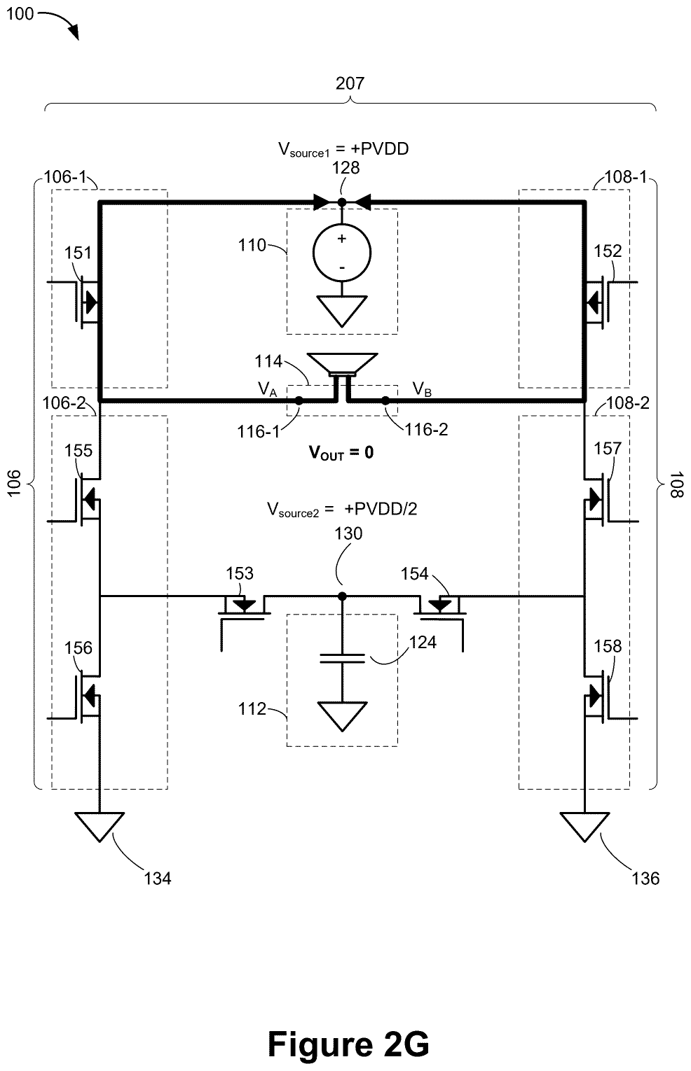

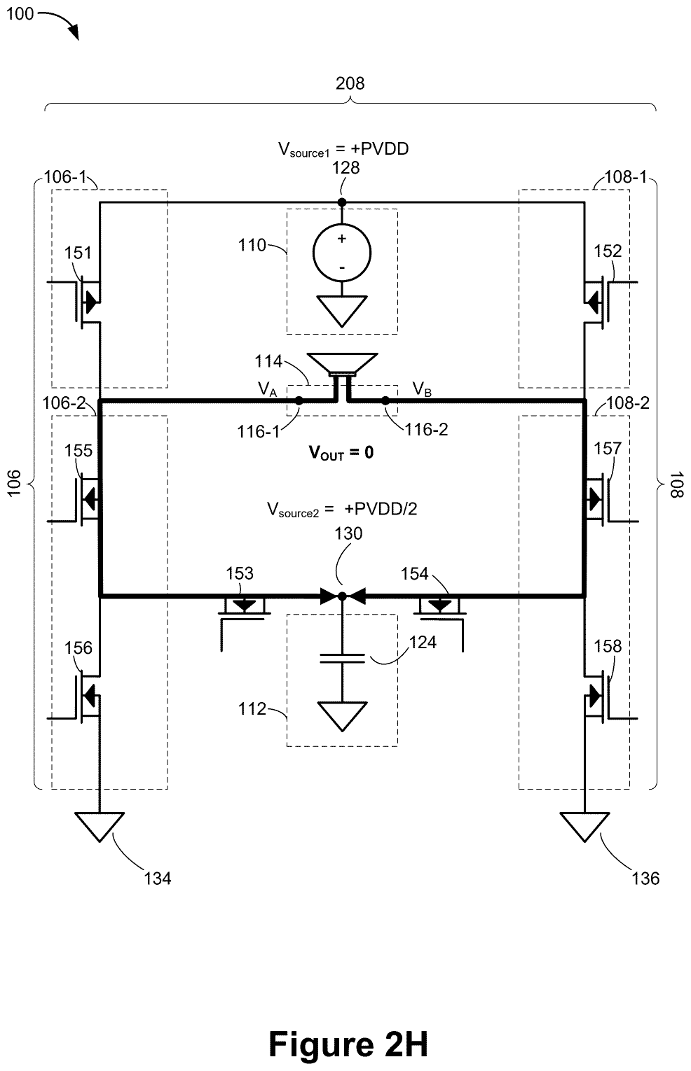

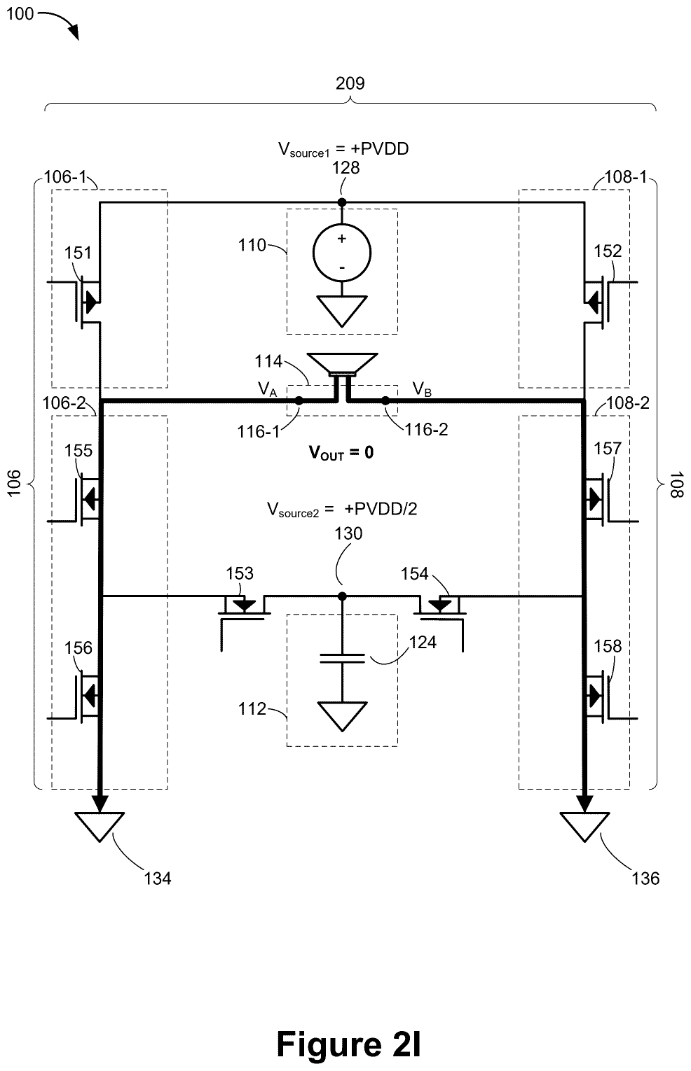

In some embodiments, the DC voltage V_{source2} 130 is configured to be one-half of the DC voltage V_{source1} 128. In some embodiments, the DC voltage V_{source1} 128 is maintained at +PVDD (e.g., a high-rail voltage), and the DC voltage V_{source2} 130 is maintained at +PVDD/2 (e.g., a low-rail voltage). In some embodiments, the DC voltage V_{source2} 130 is maintained at +PVDD/2 (e.g., a low-rail voltage) via switching operating states (e.g., as illustrated in FIGS. 2A-2I) of the circuit 100. In some embodiments, +PVDD is in a range from 8 V to 12 V, and +PVDD/2 is in a range 4 V to 6 V. For example, +PVDD may be at 10 V, and +PVDD/2 may be at 5 V. In some embodiments, +PVDD is a battery voltage (e.g., 3.7 V).

In some embodiments, the subset of switches 106-1 comprises a switch 151 and the subset of switches 106-2 comprises a switch 155 and a switch 156. In some embodiments, the switches 151, 155, and 156 are electrically connected in series, forming at least a portion of the half-bridge power stage 102. In some embodiments, the subset of switches 108-1 comprises a switch 152. The subset of switches 108-2 comprises a switch 157 and a switch 158. In some embodiments, the switches 152, 157, and 158 are electrically connected in series, forming at least a portion of the half-bridge power stage 104. In some embodiments, the half-bridge power stage 102 comprises a switch 153 and the half-bridge power stage 104 comprises a switch 154. The power source 112 is coupled to the half-bridge power stages 102 and 104 via the switch 153 and the switch 154, respectively. In some embodiments, the switches 153 and 154 are separate from the half-bridge power stages 102 and 104, respectively. In some embodiments, the switches 153 and 154 are configured to operate at the voltage level V2 corresponding to the DC voltage V_{source2} 130. In some embodiments, the switches 153 and 154 are configured to operate in a manner similar to the switches 155, 156, 157, and 158.

In some embodiments, each switch of the circuit 100 comprises a transistor. In some embodiments, the sets of switches 106 and 108 comprise one or more metal-oxide-semiconductor field-effect transistors (MOSFETs) (e.g., one or more N-channel MOSFETs and/or P-channel MOSFETs). In some embodiments, the respective subsets of switches 106-1 and 108-1 comprise P-channel MOSFETs, and the respective subsets of switches 106-2 and 108-2 comprise N-channel MOSFETs. For example, the switches 151 and 152 may be P-type MOSFETs. In another example, the switches 155, 156, 157, and 158 may be N-channel MOSFETs. In some embodiments, the respective subsets of switches 106-1 and 108-1 consist essentially of P-channel MOSFETs. In some embodiments, the respective subsets of switches 106-1 and 108-1 consist essentially of N-channel MOSFETs. In some embodiments, the subsets of switches 106-2 sand 108-2 consist essentially of N-channel MOSFETs. In some embodiments, the respective subsets of switches 106-2 and 108-2 consist essentially of P-channel MOSFETs. In some embodiments, the sets of switches 106 and 108 comprise one or more bipolar junction transistors (BJTs) (e.g., NPN BJTs, PNP BJTs) and/or FETs. In some embodiments, the switches 153 and 154 are implemented using the same type of switch devices (e.g., N-channel MOSFETs or NPN BJTs) as the switches 155, 156, 157, and 158. In some embodiments, each switch of the circuit 100 includes a parasitic diode (e.g., a body diode).

In some embodiments, the voltage level V1 is 10 V, e.g., corresponding to +PVDD (e.g., a high-rail voltage) of 10 V, and the voltage level V2 is 5 V, e.g., corresponding to +PVDD/2 (e.g., a low-rail voltage) of 5 V. In some embodiments, the voltage level V1 is 5 V, e.g., corresponding to +PVDD (e.g., a high-rail voltage) of 5 V, and the voltage level V2 is 2.5 V, e.g., corresponding to +PVDD/2 (e.g., a low-rail voltage) of 2.5 V. In some embodiments, the voltage level V1 and the voltage level V2 are determined (e.g., selected) based on +PVDD (e.g., ranging from 8 V to 12 V) and +PVDD/2 (e.g., ranging from 4 V to 6 V), respectively. In some embodiments, the voltage level V1 and the voltage level V2 are determined (e.g., selected) based on +PVDD (e.g., ranging from 4 V to 6 V) and +PVDD/2 (e.g., ranging from 2 V to 3 V), respectively. In some embodiments, the voltage levels V1 and V2 correspond to logic levels of switches. In some embodiments, some switches (e.g., the switches 151 and 152) of the circuit 100 are designed to operate at higher voltages (e.g., switches having higher voltage ratings associated with the voltage level V1 of 10 V), and other switches (e.g., the switches 153, 154, 155, 156, 157, and 158) of the circuit 100 are designed to operate at lower voltages (e.g., switches having lower voltage ratings associated with (i) the voltage level V2 of 5 V and/or (ii) the differences between the voltage levels V1 and V2). In some embodiments, a respective switch (e.g., a transistor) of the circuit 100 designed to operate at higher voltage(s) (e.g., 10 V) has a larger footprint (e.g., physical size) compared to another switch (e.g., a transistor) designed to operate at lower voltage(s) (e.g., 5 V). For example, the switch 151 may have a larger footprint compared to the switch 155. In some embodiments, only the switches 151 and 152 of the circuit 100 are configured to operate with a higher voltage level (e.g., V1), while the remaining switches are configured to operate with a lower voltage level (e.g., V2). In this circumstance, the overall silicon area can be reduced, as high-voltage switches may require larger footprints. By restricting the number of high-voltage switches, this approach enables a more compact and cost-efficient circuit implementation, while preserving the full functionality of the multi-level class D amplifier. In some embodiments, implementing a combination of switches operating at different voltages can impact overall circuity efficiency. For example, in the absence of a 4 V transistor, a 5 V transistor must be used instead, which induces an efficiency penalty (e.g., increased gate capacitance, higher threshold voltage, etc.).

In some embodiments, the half-bridge power stages 102 and 104 comprise a same configuration of switches (e.g., number of switches, parameters of switches). In some embodiments, the switches (e.g., the switches 151, 155, and 156) of the half-bridge power stage 102 have the same parameters as the switches (e.g., the switches 152, 157, and 158) of the half-bridge power stage 104. In some embodiments, the switches 153 and 154 have the same parameters as the switches 155, 156, 157, and 158. For example, when the switches are implemented as MOSFETs, the same parameters may include electrical characteristics such as threshold voltage, current or voltage rating, on-resistance, switching speed, gain, and other relevant properties. In some embodiments, the switches (e.g., the switches 151, 155, and 156) of the half-bridge power stage 102 have one or more parameters that are different than parameters of the switches (e.g., the switches 152, 157, and 158) of the half-bridge power stage 104. For example, when the switches are implemented as MOSFETs, these differing parameters may include threshold voltage, current or voltage rating, on-resistance, switching speed, gain, or any combination thereof.

In some embodiments, the circuit 100 is configured in an integrated circuit (IC) package. In some embodiments, the circuit 100 comprises only one capacitor (e.g., the capacitor 124). In one circumstance, only one external connection (e.g., a physical pin on the IC package) is needed to interface with the capacitor, e.g., when the capacitor is used to generate a voltage (e.g., +PVDD/2) referenced to a ground (e.g., the electrical ground 126), thereby reducing overall footprint and design complexity of the IC package. In another circumstance, two external connections (e.g., two physical pins on the IC package, one for each side of the capacitor) are needed, e.g., when the capacitor is used to generate a differential voltage across its terminals.

FIGS. 2A-2I illustrate example operating states of the circuit 100, in accordance with some embodiments. In some embodiments, the circuit 100 is configured to provide distinct voltage levels, e.g., +PVDD, +PVDD/2, 0, −PVDD/2, −PVDD, for the differential voltage V_{OUT}. In some embodiments, the DC voltage V_{source1} 128 is maintained at +PVDD (e.g., a high-rail voltage). In some embodiments, the DC voltage V_{source2} 130 is maintained at +PVDD/2 (e.g., a low-rail voltage) via the capacitor 124. In some embodiments, the DC voltage V_{source2} 130 is maintained at +PVDD/2 (e.g., a low-rail voltage) via switching (e.g., transitioning) operating states (e.g., as illustrated in FIGS. 2C-2F) of the circuit 100. The DC voltage V_{source2} 130 may be maintained by selectively charging using the DC voltage V_{source1} 128 (e.g., as illustrated in FIG. 2C). For example, if the desired output is +PVDD and the voltage at the capacitor is lower than PVDD/2, switching to operating state 203 (FIG. 2C) may be selected to add charge to the capacitor. Conversely, if the voltage at the capacitor is higher than PVDD/2, switching state 205 (FIG. 2E) may be selected to remove charge from the capacitor. In some embodiments, a voltage level (e.g., the voltage level V1 or the voltage level V2) of each switch of the circuit 100 is no less than a voltage applied across the respective switch (e.g., also referred to as stressed voltage). For example, when a switch is stressed at 5 V, a corresponding voltage level of the switch may be set to 5 V, 8 V or 10 V, which is no less than 5V. In some embodiments, each switch of the circuit 100 includes a parasitic diode (e.g., a body diode). In some embodiments, during an operating state, current flows through parasitic diode(s) (e.g., body diode(s)) coupled to respective switch(es) of the circuit 100.

FIG. 2A illustrates an operating state 201 in which the circuit 100 is configured to provide a voltage level of +PVDD for the differential voltage V_{OUT}, corresponding to the DC voltage V_{source1} 128, at the output interface 114, e.g., the voltage V_{A} at the terminal 116-1 equal to +PVDD and the voltage V_{B} at the terminal 116-2 equal to zero. In some embodiments, the voltage level of +PVDD for the differential voltage V_{OUT} is provided in accordance with (i) the switch 151 of the set of switches 106 being active (e.g., in a closed state such that current is flowing through the switch 151) and (ii) the switches 157 and 158 of the set of switches 108 being active (e.g., in a closed state such that current is flowing through the switches 157 and 158). In this circumstance, the switch 151 is turned on to connect the power source 110 to the terminal 116-1, and the switches 157 and 158 are turned on to connect the electrical ground 136 to the terminal 116-2. All other switches (e.g., the switches 152, 153, 154, 155, and 156) in the circuit 100 are inactive (e.g., in an open state such that current cannot flow through the switches 152, 153, 154, 155, and 156). Accordingly, the switches 152, 153, 154, 155, and 156 are stressed at: +PVDD, 0, +PVDD/2, +PVDD/2, and +PVDD/2, respectively. In some embodiments, the voltage level of +PVDD has a first polarity (e.g., a positive polarity relative to a common ground or reference potential).

FIG. 2B illustrates an operating state 202 in which the circuit 100 is configured to provide a voltage level of −PVDD for the differential voltage V_{OUT}, corresponding to the DC voltage V_{source1} 128, at the output interface 114, e.g., the voltage V_{A} at the terminal 116-1 equal to zero and the voltage V_{B} at the terminal 116-2 equal to +PVDD. In some embodiments, the voltage level of −PVDD for the differential voltage V_{OUT} is provided in accordance with (i) the switches 155 and 156 of the set of switches 106 being active (e.g., in a closed state such that current is flowing through the switches 155 and 156) and (ii) the switch 152 of the set of switches 108 being active (e.g., in a closed state such that current is flowing through the switch 152). In this circumstance, the switches 155 and 156 are turned on to connect the electrical ground 134 to the terminal 116-1, and the switch 152 is turned on to connect the power source 110 to the terminal 116-2. All other switches (e.g., the switches 151, 153, 154, 157, and 158) in the circuit 100 are inactive (e.g., in an open state such that current cannot flow through the switches 151, 153, 154, 157, and 158). Accordingly, the switches 151, 153, 154, 157, and 158 are stressed at: +PVDD, +PVDD/2, 0, +PVDD/2, and +PVDD/2, respectively. In some embodiments, the voltage level of −PVDD has a second polarity (e.g., a negative polarity relative to a common ground or reference potential).

FIG. 2C illustrates an operating state 203 in which the circuit 100 is configured to provide a voltage level of +PVDD/2 for the differential voltage V_{OUT}, corresponding to the DC voltage V_{source2} 130, at the output interface 114, e.g., the voltage V_{A} at the terminal 116-1 equal to +PVDD and the voltage V_{B} at the terminal 116-2 equal to +PVDD/2. In some embodiments, the voltage level of +PVDD/2 for the differential voltage V_{OUT} is provided in accordance with (i) the switch 151 of the set of switches 106 being active (e.g., in a closed state such that current is flowing through the switch 151), (ii) the switch 157 of the set of switch 108 being active (e.g., in a closed state such that current is flowing through the switch 157), and (iii) the switch 154 being active (e.g., in a closed state such that current is flowing through the switch 154). In this circumstance, the switch 151 is turned on to connect the power source 110 to the terminal 116-1, and the switches 154 and 157 are turned on to connect the power source 112 to the terminal 116-2. All other switches (e.g., the switches 152, 153, 155, 156, and 158) in the circuit 100 are inactive (e.g., in an open state such that current cannot flow through the switches 152, 153, 155, 156, and 158). Accordingly, the switches 152, 153, 155, 156, and 158 are stressed at: +PVDD/2, 0, +PVDD/2, +PVDD/2, and +PVDD/2, respectively. In some embodiments, the voltage level of +PVDD/2 has the first polarity (e.g., a positive polarity relative to a common ground or reference potential). In some embodiments, while in the operating state 203, the circuit 100 charges the capacitor 124 of the power source 112 through a current, e.g., the current that flows through the load 132 adds charge to the capacitor 124. In some embodiments, the DC voltage V_{source2} 130 is maintained at +PVDD/2 (e.g., a low-rail voltage) via switching (e.g., transitioning) to the operating state 203, which adds charge to the capacitor 124. For example, when the differential voltage V_{OUT} is required to be +PVDD/2 and the DC voltage V_{source2} 130 is lower than +PVDD/2, the circuit 100 is switched (e.g., transitioned) to the operating state 203 to add charge to the capacitor 124.

FIG. 2D illustrates an operating state 204 in which the circuit 100 is configured to provide a voltage level of −PVDD/2 for the differential voltage V_{OUT}, corresponding to the DC voltage V_{source2} 130, at the output interface 114, e.g., the voltage V_{A} at the terminal 116-1 equal to +PVDD/2 and the voltage V_{B} at the terminal 116-2 equal to +PVDD. In some embodiments, the voltage level of −PVDD/2 for the differential voltage V_{OUT} is provided in accordance with (i) the switch 155 of the set of switches 106 being active (e.g., in a closed state such that current is flowing through the switch 155), (ii) the switch 152 of the set of switches 108 being active (e.g., in a closed state such that current is flowing through the switch 152), and (iii) the switch 153 being active (e.g., in a closed state such that current is flowing through the switch 153). In this circumstance, the switches 153 and 155 are turned on to connect the power source 112 to the terminal 116-1, and the switch 152 is turned on to connect the power source 110 to the terminal 116-2. All other switches (e.g., the switches 151, 154, 156, 157, and 158) in the circuit 100 are inactive (e.g., in an open state such that current cannot flow through the switches 151, 154, 156, 157, and 158). Accordingly, the switches 151, 154, 156, 157, and 158 are stressed at: +PVDD/2, 0, +PVDD/2, +PVDD/2, and +PVDD/2, respectively. In some embodiments, the voltage level of −PVDD/2 has the second polarity (e.g., a negative polarity relative to a common ground or reference potential). In some embodiments, while in the operating state 204, the circuit 100 charges the capacitor 124 of the power source 112 through a current, e.g., the current that flows through the load 132 adds charge to the capacitor 124. In some embodiments, the DC voltage V_{source2} 130 is maintained at +PVDD/2 (e.g., a low-rail voltage) via switching (e.g., transitioning) to the operating state 204, which adds charge to the capacitor 124. For example, when the differential voltage V_{OUT} is required to be −PVDD/2 and the DC voltage V_{source2} 130 is lower than +PVDD/2, the circuit 100 is switched (e.g., transitioned) to the operating state 204 to add charge to the capacitor 124.

FIG. 2E illustrates an operating state 205 in which the circuit 100 is configured to provide the voltage level of +PVDD/2 for the differential voltage V_{OUT}, corresponding to the DC voltage V_{source2} 130, at the output interface 114, e.g., the voltage V_{A} at the terminal 116-1 equal to +PVDD/2 and the voltage V_{B} at the terminal 116-2 equal to zero. In some embodiments, the voltage level of +PVDD/2 for the differential voltage V_{OUT} is provided in accordance with (i) the switch 155 of the set of switches 106 being active (e.g., in a closed state such that current is flowing through the switch 155), (ii) the switches 157 and 158 of the set of switches 108 being active (e.g., in a closed state such that current is flowing through the switches 157 and 158), and (iii) the switch 153 being active (e.g., in a closed state such that current is flowing through the switch 153). In this circumstance, the switches 153 and 155 are turned on to connect the power source 112 to the terminal 116-1, and the switches 157 and 158 are turned on to connect the electrical ground 136 to the terminal 116-2. All other switches (e.g., the switches 151, 152, 154, and 156) in the circuit 100 are inactive (e.g., in an open state such that current cannot flow through the switches 151, 152, 154, and 156). Accordingly, the switches 151, 152, 154, and 156 are stressed at: +PVDD/2, +PVDD, +PVDD/2, and +PVDD/2, respectively. In some embodiments, the voltage level of +PVDD/2 has the first polarity (e.g., a positive polarity relative to a common ground or reference potential). In some embodiments, while in the operating state 205, the circuit 100 discharges the capacitor 124 of the power source 112 through a current, e.g., the current that flows through the load 132 pulls (e.g., removes) charge from the capacitor 124. In some embodiments, while in the operating state 205, the current flows through parasitic diode(s) (e.g., body diode(s)) coupled to respective switch(es). In some embodiments, the DC voltage V_{source2} 130 is maintained at +PVDD/2 (e.g., a low-rail voltage) via switching (e.g., transitioning) to the operating state 205, which pulls (e.g., removes) charge from the capacitor 124. For example, when the differential voltage V_{OUT} is required to be +PVDD/2 and the DC voltage V_{source2} 130 is higher than +PVDD/2, the circuit 100 is switched (e.g., transitioned) to the operating state 205 to pull (e.g., remove) charge to the capacitor 124.

FIG. 2F illustrates an operating state 206 in which the circuit 100 is configured to provide the voltage level of −PVDD/2 for the differential voltage V_{OUT}, corresponding to the DC voltage V_{source2} 130 (e.g., a negative value of the DC voltage V_{source2} 130), at the output interface 114, e.g., the voltage V_{A} at the terminal 116-1 equal to zero and the voltage V_{B} at the terminal 116-2 equal to +PVDD/2. In some embodiments, the voltage level of −PVDD/2 for the differential voltage V_{OUT} is provided in accordance with (i) the switches 155 and 156 of the set of switch 106 being active (e.g., in a closed state such that current is flowing through the switches 155 and 156), (ii) the switch 157 of the set of switch 108 being active (e.g., in a closed state such that current is flowing through the switch 157), and (iii) the switch 154 being active (e.g., in a closed state such that current is flowing through the switch 154). In this circumstance, the switches 155 and 156 are turned on to connect the electrical ground 134 to the terminal 116-1, and the switches 154 and 157 are turned on to connect the power source 112 to the terminal 116-2. All other switches (e.g., the switches 151, 152, 153, and 158) in the circuit 100 are inactive (e.g., in an open state such that current cannot flow through the switches 151, 152, 153, and 158). Accordingly, the switches 151, 152, 153, and 158 are stressed at: +PVDD, +PVDD/2, +PVDD/2, and +PVDD/2, respectively. In some embodiments, the voltage level of −PVDD/2 has the second polarity (e.g., a negative polarity relative to a common ground or reference potential). In some embodiments, while in the operating state 206, the circuit 100 discharges the capacitor 124 of the power source 112 through a current, e.g., the current that flows through the load 132 pulls charge from the capacitor 124. In some embodiments, while in the operating state 206, the current flows through parasitic diode(s) (e.g., body diode(s)) coupled to respective switch(es). In some embodiments, the DC voltage V_{source2} 130 is maintained at +PVDD/2 (e.g., a low-rail voltage) via switching (e.g., transitioning) to the operating state 206, which pulls (e.g., removes) charge from the capacitor 124. For example, when the differential voltage V_{OUT} is required to be −PVDD/2 and the DC voltage V_{source2} 130 is higher than +PVDD/2, the circuit 100 is switched (e.g., transitioned) to the operating state 206 to pull (e.g., remove) charge to the capacitor 124.

FIG. 2G illustrates an operating state 207 in which the circuit 100 is configured to provide a voltage level of zero for the differential voltage V_{OUT} at the output interface 114, e.g., the voltage V_{A} at the terminal 116-1 equal to +PVDD and the voltage V_{B} at the terminal 116-2 equal to +PVDD. In some embodiments, the voltage level of zero for the differential voltage V_{OUT} is provided in accordance with (i) the switch 151 of the set of switches 106 being active (e.g., in a closed state such that current is flowing through the switch 151) and (ii) the switch 152 of the set of switches 108 being active (e.g., in a closed state such that current is flowing through the switch 152). In this circumstance, the switch 151 is turned on to connect the power source 110 to the terminal 116-1, and the switch 152 is turned on to connect the power source 110 to the terminal 116-2. All other switches (e.g., the switches 153, 154, 155, 156, 157, and 158) in the circuit 100 are inactive (e.g., in an open state such that current cannot flow through the switches 153, 154, 155, 156, 157, and 158). Accordingly, the switches 153, 154, 155, 156, 157, and 158 are stressed at: 0, 0, +PVDD/2, +PVDD/2, +PVDD/2, and +PVDD/2, respectively. In some embodiments, the voltage level of zero is a zero voltage. In some embodiments, while in the operating state 207, two terminals (e.g., the terminals 116-1 and 116-2) of the output interface 114 are electrically coupled to the power source 110.

FIG. 2H illustrates an operating state 208 in which the circuit 100 is configured to provide the voltage level of zero for the differential voltage V_{OUT} at the output interface 114, e.g., the voltage V_{A} at the terminal 116-1 equal to +PVDD/2 and the voltage V_{B} at the terminal 116-2 equal to +PVDD/2. In some embodiments, the voltage level of zero for the differential voltage V_{OUT} is provided in accordance with (i) the switch 155 of the set of switches 106 being active (e.g., in a closed state such that current is flowing through the switch 155), (ii) the switch 157 of the set of switches 108 being active (e.g., in a closed state such that current is flowing through the switch 157), and (iii) the switches 153 and 154 being active (e.g., in a closed state such that current is flowing through the switches 153 and 154). In this circumstance, the switches 153 and 155 are turned on to connect the power source 112 to the terminal 116-1, and the switches 154 and 157 are turned on to connect the power source 112 to the terminal 116-2. All other switches (e.g., the switches 151, 152, 156, and 158) in the circuit 100 are inactive (e.g., in an open state such that current cannot flow through the switches 151, 152, 156, and 158). Accordingly, the switches 151, 152, 156, and 158 are stressed at: +PVDD/2, +PVDD/2, +PVDD/2, and +PVDD/2, respectively. In some embodiments, the voltage level of zero is a zero voltage. In some embodiments, while in the operating state 208, two terminals (e.g., the terminals 116-1 and 116-2) of the output interface 114 are electrically coupled to the power source 112.

FIG. 2I illustrates an operating state 209 in which the circuit 100 is configured to provide the voltage level of zero for the differential voltage V_{OUT} at the output interface 114, e.g., the voltage V_{A} at the terminal 116-1 equal to zero and the voltage V_{B} at the terminal 116-2 equal to zero. In some embodiments, the voltage level of zero for the differential voltage V_{OUT} is provided in accordance with (i) the switches 155 and 156 of the set of switches 106 being active (e.g., in a closed state such that current is flowing through the switches 155 and 156) and (ii) the switches 157 and 158 of the set of switches 108 being active (e.g., in a closed state such that current is flowing through the switches 157 and 158). In this circumstance, the switches 155 and 156 are turned on to connect the electrical ground 134 to the terminal 116-1, and the switches 157 and 158 are turned on to connect the electrical ground 136 to the terminal 116-2. All other switches (e.g., the switches 151, 152, 153, and 154) in the circuit 100 are inactive (e.g., in an open state such that current cannot flow through the switches 151, 152, 153, and 154). Accordingly, the switches 151, 152, 153, and 154 are stressed at: +PVDD, +PVDD, +PVDD/2, and +PVDD/2, respectively. In some embodiments, while in the operating state 209, two terminals (e.g., the terminals 116-1 and 116-2) of the output interface 114 are electrically coupled to an electrical ground (e.g., the electrical ground 134 and/or the electrical ground 136).

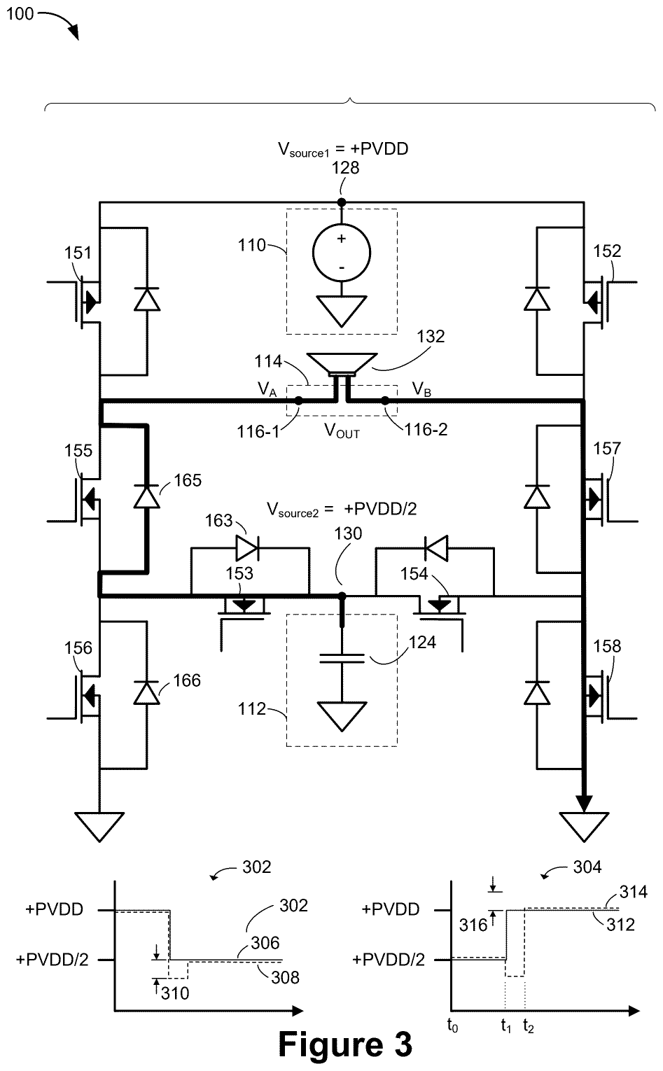

FIG. 3 illustrates an example transient operating state 301 that occurs during a transition between voltage levels of the circuit 100, in accordance with some embodiments. In some embodiments, the transient operating state 301 occurs when the voltage level of the circuit 100 transitions between the voltage level of +PVDD and the voltage level of +PVDD/2, e.g., when the circuit 100 switches its operation from the operating state 201 (e.g., in reference to FIG. 2A) to the operating state 205 (e.g., in reference to FIG. 2E), and vice versa.

In some embodiments, each switch of the circuit 100 includes a parasitic diode (e.g., a body diode). For example, the switch 155 (e.g., a transistor) includes a parasitic diode 165. In another example, the switch 156 (e.g., a transistor) includes a parasitic diode 166. In some embodiments, in the transient operating state 301 when the circuit 100 switches its operation from the operating state 201 to the operating state 205, the switch 151 becomes inactive (e.g., turned off) and the switches 153 and 155 becomes active (e.g., turned on). In this scenario (e.g., scenario 302), compared to an ideal voltage profile 306, an actual voltage profile 308 exhibits a voltage drop 310 induced by a forward voltage (e.g., a diode drop of 0.7 V) of the parasitic diode 165. In some embodiments, in the transient operating state 301 when the circuit 100 switches its operation from the operating state 201 to the operating state 205, the switch 153 becomes active (e.g., turned on) prior to the switch 151 becoming inactive (e.g., turned off) and the switch 155 becoming active (e.g., turned on). In this circumstance, current can flow through the parasitic diode 165 during the transition without conducting through the parasitic diode 166, such that the actual voltage profile 308 exhibits a diode drop (e.g., +0.7 V) away from the ideal voltage profile 306 but not away from an electrical ground. In some embodiments, the transient operating state 301 corresponds to the circuit 100 switching its operation from the operating state 205 to the operating state 201, in which the switches 153 and 155 becomes inactive (e.g., turned off) and the switch 151 becomes active (e.g., turned on). In this scenario (e.g., scenario 304), compared to an ideal voltage profile 312, an actual voltage profile 314 exhibits a voltage drop 316 induced by the forward voltage (e.g., 0.7 V) of the parasitic diode 165. For example, during a time period from t0 to t1, the switches 153 and 155 become active (e.g., turned on) to conduct current, such that the terminal 116-1 is electrically connected to the power source 112, e.g., the voltage V_{A} equal to the DC voltage V_{source2} 130 of +PVDD/2. During a time period from t1 to t2, the switch 153 becomes inactive (e.g., turned off). The current continues flowing through the load 132 (e.g., resulting from electrical energy stored in the load's inductance), and the current biases a parasitic diode 163 (e.g., a body diode) of the switch 153, such that the current flows through the parasitic diode 163 and leads to the voltage drop 316, e.g., the voltage V_{A} equal to V_{source2} minus a diode drop of +0.7 V. During a time period starting from t2, the switch 151 become active (e.g., turned on) to electrically connect the terminal 116-1 to the power source 110, e.g., the voltage V_{A} equal to the DC voltage V_{source1} 128 of +PVDD. In some circumstances, signal ripples/swings (e.g., the voltage drop 310 and/or the voltage drop 316) may not adversely affect the operational functionality of the circuit 100 in its role as a five-level class D amplifier. In other circumstances, signal ripples/swings (e.g., the voltage drop 310 and/or the voltage drop 316) can be compensated by a feedback loop (e.g., determined by a loop gain) to minimize their impact.

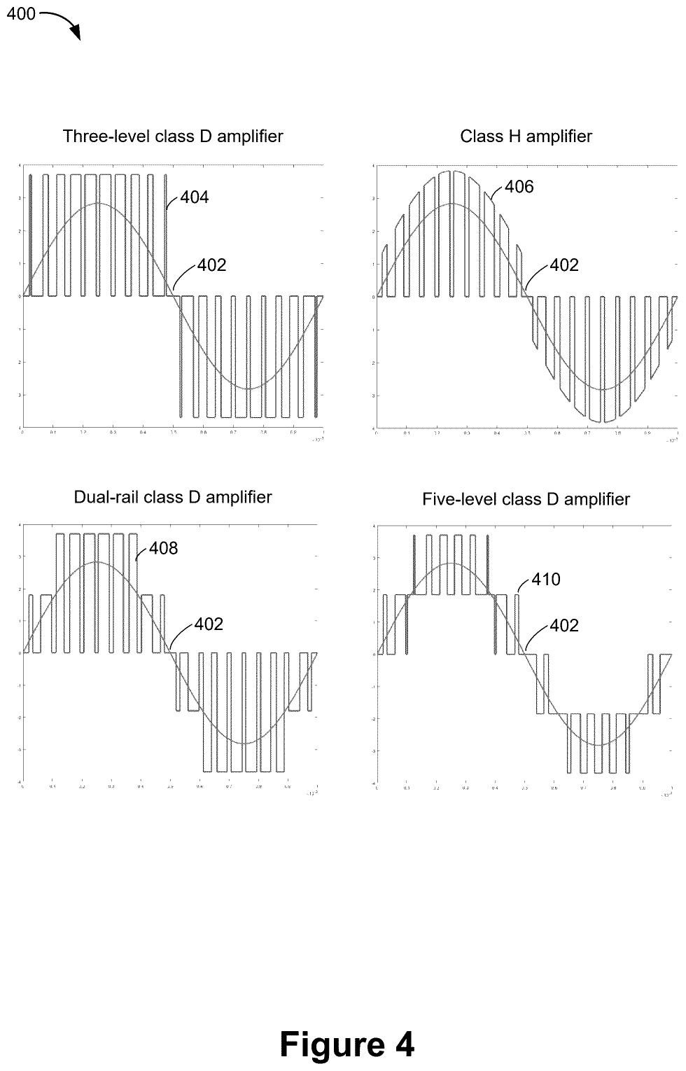

FIG. 4 illustrates example output signals 400 generated by different amplifier topologies, in accordance with some embodiments. Output signals 404, 406, 408, and 410 are generated by a three-level class D amplifier, a class H amplifier, a dual-rail class D amplifier, and a five-level class D amplifier, respectively, in response to an input audio signal 402. As shown in FIG. 4, the output signal 410, which is generated by the five-level class D amplifier, shows smaller step changes between voltage levels when compared to the output signals 404, 406, and 408. These reduced step changes in the five-level amplifier topology can minimize high-frequency switching ripples/swings and also enable more efficient output filtering. In some embodiments, the output signals 404, 406, 408, and 410 are pulse-width modulated (PWM) waveforms. In some embodiments, the output signal 410 can be generated by the circuit 100 that is configured as a five-level class D amplifier.

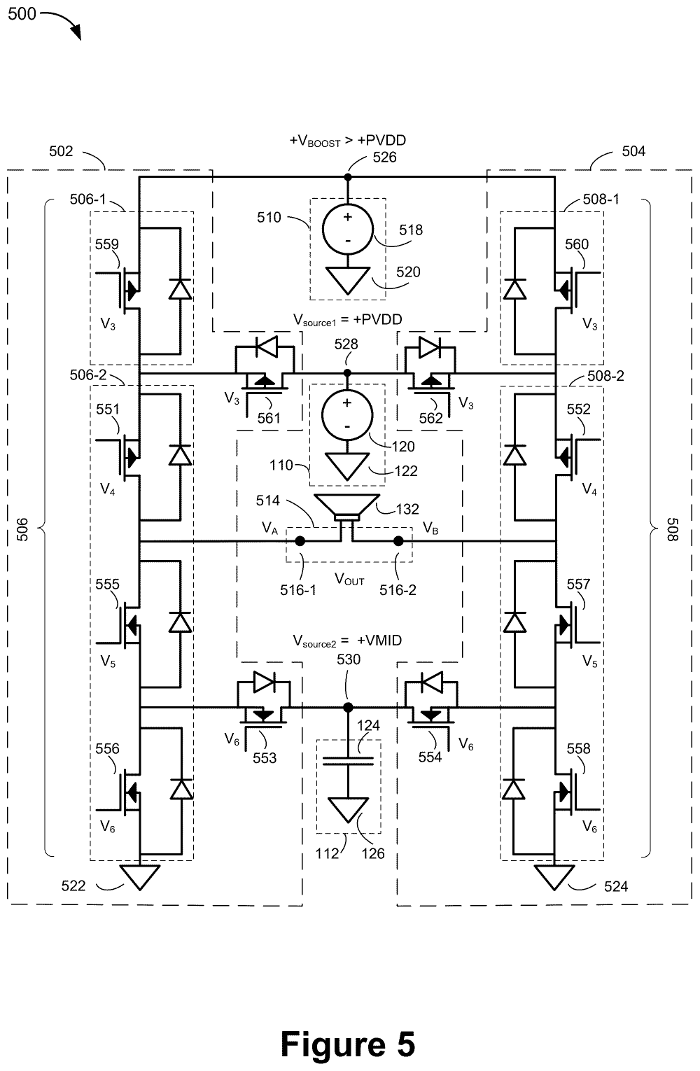

FIG. 5 illustrates another example multi-level amplification circuit 500 (e.g., corresponding to a multi-level class D amplifier), in accordance with some embodiments. In some embodiments, the circuit 500 is configured as a seven-level class D amplifier that provides a seven-level output, e.g., seven distinct voltage levels of +VBOOST, +PVDD, +VMID, 0, −VMID, −PVDD, −VBOOST. This circuit topology facilitates multi-level modulation between a higher voltage rail and a battery rail, thereby enabling finer voltage resolution and improved modulation performance. In some embodiments, the higher voltage rail is a boosted rail (e.g., at +VBOOST) that is driven by a boost converter. In some embodiments, the battery rail is a +PVDD rail (e.g., the power source 110). Additionally, this seven-level amplifier topology of the circuit 500 offers several advantages, including (i) interleaved operation between the boosted and battery rails to enable configurable current draw “smoothing”, (ii) dynamic modulation between the boosted and battery rail voltages to generate an elevated voltage output when needed (e.g., increased output headroom, speaker linearization, etc.), (iii) capability to power the output using the boosted rail without sacrificing efficiency when operating the battery rail, and (iv) minimized silicon area requirements. In some embodiments, the circuit 500 has operational behaviors and architectural characteristics similar to those described previously with respect to the circuit 100. In some embodiments, the boosted rail comprises a reservoir capacitor (e.g., having a storage capacitance) that is configured to store electrical energy and can be selectively depleted and recharged at a controlled rate. In some embodiments, the circuit 500 comprises the circuit 100, e.g., the circuit 100 is a subset of the circuit 500.

In some embodiments, the circuit 500 comprises a half-bridge power stage 502 and a half-bridge power stage 504. The half-bridge power stage 502 includes a set of switches 506, and the half-bridge power stage 504 includes a set of switches 508. A power source 510 is coupled to the half-bridge power stages 502 and 504 and configured to supply a boosted DC voltage +VBOOST 526 (e.g., through a boosted voltage rail). Similar to the circuit 100, power sources 110 and 112 (e.g., in reference to FIGS. 1-3) are coupled to the half-bridge power stages 502 and 504, and are configured to supply a DC voltage V_{source1} 528 and a DC voltage V_{source2} 530, respectively (e.g., through voltage rails). An output interface 514 is coupled to the half-bridge power stages 502 and 504 and configured to couple to the load 132 (e.g., in reference to FIGS. 1-3). The half-bridge power stages 502 and 504 of the circuit 500 are configured to generate a seven-level differential signal for driving the load 132. The set of switches 506 of the half-bridge power stage 502 includes a subset of switches 506-1 and a subset of switches 506-2. Each switch of the subset of switches 506-1 is configured to operate at a voltage level V3. Each switch of the subset of switches 506-2 is configured to operate at a voltage level V4, V5, or V6. Similarly, the set of switches 508 of the half-bridge power stage 504 includes a subset of switches 508-1 and a subset of switches 508-2. Each switch of the subset of switches 508-1 is configured to operate at the voltage level V3. Each switch of the subset of switches 508-2 is configured to operate at the voltage level V4, V5, or V6. The voltage levels V3, V4, V5, and V6 correspond to the boosted DC voltage +VBOOST 526, the DC voltage V_{source1} 528, the DC voltage V_{source2} 530, or a combination thereof. In some embodiments, each switch of a respective set of switches (e.g., the set of switches 506 or the set of switches 508) is configured to operate at a distinct voltage level, which corresponds to the boosted DC voltage +VBOOST 526, the DC voltage V_{source1} 528, the DC voltage V_{source2} 530, or a combination thereof. In some embodiments, the load 132 comprises a speaker load coupled to the output interface 514. In some embodiments, the half-bridge power stage 502 includes an electrical ground 522, and the half-bridge power stage 504 includes an electrical ground 524. In some embodiments, a voltage level (e.g., V3, V4, V5, and/or V6) may also be referred to as a voltage rating (e.g., a voltage rating of a transistor). In some embodiments, a voltage level (e.g., V3, V4, V5, and/or V6) is also referred to as a maximum voltage level, e.g., the highest voltage applied to a switch. In some embodiments, a voltage level (e.g., V3, V4, V5, and/or V6) is also referred to as to a target voltage level, e,g,. a predetermined voltage level to be maintained for a switch. In some embodiments, similar to the circuit 100, the circuit 500 is configured in an IC package. In some embodiments, the circuit 100 comprises only one capacitor (e.g., the capacitor 124). Accordingly, only one external connection (e.g., a physical pin on the IC package) is needed to interface with the capacitor, thereby reducing overall footprint and design complexity of the IC package.

In some embodiments, the output interface 514 comprises terminals 516-1 and 516-2 that are coupled to the half-bridge power stages 502 and 504, respectively. In some embodiments, the terminal 516-1 receives a voltage V_{A} via the half-bridge power stage 502 and the terminal 516-2 receives a voltage V_{B} via the half-bridge power stage 504, such that the load 132 is powered by a differential voltage V_{OUT} (e.g., V_{OUT}=V_{A}−V_{B}) applied across the terminals 516-1 and 516-2.

In some embodiments, the power source 510 comprises a power supply 518 (e.g., a boosted voltage source, a battery voltage source, etc.) and an electrical ground 520 (e.g., GND). In some embodiments, the power source 510 is configured as a boosted rail. In some embodiments, the power source 510 is configured as a battery rail. In some embodiments, the boosted DC voltage +VBOOST 526 is maintained at a DC voltage greater than +PVDD, e.g., +VBOOST>+PVDD. In some embodiments, the power source 110 is configured as a battery rail, and the DC voltage V_{source1} 128 is maintained at +PVDD (e.g., a high-rail voltage). In some embodiments, the DC voltage V_{source2} 530 is maintained at +VMID (e.g., a mid-rail voltage). In some embodiments, the DC voltage V_{source2} 530 is configured to be one-half of the DC voltage V_{source1} 528 and maintained at +PVDD/2 (e.g., +VMID equal to +PVDD/2). In some embodiments, the DC voltage V_{source2} 530 is maintained at +VMID (e.g., a mid-rail voltage) via switching (e.g., transitioning) operating states of the circuit 500, e.g., via charging or discharging the capacitor 124 similar to FIGS. 2C-2F. In some embodiments, +VBOOST is in a range from 8 V to 12 V, +PVDD is in a range from 2 V to 6 V, and +VMID is in a range 1 V to 3 V. For example, +VBOOST may be at 10 V, +PVDD may be at 5.5 V, and +VMID may be at 2.75 V. In another example, +VBOOST may be at 10 V, +PVDD may be at 3.7 V, and +VMID may be at 1.85 V. In yet another example, +VBOOST may be at 10 V, +PVDD may be at 5 V, and +VMID may be at 2.5 V.

In some embodiments, the subset of switches 506-1 comprises a switch 559 and the subset of switches 506-2 comprises switches 551, 555, and 556. In some embodiments, the switches 559, 551, 555, and 556 are electrically connected in series, forming at least a portion of the half-bridge power stage 502. In some embodiments, the subset of switches 508-1 comprises a switch 560 and the subset of switches 508-2 comprises switches 552, 557, and 558. In some embodiments, the switches 560, 552, 557, and 558 are electrically connected in series, forming at least a portion of the half-bridge power stage 504. In some embodiments, the half-bridge power stage 502 comprises a switch 561 and the half-bridge power stage 504 comprises a switch 562. The power source 110 is coupled to the half-bridge power stages 502 and 504 via the switch 561 and the switch 562, respectively. In some embodiments, the half-bridge power stage 502 comprises a switch 553 and the half-bridge power stage 504 comprises a switch 554. The power source 112 is coupled to the half-bridge power stages 502 and 504 via the switch 553 and the switch 554, respectively. In some embodiments, the switches 561 and 562 are separate from the half-bridge power stages 502 and 504, respectively. In some embodiments, the switches 553 and 554 are separate from the half-bridge power stages 502 and 504, respectively. In some embodiments, the switches 559, 560, 561 and 562 are configured to operate at the voltage level V3. In some embodiments, the switches 551 and 552 are configured to operate at the voltage level V4. In some embodiments, the switches 555 and 557 are configured to operate at the voltage level V5. In some embodiments, the switches 553, 554, 556, and 558 are configured to operate at the voltage level V6. In some embodiments, the switches 561 and 562 are configured to operate in a manner similar to the switches 551, 552, 559, and 560. In some embodiments, the switches 553 and 554 are configured to operate in a manner similar to the switches 555, 556, 557, and 558.

In some embodiments, the half-bridge power stages 502 and 504 of the circuit 500 comprise a same configuration of switches (e.g., number of switches, parameters of switches), e.g., similar to the half-bridge power stages 102 and 104 of the circuit 100. In some embodiments, each switch of the circuit 500 comprises a transistor. In some embodiments, the sets of switches 506 and 508 comprise one or more MOSFETs (e.g., one or more N-channel MOSFETs and/or P-channel MOSFETs). In some embodiments, the sets of switches 506 and 508 comprise one or more BJTs (e.g., NPN BJTs, PNP BJTs) and/or FETs. In some embodiments, the switches 551, 552, 559, 560, 561, and 562 are implemented using the same type of switch devices (e.g., P-channel MOSFETs or PNP BJTs). In some embodiments, the switches 553, 554, 555, 556, 557, and 558 are implemented using the same type of switch devices (e.g., n-channel MOSFETs or NPN BJTs). In some embodiments, each switch of the circuit 500 includes a parasitic diode (e.g., a body diode).

In some embodiments, the voltage level V3 is 8 V, e.g., corresponding to +VBOOST of 10 V, +PVDD of 5 V, +VMID of 2.5 V, or a combination thereof. In some embodiments, the voltage level V4 is 5 V, e.g., corresponding to +VBOOST of 10 V, +PVDD of 5 V, +VMID of 2.5 V. In some embodiments, the voltage level V5 is 10 V, e.g., corresponding to +VBOOST of 10 V, +PVDD of 5 V, +VMID of 2.5 V. In some embodiments, the voltage level V6 is 2.5 V, e.g., corresponding to +VBOOST of 10 V, +PVDD of 5 V, +VMID of 2.5 V. In some embodiments, the voltage level V3 is 8 V or 10 V, e.g., corresponding to +VBOOST of 10 V, +PVDD of 5.5 V, +VMID of 2.75 V, or a combination thereof. In some embodiments, the voltage level V4 is 5 V, e.g., corresponding to +VBOOST of 10 V, +PVDD of 5.5 V, +VMID of 2.75 V, or a combination thereof. In some embodiments, the voltage level V5 is 5 V, e.g., corresponding to +VBOOST of 10 V, +PVDD of 5.5 V, +VMID of 2.75 V, or a combination thereof. In some embodiments, the voltage level V6 is 5 V, e.g., corresponding to +VBOOST of 10 V, +PVDD of 5.5 V, +VMID of 2.75 V, or a combination thereof. In some embodiments, the voltage levels V4, V5, and V6 are identical. In some embodiments, the voltage levels V3, V4, V5, and V6 are determined (e.g., selected) based on +VBOOST (e.g., ranging from 8 V to 12 V), +PVDD (e.g., ranging from 2 V to 6 V), and +VMID (e.g., ranging from 1 V to 3 V). In some embodiments, the voltage levels V3 and V4 correspond to logic levels of switches. In some embodiments, some switches (e.g., the switches 559 and 560) of the circuit 500 are designed to operate at higher voltages (e.g., switches having higher voltage ratings associated with the voltage level V3 of 8 V), and other switches (e.g., the switches 551, 552, 555, 556, 557, and 558) of the circuit 500 are designed to operate at lower voltages (e.g., switches having lower voltage ratings associated with the voltage level V4 of 5 V). In some embodiments, each switch of a respective set of switches (e.g., the set of switches 506 or the set of switches 508) is configured to operate at a distinct voltage level. For example, the switches 559, 551, 555, and 556 of the set of switches 506 are configured to operating at voltage levels of 8 V, 5 V, 10 V, and 2.5 V, respectively, which correspond to +VBOOST of 10 V, +PVDD of 5 V, and +VMID of 2.5 V. In some embodiments, a respective switch (e.g., a transistor) of the circuit 500 designed to operate at higher voltage(s) (e.g., 8 V) has a larger footprint (e.g., physical size) compared to another switch (e.g., a transistor) designed to operate at lower voltage(s) (e.g., 5 V). For example, the switch 559 may have a larger footprint compared to the switch 551. In some embodiments, only the switches 559, 560, 561, and 562 of the circuit 500 are configured to operate with a higher voltage level (e.g., V3), while the remaining switches are configured to operate with a lower voltage level (e.g., V4, V5, or V6). In this circumstance, the overall silicon area can be reduced, as high-voltage switches may require larger footprints. By restricting the number of high-voltage switches, this approach enables a more compact and cost-efficient circuit implementation, while preserving the full functionality of the multi-level class D amplifier. In some embodiments, implementing a combination of switches operating at different voltages can impact overall circuity efficiency. For example, in the absence of an 8 V transistor, a 10 V transistor must be used instead, which induces an efficiency penalty (e.g., increased gate capacitance, higher threshold voltage, etc.).

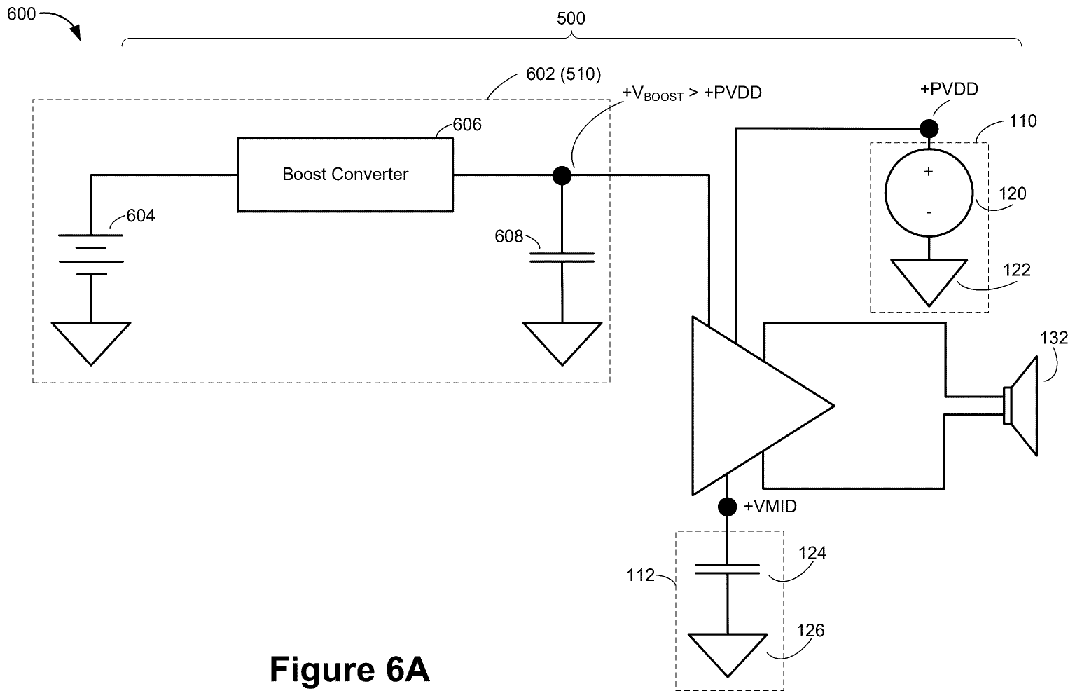

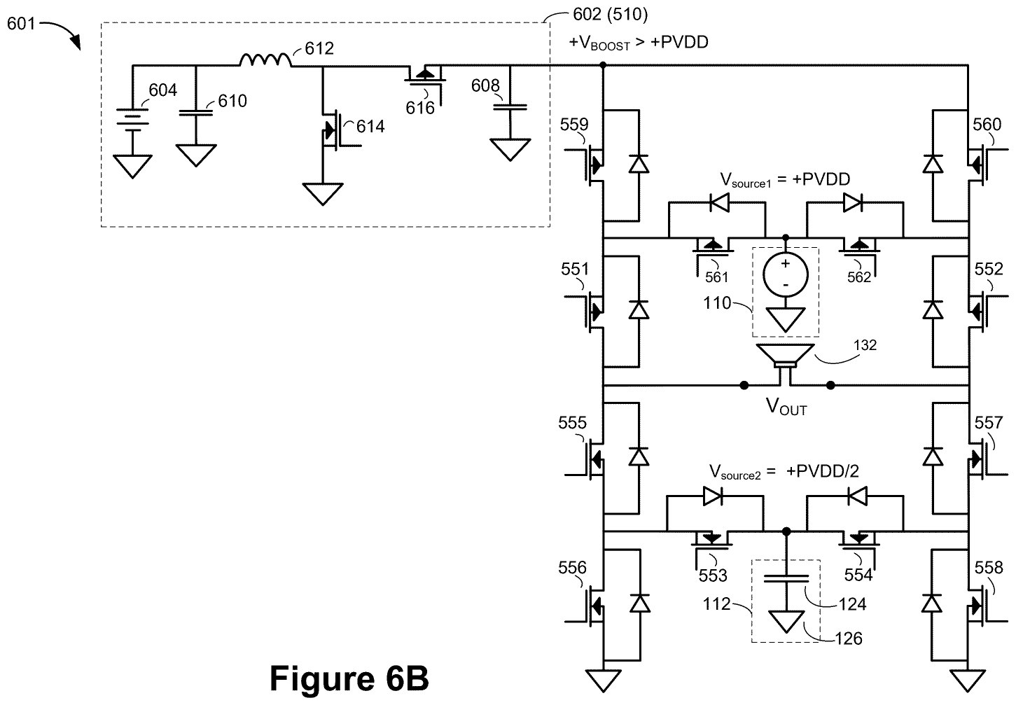

FIGS. 6A and 6B illustrate example multi-level amplification circuits 600 and 601 in which the power source 510 is configured as a boosted rail 602, in accordance with some embodiments. In some embodiments, the circuits 600 and 601 correspond to the circuit 500 and are configured as seven-level class D amplifiers. In some embodiments, each of the circuits 600 and 601 comprises the circuit 500. In some embodiments, an operation of a circuit (e.g., circuit 600 or circuit 601) using both boosted rail and battery rail may lead to increased power consumption compared to an operation using only battery rails. In some embodiments, the circuit 600 comprises the power sources 110 and 112 (e.g., in reference to FIGS. 1-3 and 5).

In some embodiments, the power source 510 of the circuit 500 comprises a battery voltage source 604, a boost converter 606, and a boost capacitor 608 (e.g., C_{BOOST}). In some embodiments, the boost converter 606 comprises an input capacitor 610 (e.g., C_{INPUT}), a boost inductor 612 (e.g., L_{BOOST}), a switch 614, and a switch 616. In some embodiments, the battery voltage source 604 is the power supply 120 (e.g., a voltage source, a battery) of the power source 110. In some embodiments, each of the switches 614 and 616 comprises a transistor. For example, the switch 614 is a N-channel MOSFET. In another example, the switch 616 is a P-channel MOSFET.

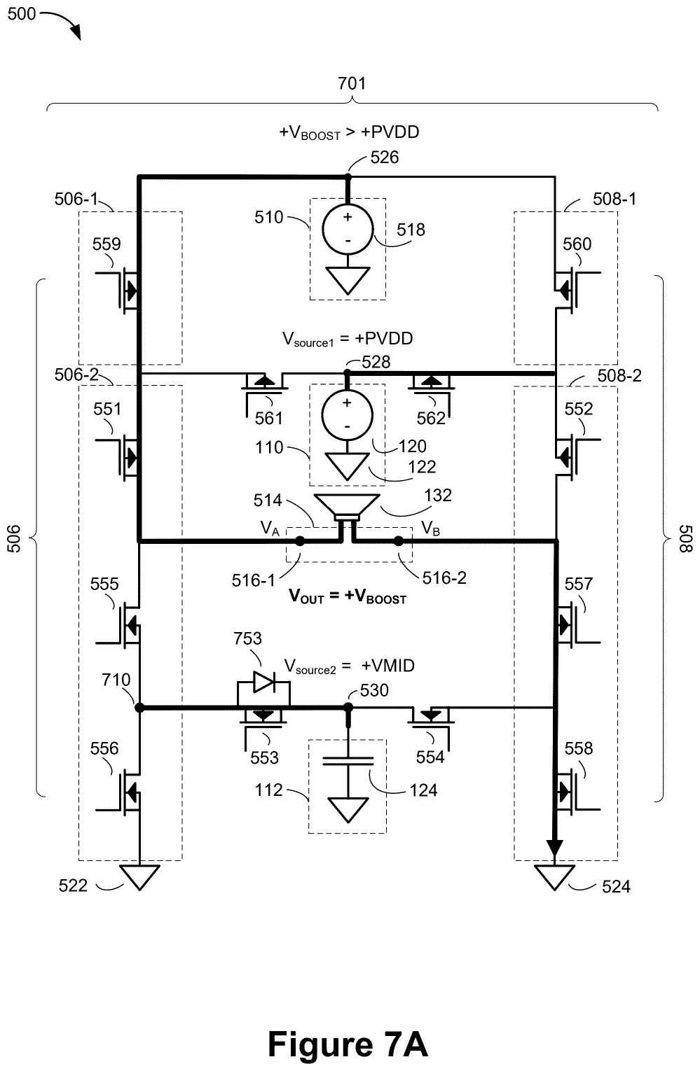

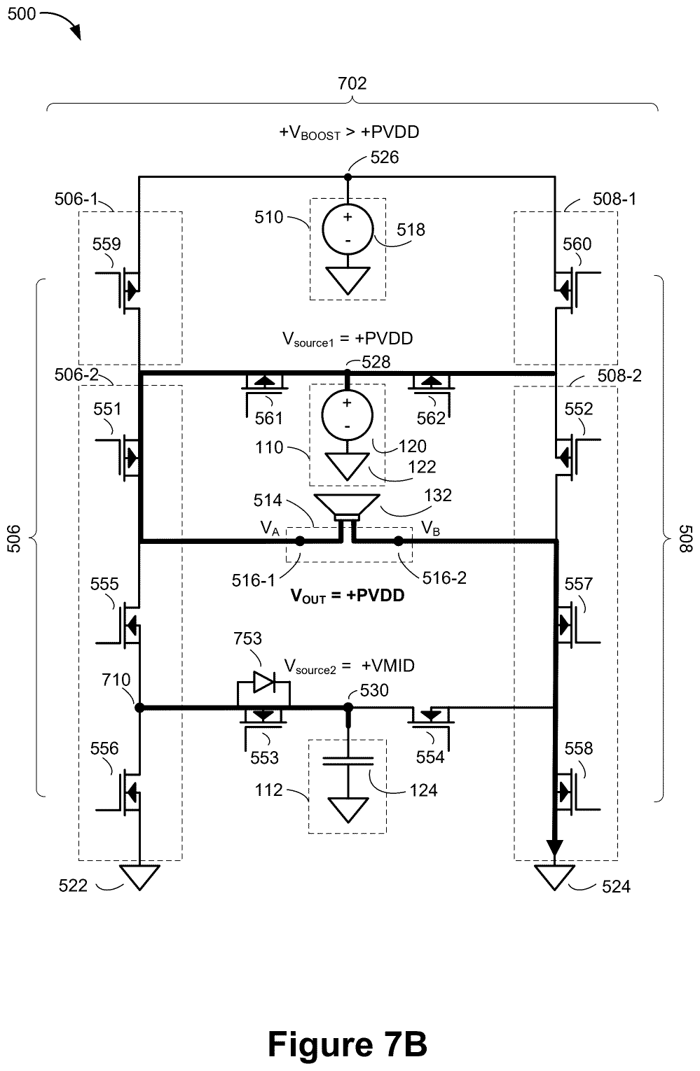

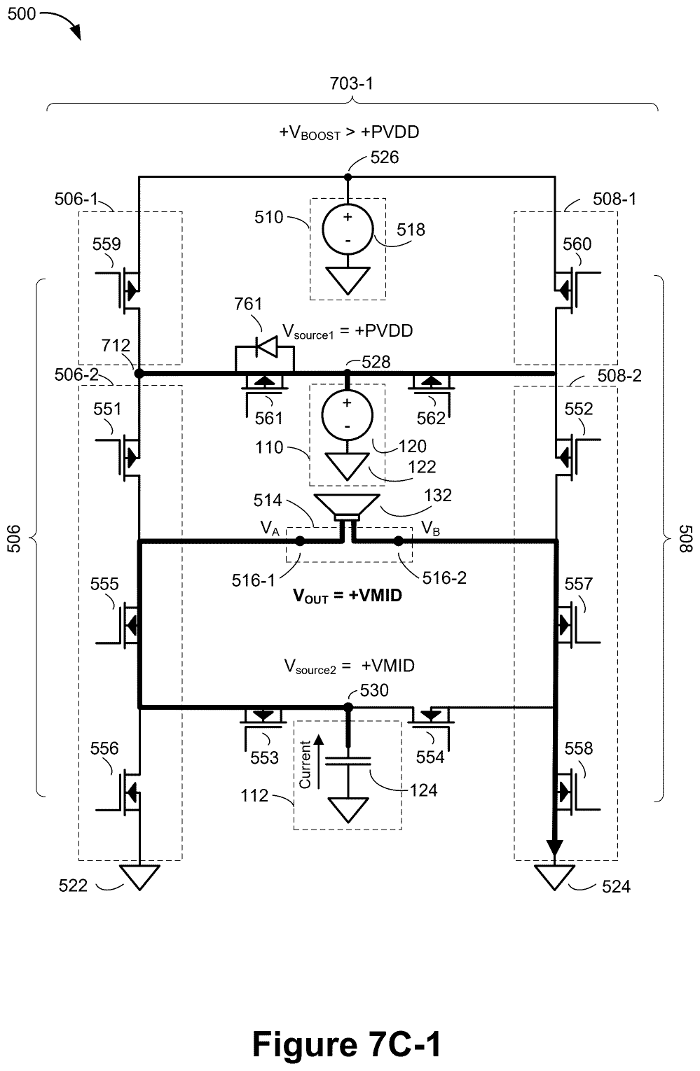

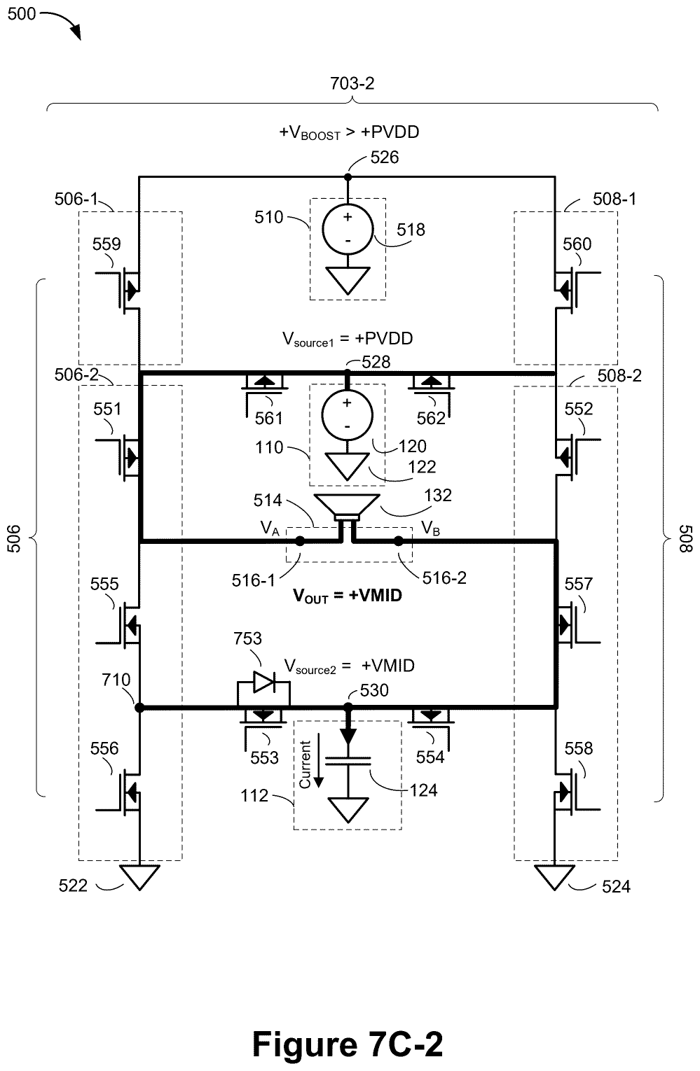

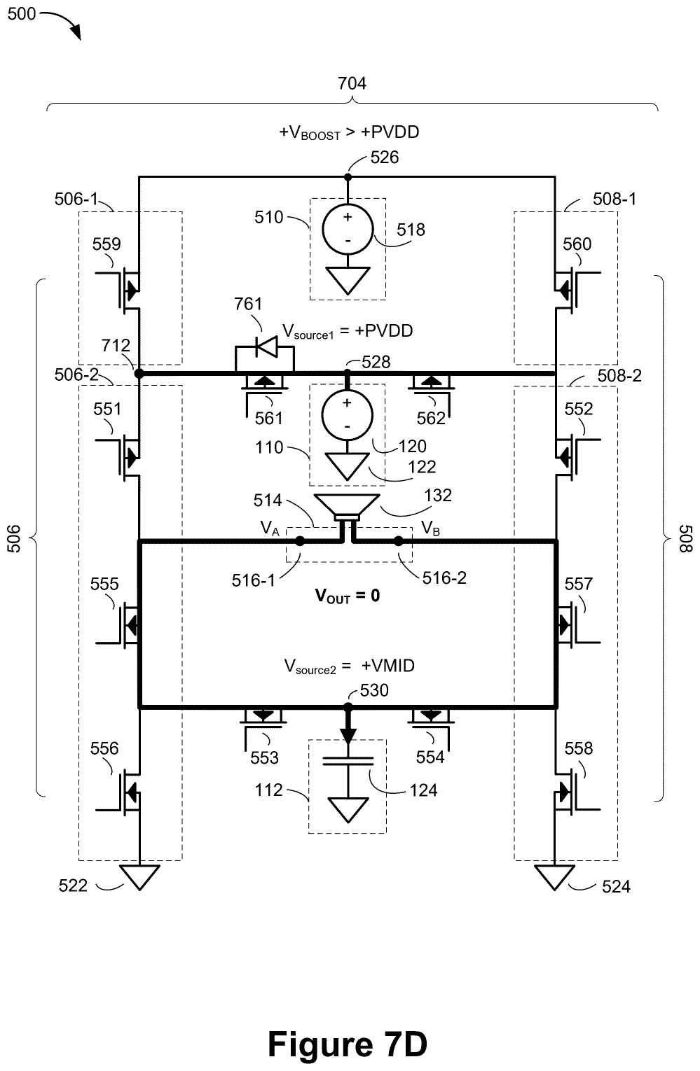

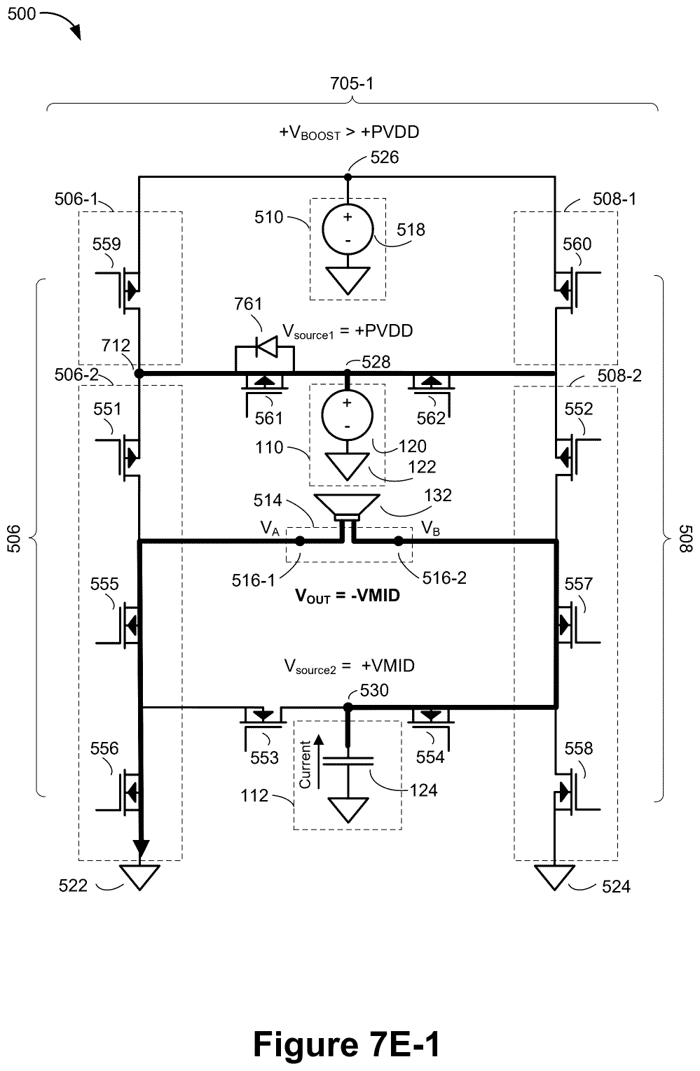

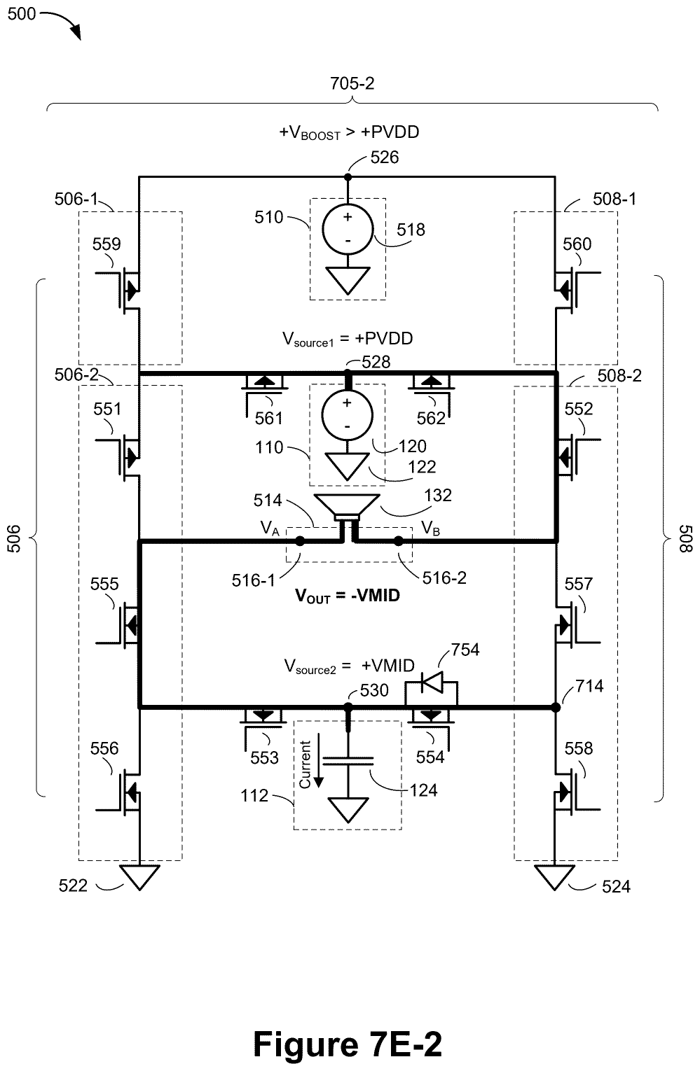

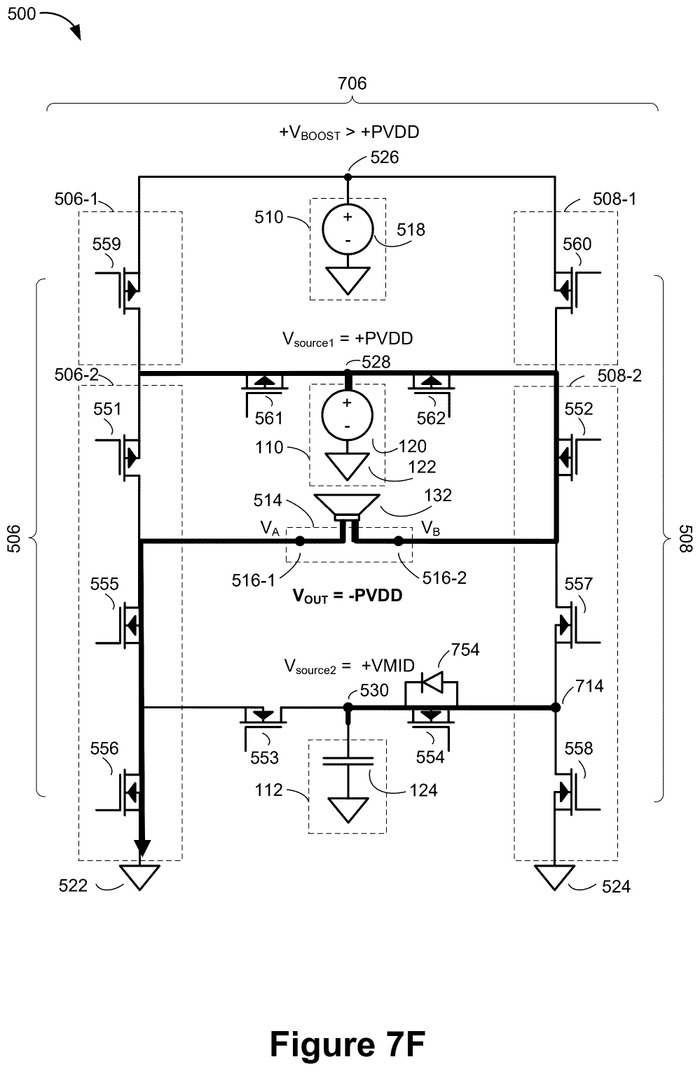

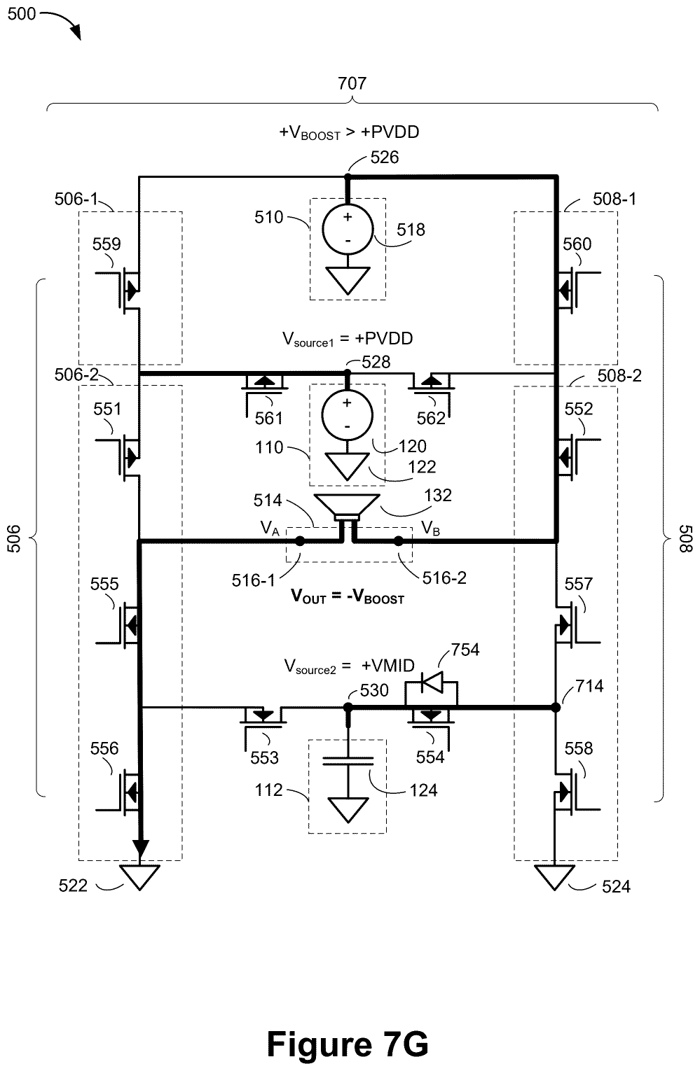

FIGS. 7A-7G illustrate example operating states of the circuit 500, in accordance with some embodiments. In some embodiments, the circuit 500 is configured to provide distinct voltage levels, e.g., +VBOOST, +PVDD, +VMID, 0, −VMID, −PVDD, −VBOOST, for the differential voltage V_{OUT}. In some embodiments, the boosted DC voltage +VBOOST 526 is maintained at +VBOOST (e.g., a boosted rail voltage). In some embodiments, the DC voltage V_{source1} 528 is maintained at +PVDD (e.g., a high-rail voltage). In some embodiments, the DC voltage V_{source2} 530 is maintained at +VMID (e.g., a mid-rail voltage) via the capacitor 124. In some embodiments, +VMID is equal to +PVDD/2. In some embodiments, a voltage level (e.g., the voltage level V3, V4, V5, or V6) of each switch of the circuit 500 is no less than a voltage applied across the respective switch (e.g., also referred to as stressed voltage). For example, when a switch is stressed at 5 V, a corresponding voltage level of the switch may be set to 5 V, 8 V or 10 V, which is no less than 5V. In some embodiments, during an operating state, one or more unused (e.g., inactive) switches of the circuit 500 become active (e.g., turned on) to maintain certain node(s) (e.g., nodes 710, 712, and/or 714 as discussed below) at desired voltage level(s) for minimizing voltage stress and/or preventing neighboring parasitic diode(s) (e.g., body diode(s)) from being active (e.g., turned on). This configuration ensures that (i) a corresponding voltage level (e.g., voltage rating) of a respective switch is not exceeded and (ii) a corresponding parasitic diode (e.g., a body diode) of the respective switch is not biased unexpectedly. In some embodiments, each switch of the circuit 500 includes a parasitic diode (e.g., a body diode). In some embodiments, during an operating state, current flows through parasitic diode(s) (e.g., body diode(s)) coupled to respective switch(es) of the circuit 500.

FIG. 7A illustrates an operating state 701 in which the circuit 500 is configured to provide a voltage level of +VBOOST (e.g., +VBOOST>+PVDD) for the differential voltage V_{OUT} at the output interface 514, e.g., the voltage V_{A} at the terminal 516-1 equal to +VBOOST and the voltage V_{B} at the terminal 516-2 equal to zero. In some embodiments, the voltage level of +VBOOST for the differential voltage V_{OUT} is provided in accordance with (i) the switches 559 and 551 of the set of switches 506 being active (e.g., in a closed state such that current is flowing through the switches 559 and 551) and (ii) the switches 557 and 558 of the set of switches 508 being active (e.g., in a closed state such that current is flowing through the switches 557 and 558). In this circumstance, the switches 559 and 551 are turned on to connect the power source 510 to the terminal 516-1 and are stressed at 0 V. The switches 557 and 558 are turned on to connect the electrical ground 524 to the terminal 516-2 and are stressed at 0 V. All other switches (e.g., the switches 552, 553, 554, 555, 556, 560, 561, and 562) in the circuit 500 are inactive (e.g., in an open state such that current cannot flow through the switches 552, 553, 554, 555, 556, 560, 561, and 562). Accordingly, the switches 552, 553, 554, 555, 556, 560, 561, and 562 are stressed at: +VBOOST/2, +VBOOST/2−+VMID, +VMID, +VBOOST/2, +VBOOST/2, +VBOOST/2, +VBOOST−+PVDD, and +VBOOST/2−+PVDD, respectively. In some embodiments, the voltage level of +VBOOST has the first polarity (e.g., a positive polarity relative to a common ground or reference potential). In some embodiments, in the operating state 701, the switches 553 and 562, which are unused (e.g., inactive) switches, become active (e.g., turned on), such that the switches 552, 553, 554, 555, 556, 560, 561, and 562 are stressed at: +PVDD, 0, +VMID, +VBOOST−+VMID, +VMID, +VBOOST−+PVDD, +VBOOST−+PVDD, and 0, respectively. In one circumstance, for example, the voltage stress on the switch 556 may be reduced from +VBOOST/2 to +VMID, e.g., when +VBOOST/2 is greater than +VMID. In another circumstance, for example, a voltage level of a node 710 (e.g., between the switches 555 and 556) is actively maintained at +VMID, thereby preventing a parasitic diode 753 of the switch 553 from being active (e.g., turned on) and clamped to approximately one diode drop (e.g., +0.7 V) above +VMID.

FIG. 7B illustrates an operating state 702 in which the circuit 500 is configured to provide a voltage level of +PVDD for the differential voltage V_{OUT} at the output interface 514, e.g., the voltage V_{A} at the terminal 516-1 equal to +PVDD and the voltage V_{B} at the terminal 516-2 equal to zero. In some embodiments, the voltage level of +PVDD for the differential voltage V_{OUT} is provided in accordance with (i) the switch 551 of the set of switches 506 being active (e.g., in a closed state such that current is flowing through the switch 551), (ii) the switches 557 and 558 of the set of switches 508 being active (e.g., in a closed state such that current is flowing through the switches 557 and 558), and (iii) the switch 561 being active (e.g., in a closed state such that current is flowing through the switch 561). In this circumstance, the switches 551 and 561 are turned on to connect the power source 110 to the terminal 516-1 and are stressed at 0 V. The switches 557 and 558 are turned on to connect the electrical ground 524 to the terminal 516-2 and are stressed at 0 V. All other switches (e.g., the switches 552, 553, 554, 555, 556, 559, 560, and 562) in the circuit 500 are inactive (e.g., in an open state such that current cannot flow through the switches 552, 553, 554, 555, 556, 559, 560, and 562). Accordingly, the switches 552, 553, 554, 555, 556, 559, 560, and 562 are stressed at: +VBOOST/2, +PVDD/2−+VMID, +VMID, +PVDD/2, +PVDD/2, +VBOOST−+PVDD, +VBOOST/2, and +VBOOST/2−+PVDD, respectively. In some embodiments, the voltage level of +PVDD has the first polarity (e.g., a positive polarity relative to a common ground or reference potential). In some embodiments, in the operating state 702, the switches 553 and 562, which are unused (e.g., inactive) switches, become active (e.g., turned on), such that the switches 552, 553, 554, 555, 556, 559, 560, and 562 are stressed at: +PVDD, 0, +VMID, +PVDD−+VMID, +VMID, +VBOOST−+PVDD, +VBOOST−+PVDD, and 0, respectively. In one circumstance, for example, the voltage stress on the switch 556 may be reduced from +PVDD/2 to +VMID, e.g., when +PVDD/2 is greater than +VMID. In another circumstance, for example, a voltage level of the node 710 (e.g., between the switches 555 and 556) is actively maintained at +VMID, thereby preventing the parasitic diode 753 of the switch 553 from being active (e.g., turned on) and clamped to approximately one diode drop (e.g., +0.7 V) above +VMID.

FIG. 7C-1 illustrates an operating state 703-1 in which the circuit 500 is configured to provide a voltage level of +VMID for the differential voltage V_{OUT} at the output interface 514, e.g., the voltage V_{A} at the terminal 516-1 equal to +VMID and the voltage V_{B} at the terminal 516-2 equal to zero. In some embodiments, the voltage level of +VMID for the differential voltage V_{OUT} is provided in accordance with (i) the switch 555 of the set of switches 506 being active (e.g., in a closed state such that current is flowing through the switch 555), (ii) the switches 557 and 558 of the set of switches 508 being active (e.g., in a closed state such that current is flowing through the switches 557 and 558), and (iii) the switch 553 being active (e.g., in a closed state such that current is flowing through the switch 553). In this circumstance, the switches 553 and 555 are turned on to connect the power source 112 to the terminal 516-1 and are stressed at 0 V. The switches 557 and 558 are turned on to connect the electrical ground 524 to the terminal 516-2 and are stressed at 0 V. All other switches (e.g., the switches 551, 552, 554, 556, 559, 560, 561, and 562) in the circuit 500 are inactive (e.g., in an open state such that current cannot flow through the switches 551, 552, 554, 556, 559, 560, 561, and 562). Accordingly, the switches 551, 552, 554, 556, 559, 560, 561, and 562 are stressed at: (+VBOOST−+VMID)/2, +VBOOST/2, +VMID, +VMID, (+VBOOST−+VMID)/2, +VBOOST/2, (+VBOOST++VMID)/2−+PVDD, and +VBOOST/2−+PVDD, respectively. In some embodiments, the voltage level of +VMID has the first polarity (e.g., a positive polarity relative to a common ground or reference potential). In some embodiments, in the operating state 703-1, the switches 561 and 562, which are unused (e.g., inactive) switches, become active (e.g., turned on), such that the switches 551, 552, 554, 556, 559, 560, 561, and 562 are stressed at: +PVDD−+VMID, +PVDD, +VMID, +VMID, +VBOOST−+PVDD, +VBOOST−+PVDD, 0, and 0, respectively. In one circumstance, for example, the voltage stress on the switch 551 may be reduced from (+VBOOST−+VMID)/2 to +PVDD−+VMID, e.g., when (+VBOOST−+VMID)/2 is greater than +PVDD−+VMID. In another circumstance, for example, a voltage level of a node 712 (e.g., between the switches 551 and 559) is actively maintained at +PVDD, thereby preventing a parasitic diode 761 of the switch 561 from being active (e.g., turned on) and clamped to approximately one diode drop (e.g., +0.7 V) above +PVDD. In some embodiments, while in the operating state 703-1, the circuit 500 discharges the capacitor 124 of the power source 112 through a current, e.g., the current that flows through the load 132 pulls (e.g., removes) charge from the capacitor 124. In some embodiments, the DC voltage V_{source2} 530 is maintained at +VMID (e.g., a mid-rail voltage) via switching (e.g., transitioning) to the operating state 703-1, which pulls (e.g., removes) charge from the capacitor 124. For example, when the differential voltage V_{OUT} is required to be +VMID and the DC voltage V_{source2} 530 is higher than +VMID, the circuit 500 is switched (e.g., transitioned) to the operating state 703-1 to pull (e.g., remove) charge from the capacitor 124.

FIG. 7C-2 illustrates an operating state 703-2 in which the circuit 500 is configured to provide a voltage level of +VMID for the differential voltage V_{OUT} at the output interface 514, e.g., the voltage V_{A} at the terminal 516-1 equal to +PVDD and the voltage V_{B} at the terminal 516-2 equal to +VMID (e.g., when +VMID equal to +PVDD/2). In some embodiments, the voltage level of +VMID for the differential voltage V_{OUT} is provided in accordance with (i) the switch 551 of the set of switches 506 being active (e.g., in a closed state such that current is flowing through the switch 551), (ii) the switch 557 of the set of switches 508 being active (e.g., in a closed state such that current is flowing through the switch 557), and (iii) the switches 554 and 561 being active (e.g., in a closed state such that current is flowing through the switches 554 and 561). In this circumstance, the switches 551 and 561 are turned on to connect the power source 110 to the terminal 516-1 and are stressed at 0 V. The switches 554 and 557 are turned on to connect the electrical ground 524 to the terminal 516-2 and are stressed at 0 V. All other switches (e.g., the switches 552, 553, 555, 556, 558, 559, 560, and 562) in the circuit 500 are inactive (e.g., in an open state such that current cannot flow through the switches 552, 553, 555, 556, 558, 559, 560, and 562). Accordingly, the switches 552, 553, 555, 556, 558, 559, 560, and 562 are stressed at: (+VBOOST−+VMID)/2, +PVDD/2−+VMID, +PVDD/2, +PVDD/2, +VMID, +VBOOST/2, +VBOOST−+PVDD, (+VBOOST−+VMID)/2, and (+VBOOST−+VMID)/2−+PVDD, respectively. In some embodiments, the voltage level of +VMID has the first polarity (e.g., a positive polarity relative to a common ground or reference potential). In some embodiments, in the operating state 703-2, the switches 553 and 562, which are unused (e.g., inactive) switches, become active (e.g., turned on), such that the switches 552, 553, 555, 556, 558, 559, 560, and 562 are stressed at: +PVDD−+VMID, 0, +PVDD −+VMID, +VMID, +VMID, +VBOOST−+PVDD, +VBOOST−+PVDD, and 0, respectively. In one circumstance, for example, the voltage stress on the switch 555 may be reduced from +PVDD/2 to +PVDD−+VMID, e.g., when +PVDD/2 is greater than +PVDD−+VMID. In another circumstance, for example, a voltage level of the node 710 (e.g., between the switches 555 and 556) is actively maintained at +VMID, thereby preventing the parasitic diode 753 of the switch 553 from being active (e.g., turned on) and clamped to approximately one diode drop (e.g., +0.7 V) above +VMID. In some embodiments, while in the operating state 703-2, the circuit 500 charges the capacitor 124 of the power source 112 through a current, e.g., the current that flows through the load 132 adds charge from the capacitor 124. In some embodiments, the DC voltage V_{source2} 530 is maintained at +VMID (e.g., a mid-rail voltage) via switching (e.g., transitioning) to the operating state 703-2, which adds charge from the capacitor 124. For example, when the differential voltage V_{OUT} is required to be +VMID and the DC voltage V_{source2} 530 is lower than +VMID, the circuit 500 is switched (e.g., transitioned) to the operating state 703-2 to add charge from the capacitor 124.

FIG. 7D illustrates an operating state 704 in which the circuit 500 is configured to provide a voltage level of zero for the differential voltage V_{OUT} at the output interface 514, e.g., the voltage V_{A} at the terminal 516-1 equal to +VMID and the voltage V_{B} at the terminal 516-2 equal to +VMID. In some embodiments, the voltage level of zero for the differential voltage V_{OUT} is provided in accordance with (i) the switch 555 of the set of switches 506 being active (e.g., in a closed state such that current is flowing through the switch 555), (ii) the switch 557 of the set of switches 508 being active (e.g., in a closed state such that current is flowing through the switch 557), and (iii) the switches 553 and 554 being active (e.g., in a closed state such that current is flowing through the switches 553 and 554). In this circumstance, the switches 553 and 555 are turned on to connect the power source 112 to the terminal 516-1 and are stressed at 0 V. The switches 554 and 557 are turned on to connect the power source 112 to the terminal 516-2 and are stressed at 0 V. All other switches (e.g., the switches 551, 552, 556, 558, 559, 560, 561, and 562) in the circuit 500 are inactive (e.g., in an open state such that current cannot flow through the switches 551, 552, 556, 558, 559, 560, 561, and 562). Accordingly, the switches 551, 552, 556, 558, 559, 560, 561, and 562 are stressed at: (+VBOOST−+VMID)/2, (+VBOOST−+VMID)/2, +VMID, +VMID, (+VBOOST−+VMID)/2, (+VBOOST−+VMID)/2, (+VBOOST++VMID)/2−+PVDD, and (+VBOOST++VMID)/2−+PVDD, respectively. In some embodiments, in the operating state 704, the switches 561 and 562, which are unused (e.g., inactive) switches, become active (e.g., turned on), such that the switches 551, 552, 556, 558, 559, 560, 561, and 562 are stressed at: +PVDD−+VMID, +PVDD −+VMID, +VMID, +VMID, +VBOOST−+PVDD, +VBOOST−+PVDD, 0, and 0, respectively. In one circumstance, for example, the voltage stress on the switch 552 may be reduced from (+VBOOST−+VMID)/2 to +PVDD−+VMID, e.g., when (+VBOOST−+VMID)/2 is greater than +PVDD−+VMID. In another circumstance, for example, a voltage level of the node 712 (e.g., between the switches 551 and 559) is actively maintained at +PVDD, thereby preventing the parasitic diode 761 of the switch 561 from being active (e.g., turned on) and clamped to approximately one diode drop (e.g., +0.7 V) above +PVDD.

FIG. 7E-1 illustrates an operating state 705-1 in which the circuit 500 is configured to provide a voltage level of −VMID for the differential voltage V_{OUT} at the output interface 514, e.g., the voltage V_{A} at the terminal 516-1 equal to zero and the voltage V_{B} at the terminal 516-2 equal to +VMID. In some embodiments, the voltage level of +VMID for the differential voltage V_{OUT} is provided in accordance with (i) the switches 555 and 556 of the set of switches 506 being active (e.g., in a closed state such that current is flowing through the switches 555 and 556), (ii) the switch 557 of the set of switches 508 being active (e.g., in a closed state such that current is flowing through the switch 557), and (iii) the switch 554 being active (e.g., in a closed state such that current is flowing through the switch 554). In this circumstance, The switches 555 and 556 are turned on to connect the electrical ground 522 to the terminal 516-1 and are stressed at 0 V. The switches 554 and 557 are turned on to connect the power source 112 to the terminal 516-2 and are stressed at 0 V. All other switches (e.g., the switches 551, 552, 553, 558, 559, 560, 561, and 562) in the circuit 500 are inactive (e.g., in an open state such that current cannot flow through the switches 551, 552, 553, 558, 559, 560, 561, and 562). Accordingly, the switches 551, 552, 553, 558, 559, 560, 561, and 562 are stressed at +VBOOST/2, (+VBOOST−+VMID)/2, +VMID, +VMID, +VBOOST/2, (+VBOOST−+VMID)/2, +VBOOST/2−+PVDD, and (+VBOOST++VMID)/2−+PVDD, respectively. In some embodiments, the voltage level of −VMID has the second polarity (e.g., a negative polarity relative to a common ground or reference potential). In some embodiments, in the operating state 705-1, the switches 561 and 562, which are unused (e.g., inactive) switches, become active (e.g., turned on), such that the switches 551, 552, 553, 558, 559, 560, 561, and 562 are stressed at: +PVDD, +PVDD−+VMID, +VMID, +VMID, +VBOOST−+PVDD, +VBOOST−+PVDD, 0, and 0, respectively. In one circumstance, for example, the voltage stress on the switch 552 may be reduced from (+VBOOST−+VMID)/2 to +PVDD−+VMID, e.g., when (+VBOOST−+VMID)/2 is greater than +PVDD−+VMID. In another circumstance, for example, a voltage level of the node 712 (e.g., between the switches 551 and 559) is actively maintained at +PVDD, thereby preventing the parasitic diode 761 of the switch 561 from being active (e.g., turned on) and clamped to approximately one diode drop (e.g., +0.7 V) above +PVDD. In some embodiments, while in the operating state 705-1, the circuit 500 discharges the capacitor 124 of the power source 112 through a current, e.g., the current that flows through the load 132 pulls (e.g., removes) charge from the capacitor 124. In some embodiments, the DC voltage V_{source2} 530 is maintained at +VMID (e.g., a mid-rail voltage) via switching (e.g., transitioning) to the operating state 705-1, which pulls (e.g., removes) charge from the capacitor 124. For example, when the differential voltage V_{OUT} is required to be-VMID and the DC voltage V_{source2} 530 is higher than +VMID, the circuit 500 is switched (e.g., transitioned) to the operating state 703-1 to pull (e.g., remove) charge from the capacitor 124.

FIG. 7E-2 illustrates an operating state 705-2 in which the circuit 500 is configured to provide a voltage level of −VMID for the differential voltage V_{OUT} at the output interface 514, e.g., the voltage V_{A} at the terminal 516-1 equal to +VMID and the voltage V_{B} at the terminal 516-2 equal to +PVDD (e.g., when +VMID equal to +PVDD/2). In some embodiments, the voltage level of +VMID for the differential voltage V_{OUT} is provided in accordance with (i) the switch 555 of the set of switches 506 being active (e.g., in a closed state such that current is flowing through the switch 555), (ii) the switch 552 of the set of switches 508 being active (e.g., in a closed state such that current is flowing through the switch 552), and (iii) the switches 553 and 562 being active (e.g., in a closed state such that current is flowing through the switches 553 and 562). In this circumstance, The switches 552 and 562 are turned on to connect the power source 112 to the terminal 516-1 and are stressed at 0 V. The switches 553 and 555 are turned on to connect the power source 110 to the terminal 516-2 and are stressed at 0 V. All other switches (e.g., the switches 551, 554, 556, 557, 558, 559, 560, and 561) in the circuit 500 are inactive (e.g., in an open state such that current cannot flow through the switches 551, 554, 556, 557, 558, 559, 560, and 561). Accordingly, the switches 551, 554, 556, 557, 558, 559, 560, and 561 are stressed at (+VBOOST−+VMID)/2, +PVDD/2−+VMID, +VMID, +PVDD/2, +PVDD/2, (+VBOOST−+VMID)/2, +VBOOST−+PVDD, and (+VBOOST++VMID)/2−+PVDD, respectively. In some embodiments, the voltage level of −VMID has the second polarity (e.g., a negative polarity relative to a common ground or reference potential). In some embodiments, in the operating state 705-2, the switches 554 and 561, which are unused (e.g., inactive) switches, become active (e.g., turned on), such that the switches 551, 554, 556, 557, 558, 559, 560, and 561 are stressed at: +PVDD−+VMID, 0, +VMID, +PVDD−+VMID, +VMID, +VBOOST−+PVDD, +VBOOST−+PVDD, and 0, respectively. In one circumstance, for example, the voltage stress on the switch 557 may be reduced from +PVDD/2 to +PVDD−+VMID, e.g., when +PVDD/2 is greater than +PVDD−+VMID. In another circumstance, for example, a voltage level of a node 714 (e.g., between the switches 557 and 558) is actively maintained at +VMID, thereby preventing a parasitic diode 754 of the switch 554 from being active (e.g., turned on) and clamped to approximately one diode drop (e.g., +0.7 V) above +VMID. In some embodiments, while in the operating state 705-2, the circuit 500 charges the capacitor 124 of the power source 112 through a current, e.g., the current that flows through the load 132 adds charge from the capacitor 124. In some embodiments, the DC voltage V_{source2} 530 is maintained at +VMID (e.g., a mid-rail voltage) via switching (e.g., transitioning) to the operating state 705-2, which adds charge from the capacitor 124. For example, when the differential voltage V_{OUT} is required to be −VMID and the DC voltage V_{source2} 530 is lower than +VMID, the circuit 500 is switched (e.g., transitioned) to the operating state 705-2 to add charge to the capacitor 124.

FIG. 7F illustrates an operating state 706 in which the circuit 500 is configured to provide a voltage level of −PVDD for the differential voltage V_{OUT} at the output interface 514, e.g., the voltage V_{A} at the terminal 516-1 equal to zero and the voltage V_{B} at the terminal 516-2 equal to +PVDD. In some embodiments, the voltage level of −PVDD for the differential voltage V_{OUT} is provided in accordance with (i) the switches 555 and 556 of the set of switches 506 being active (e.g., in a closed state such that current is flowing through the switches 555 and 556), (ii) the switch 552 of the set of switches 508 being active (e.g., in a closed state such that current is flowing through the switch 552), and (iii) the switch 562 being active (e.g., in a closed state such that current is flowing through the switch 562). In this circumstance, the switches 555 and 556 are turned on to connect the electrical ground 522 to the terminal 516-1 and are stressed at 0 V. The switches 552 and 562 are turned on to connect the power source 110 to the terminal 516-2 and are stressed at 0 V. All other switches (e.g., the switches 551, 553, 554, 557, 558, 559, 560, and 561) in the circuit 500 are inactive (e.g., in an open state such that current cannot flow through the switches 551, 553, 554, 557, 558, 559, 560, and 561). Accordingly, the switches 551, 553, 554, 557, 558, 559, 560, and 561 are stressed at: +VBOOST/2, +VMID, +PVDD/2−+VMID, +PVDD/2, +PVDD/2, +VBOOST/2, +VBOOST−+PVDD, and +VBOOST/2−+PVDD, respectively. In some embodiments, the voltage level of −PVDD has the second polarity (e.g., a negative polarity relative to a common ground or reference potential). In some embodiments, in the operating state 706, the switches 554 and 561, which are unused (e.g., inactive) switches, become active (e.g., turned on), such that the switches 551, 553, 554, 557, 558, 559, 560, and 561 are stressed at: +PVDD, +VMID, 0, +PVDD−+VMID, +VMID, +VBOOST−+PVDD, +VBOOST−+PVDD, and 0, respectively. In one circumstance, for example, the voltage stress on the switch 558 may be reduced from +PVDD/2 to +VMID, e.g., when +PVDD/2 is greater than +VMID. In another circumstance, for example, a voltage level of the node 714 (e.g., between the switches 557 and 558) is actively maintained at +VMID, thereby preventing the parasitic diode 754 of the switch 554 from being active (e.g., turned on) and clamped to approximately one diode drop (e.g., +0.7 V) above +VMID.

FIG. 7G illustrates an operating state 707 in which the circuit 500 is configured to provide a voltage level of −VBOOST (e.g., −VBOOST<−PVDD) for the differential voltage V_{OUT} at the output interface 514, e.g., the voltage V_{A} at the terminal 516-1 equal to zero and the voltage V_{B} at the terminal 516-2 equal to +VBOOST. In some embodiments, the voltage level of −VBOOST for the differential voltage V_{OUT} is provided in accordance with (i) the switches 555 and 556 of the set of switches 506 being active (e.g., in a closed state such that current is flowing through the switches 555 and 556) and (ii) the switches 560 and 552 of the set of switches 508 being active (e.g., in a closed state such that current is flowing through the switches 560 and 552). In this circumstance, the switches 555 and 556 are turned on to connect the electrical ground 522 to the terminal 516-1 and are stressed at 0 V. The switches 560 and 552 are turned on to connect the power source 510 to the terminal 516-2 and are stressed at 0 V. All other switches (e.g., the switches 551, 553, 554, 557, 558, 559, 561, and 562) in the circuit 500 are inactive (e.g., in an open state such that current cannot flow through the switches 551, 553, 554, 557, 558, 559, 561, and 562). Accordingly, the switches 551, 553, 554, 557, 558, 559, 561, and 562 are stressed at: +VBOOST/2, +VMID, +VBOOST/2−+VMID, +VBOOST/2, +VBOOST/2, +VBOOST/2, +VBOOST/2−+PVDD, and +VBOOST−+PVDD, respectively. In some circumstances, voltage level of a node 710 (e.g., between the switches 557 and 558) is clamped by the parasitic diode 754 (e.g., a body diode) of the switch 554 to approximately one diode drop (e.g., +0.7 V) above the DC voltage V_{source2} 530. In some embodiments, the voltage level of −VBOOST has the second polarity (e.g., a negative polarity relative to a common ground or reference potential). In some embodiments, in the operating state 707, the switches 554 and 561, which are an unused (e.g., inactive) switches, become active (e.g., turned on), such that the switches 551, 553, 554, 557, 558, 559, 561, and 562 are stressed at: +PVDD, +VMID, 0, +VBOOST−+VMID, +VMID, +VBOOST−+PVDD, 0, and +VBOOST−+PVDD, respectively. In one circumstance, for example, the voltage stress on the switch 558 may be reduced from +VBOOST/2 to +VMID, e.g., when +VBOOST/2 is greater than +VMID. In another circumstance, for example, the voltage level of the node 714 (e.g., between the switches 557 and 558) is actively maintained at +VMID, thereby preventing it from being active (e.g., turned on) and clamped to approximately one diode drop (e.g., +0.7 V) above +VMID.

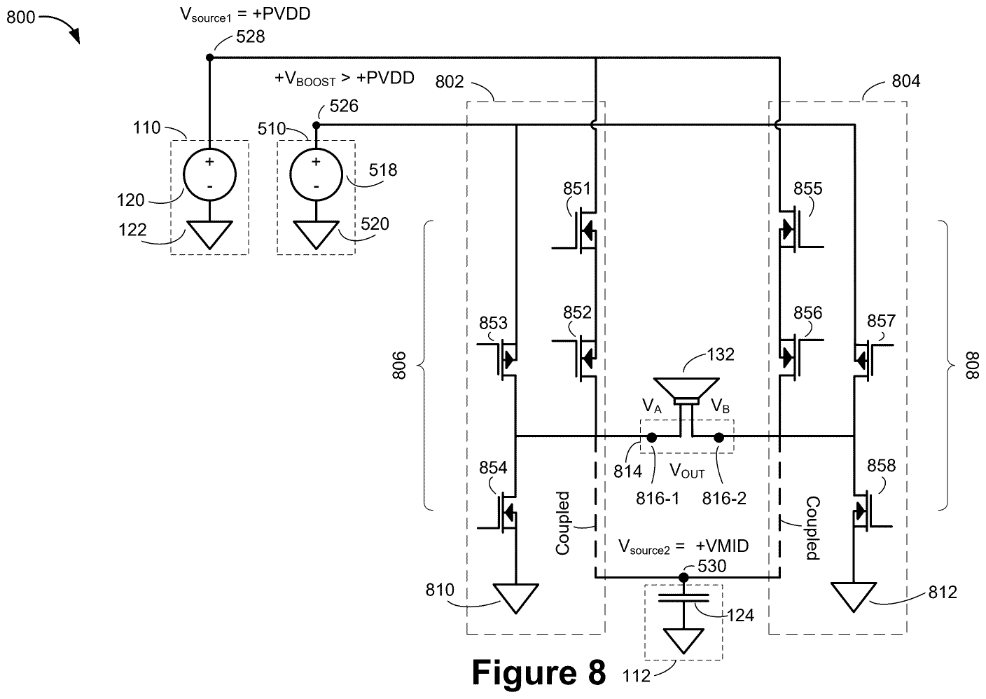

FIG. 8 illustrates another example multi-level amplification circuit 800 (e.g., corresponding to a multi-level class D amplifier), in accordance with some embodiments. In some embodiments, the circuit 800 facilitates multi-level modulation between a boosted rail (e.g., a +VBOOST rail, where +VBOOST>+PVDD) and a battery rail (e.g., a high voltage rail configured as a +PVDD rail), thereby enabling finer voltage resolution and improved modulation performance. The circuit 800 may be configured as a five-level class D amplifier or a seven-level class D amplifier. The circuit 800 may require a larger silicon area compared to the circuit 500 and/or the circuit 100.

In some embodiments, the circuit 800 comprises a half-bridge power stage 802 and a half-bridge power stage 804. The half-bridge power stage 802 includes a set of switches 806, and the half-bridge power stage 804 includes a set of switches 808. Similar to the circuit 500, the power source 110 (e.g., in reference to FIGS. 1-3 and 5-7G), the power source 510 (e.g., in reference to FIGS. 5-7G), and the power source 112 (e.g., in reference to FIGS. 1-3 and 5-7G) are coupled to the half-bridge power stages 802 and 804. The power source 510 is configured to supply the boosted DC voltage +VBOOST 526 (e.g., through a boosted voltage rail). The power source 110 is configured to supply the DC voltage V_{source1} 528 (e.g., through a voltage rail). An output interface 814 is coupled to the half-bridge power stages 802 and 804 and configured to couple to the load 132 (e.g., in reference to FIGS. 1-3 and 5-6B). The half-bridge power stages 802 and 804 of the circuit 800 are configured to generate a five-level and/or seven-level differential signal for driving the load 132. In some embodiments, the load 132 comprises a speaker load coupled to the output interface 814. In some embodiments, the half-bridge power stage 802 includes an electrical ground 810, and the half-bridge power stage 804 includes an electrical ground 812. In some embodiments, similar to the circuits 100 and 500, the circuit 800 is configured in an IC package. In some embodiments, the circuit 800 does not include a low voltage rail (e.g., the power source 112).

In some embodiments, the output interface 814 comprises terminals 816-1 and 816-2 that are coupled to the half-bridge power stages 802 and 804, respectively. In some embodiments, the terminal 816-1 receives a voltage V_{A} via the half-bridge power stage 802 and the terminal 816-2 receives a voltage V_{B} via the half-bridge power stage 804, such that the load 132 is powered by a differential voltage V_{OUT} (e.g., V_{OUT}=V_{A}−V_{B}) applied across the terminals 816-1 and 816-2.

In some embodiments, the set of switches 806 comprises switches 851, 852, 853, and 854. In some embodiments, the set of switches 808 comprises switches 855, 856, 857, and 858. In some embodiments, the power source 110 is coupled to the terminals and 816-1 and 816-2 via the switches 851 and 852 of the set of switches 806 and the switches 855 and 856 of the set of switches 808, respectively. In some embodiments, the power source 510 is coupled to the terminals and 816-1 and 816-2 via the switch 853 of the set of switches 806 and the switch 857 of the set of switches 808, respectively.

In some embodiments, the half-bridge power stages 802 and 804 of the circuit 800 comprise a same configuration of switches (e.g., number of switches, parameters of switches), e.g., similar to the half-bridge power stages 102 and 104 of the circuit 100 and the half-bridge power stages 502 and 504 of the circuit 500. In some embodiments, each switch of the circuit 800 comprises a transistor. In some embodiments, the sets of switches 806 and 808 comprise one or more MOSFETs (e.g., one or more N-channel MOSFETs and/or P-channel MOSFETs). In some embodiments, the sets of switches 806 and 808 comprise one or more BJTs (e.g., NPN BJTs, PNP BJTs) and/or FETs. In some embodiments, the switches 853 and 857 are implemented using the same type of switch devices (e.g., P-channel MOSFETs or PNP BJTs). In some embodiments, the switches 851, 852, 854, 855, 856, and 858 are implemented using the same type of switch devices (e.g., n-channel MOSFETs or NPN BJTs). In some embodiments, each switch of the circuit 800 includes a parasitic diode (e.g., a body diode).

In some embodiments, the switches 851, 852, 855, and 856 operate at a voltage level of 5 V. In some embodiments, the switches 853, 854, 857, and 858 operate at a voltage level of 10 V.

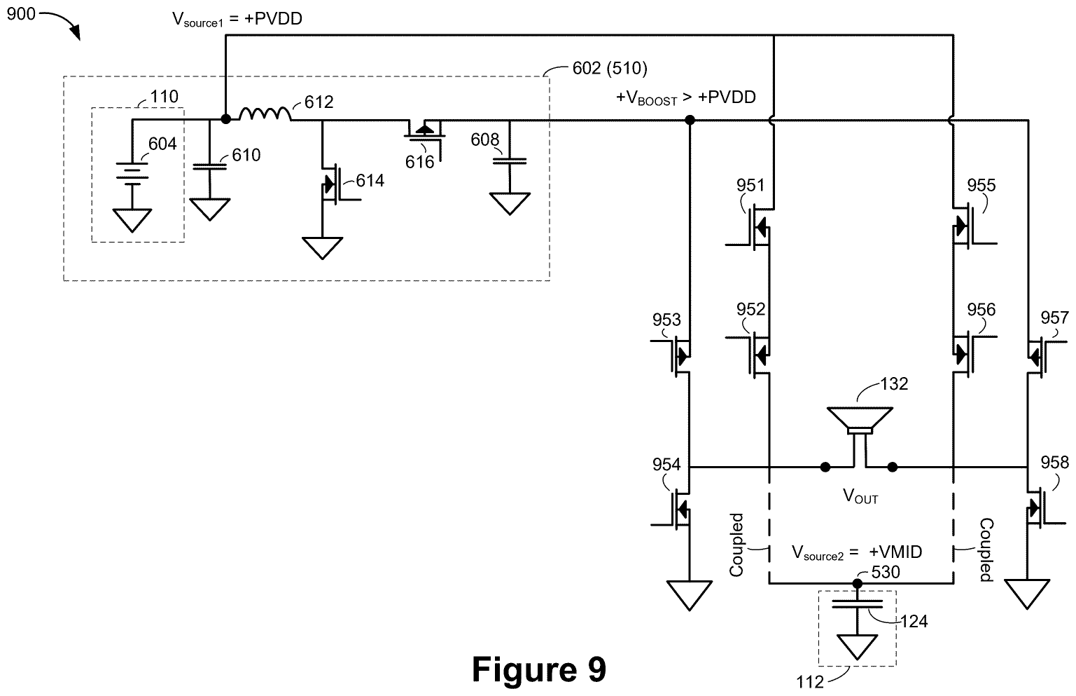

FIG. 9 illustrates an example multi-level amplification circuit 900 in which the power source 510 is configured as the boosted rail 602, in accordance with some embodiments. In some embodiments, the circuit 900 corresponds to the circuit 800 and is configured as seven-level class D amplifiers. In some embodiments, the circuit 900 comprises the circuit 800. In some embodiments, an operation of a circuit (e.g., the circuit 800) using both boosted rail and battery rail may lead to increased power consumption compared to an operation using only battery rails. In some embodiments, the configuration of the boosted rail 602 is configured in a manner that is substantially similar in the circuits 500 and 800. In some embodiments, the battery voltage source 604 is the power supply 120 (e.g., a voltage source, a battery) of the power source 110.

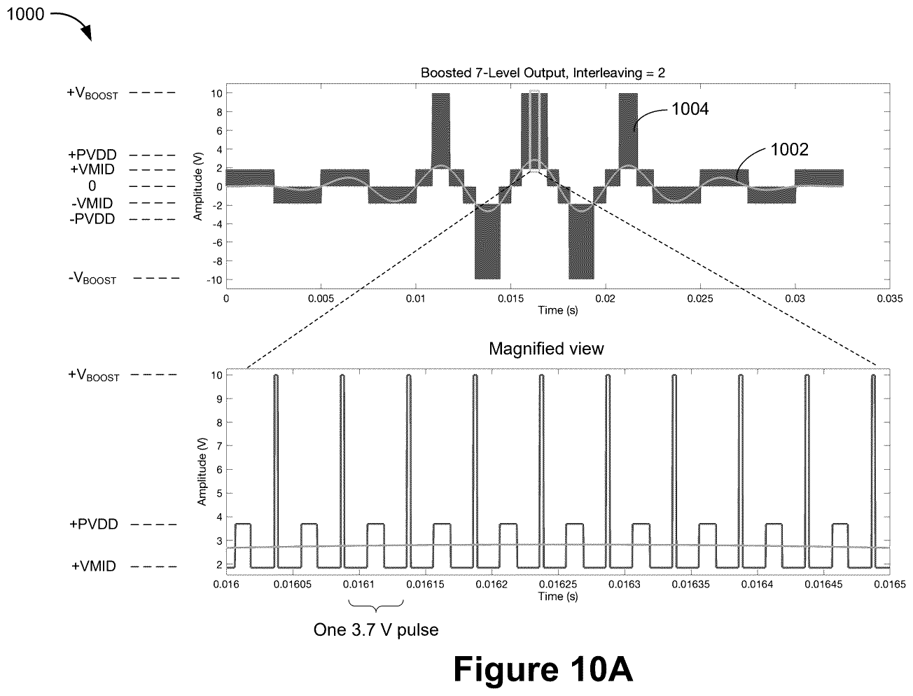

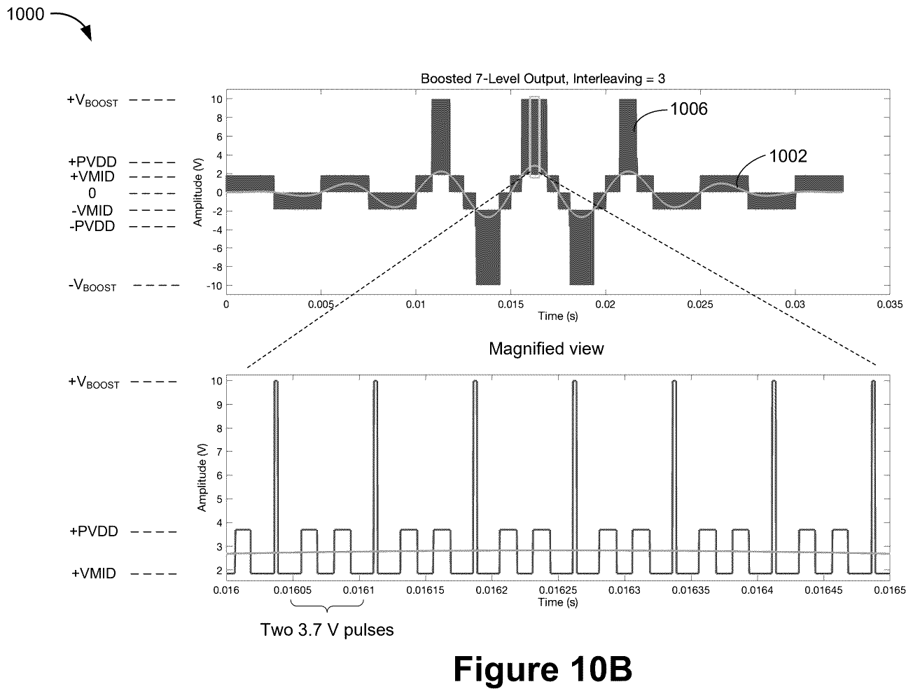

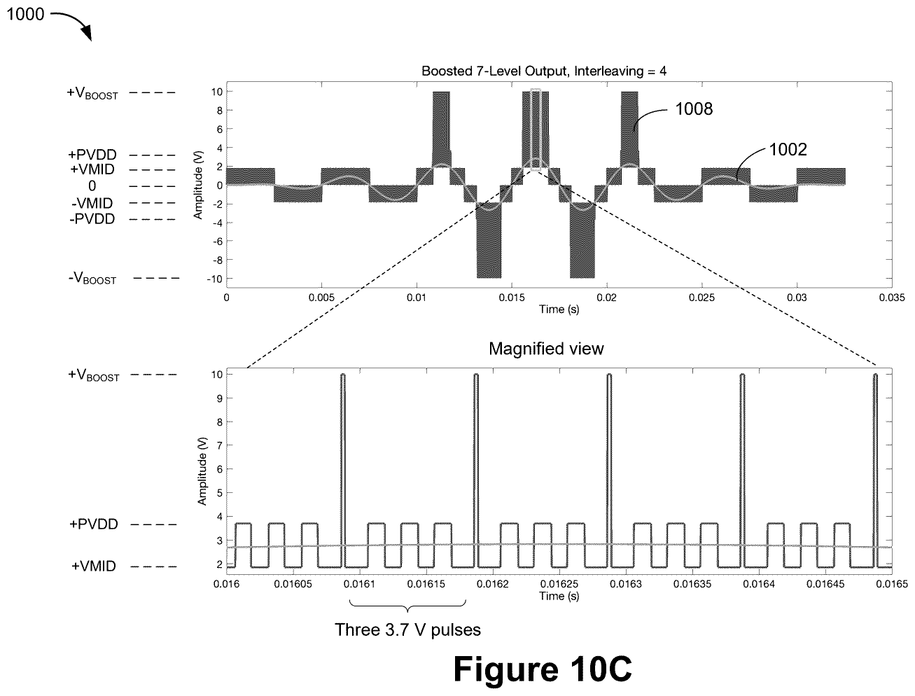

FIGS. 10A-10C illustrate example outputs 1000 generated by the circuit 500 (e.g., a seven-level class D amplifier), in accordance with some embodiments. The example outputs 1000 illustrate an interleaved operation based on a boosted rail (e.g., the boosted rail 602 that supplies +VBOOST>+PVDD) and a battery rail (e.g., the power source 110 that supplies +PVDD). As shown in FIGS. 10A-10C, example output signals 1004, 1006, and 1008 are generated by the circuit 500 at different levels of interleaving, respectively, in response to an input audio signal 1002. In some embodiments, the output signals 1004, 1006, and 1008 are PWM waveforms. In some embodiments, the output signals 1004, 1006, and 1008 can be generated by the circuit 800 and/or the circuit 900 that are configured as seven-level class D amplifiers. In some embodiments, +VBOOST is at 10.0 V, +PVDD is at 3.7 V, and +VMID is at 1.8 V.

In some embodiments, the interleaved operation reduces peak current demands on the battery rail, thereby improving power efficiency (e.g., for thermal management), lowering power supply noise, and mitigating large battery voltage drops that may cause system brownouts. In some embodiments, the output signal 1004 corresponds to an interleaving level of 2, e.g., each 10.0 V pulse is accompanied by one 3.7 V pulse. In some embodiments, the output signal 1006 corresponds to an interleaving level of 3, e.g., each 10.0 V pulse is accompanied by two 3.7 V pulses. In some embodiments, the output signal 1008 corresponds to an interleaving level of 4, e.g., each 10.0 V pulse is accompanied by three 3.7 V pulses. In some embodiments, a lower interleaving level (e.g., a level of 2) can provide an improved current draw smoothing compared to a higher interleaving level (e.g., a level of 4). For example, receiving more pulses from the boosted rail reduces current drawn from the battery rail during a transient, thereby improving current draw smoothing during transient events (e.g., transient events associated with an audio output of the load 132 for producing audio output waveforms).

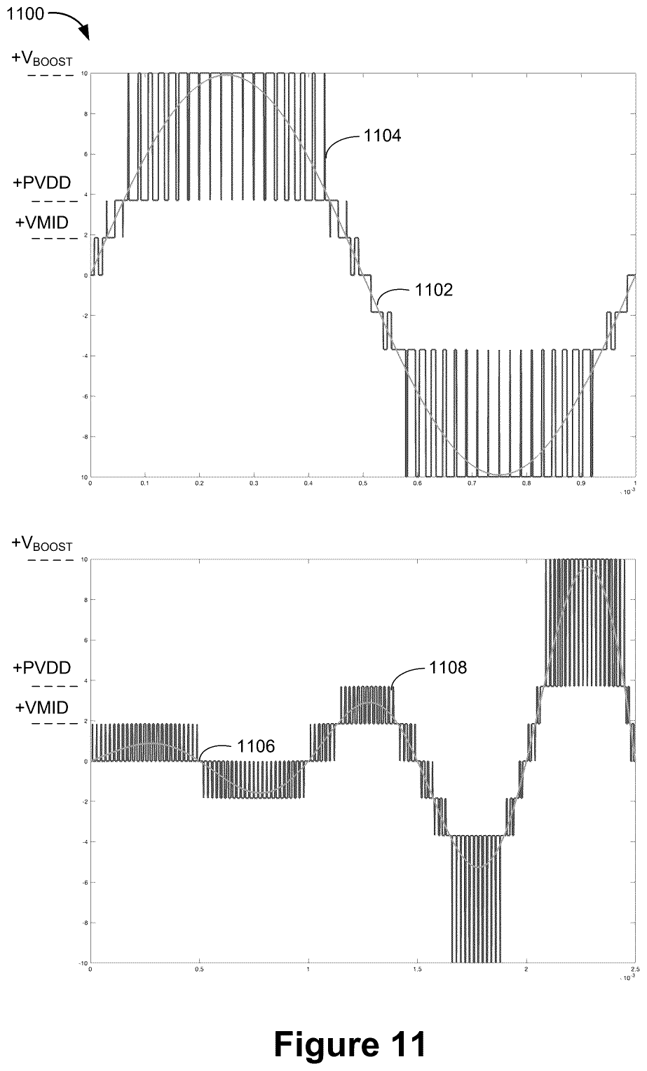

FIG. 11 illustrates another example outputs 1100 generated by the circuit 500 (e.g., a seven-level class D amplifier), in accordance with some embodiments. The example outputs 1100 illustrate an increased headroom based on a boosted rail (e.g., the boosted rail 602 that supplies +VBOOST>+PVDD) and a battery rail (e.g., the power source 110 that supplies +PVDD). As shown in FIG. 11, example output signals 1104 and 1108 are generated by the circuit 500 in response to input audio signals 1102 and 1106, respectively. In some embodiments, the output signals 1104 and 1108 are PWM waveforms. In some embodiments, the output signals 1104 and 1108 can be generated by the circuit 800 and/or the circuit 900 that are configured as seven-level class D amplifiers. In some embodiments, +VBOOST is at 10.0 V, +PVDD is at 3.7 V, and +VMID is at 1.8 V.

In some embodiments, the output signal 1104 is a static output in response to the input audio signal 1102 (e.g., a sinusoidal wave). In some embodiments, the output signal 1108 is an output with a magnitude increase in response to the input audio signal 1106 (e.g., a growing oscillation wave). In some embodiments, compared to the circuit 100, output signals 1104 and 1108 of the circuit 500 show an increased headroom (e.g., up to 10.0 V) enable by the boosted rail.

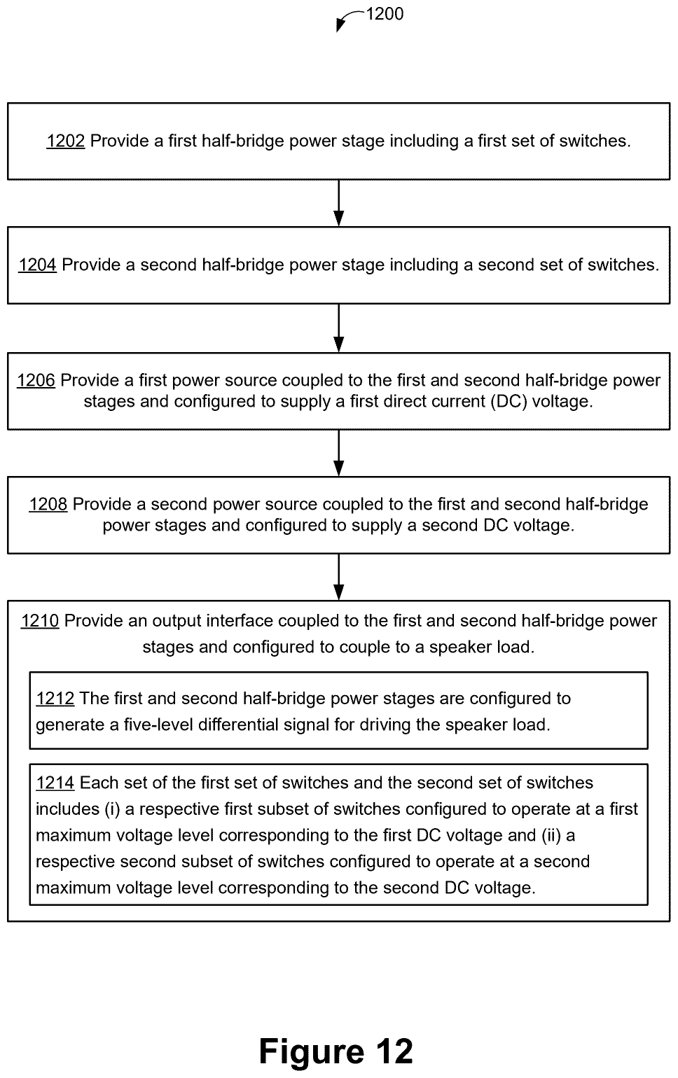

FIG. 12 illustrates a flow diagram of an example method 1200 of operating a multi-level amplification circuit (e.g., the circuit 100), in accordance with some embodiments. Operations (e.g., steps) of the method 1200 can be performed by a multi-level amplification circuit (e.g., a circuit of a device or system such as an XR device). At least some of the operations shown in FIG. 12 correspond to instructions stored in a computer memory or computer-readable storage medium (e.g., storage, RAM, and/or memory). Operations of the method 1200 can be performed by a single device alone or in conjunction with one or more processors and/or hardware components of another communicatively coupled device and/or instructions stored in memory or computer-readable medium of the other device communicatively coupled to the system. In some embodiments, the various operations of the methods described herein are interchangeable and/or optional, and respective operations of the methods are performed by any of the aforementioned devices, systems, or combination of devices and/or systems. For convenience, the method operations will be described below as being performed by particular component or device, but should not be construed as limiting the performance of the operation to the particular device in all embodiments.

(A1) The method 1200 occurs at a circuit (e.g., the circuit 100) configured as a multi-level class D amplifier (e.g., a five-level class D amplifier). In some embodiments, the method 1200 includes providing (1202) a first half-bridge power stage (e.g., the half-bridge power stage 102) including a first set of switches (e.g., the set of switches 106). The method 1200 further includes providing (1204) a second half-bridge power stage (e.g., the half-bridge power stage 104) including a second set of switches (e.g., the set of switches 108). The method 1200 further includes providing (1206) a first power source (e.g., the power source 110) coupled to the first and second half-bridge power stages (e.g., the half-bridge power stages 102 and 104) and configured to supply a first direct current (DC) voltage (e.g., +PVDD as a high-rail voltage). The method 1200 further includes providing (1208) a second power source (e.g., the power source 112) coupled to the first and second half-bridge power stages (e.g., the half-bridge power stages 102 and 104) and configured to supply a second DC voltage (e.g., +PVDD/2 as a low-rail voltage). The method 1200 further includes providing (1210) an output interface (e.g., the output interface 114 having terminals 116-1 and 116-2) coupled to the first and second half-bridge power stages (e.g., the half-bridge power stages 102 and 104) and configured to couple to a speaker load (e.g., the load 132). The first and second half-bridge power stages (e.g., the half-bridge power stages 102 and 104) are configured to generate (1212) a five-level differential signal (e.g., +PVDD, +PVDD/2, 0, −PVDD/2, −PVDD) for driving the speaker load (e.g., the load 132). Each set of the first set of switches (e.g., the set of switches 106) and the second set of switches (e.g., the set of switches 108) includes (1214) (i) a respective first subset of switches (e.g., the switch 151 of the subset of switches 106-1, or the switch 152 of the subset of switches 108-1) configured to operate at a first voltage level (e.g., V1) corresponding to the first DC voltage (e.g., +PVDD as a high-rail voltage) and (ii) a respective second subset of switches (e.g., the switches 155 and 156 of the subset of switches 106-2, or the switches 157 and 158 of the subset of switches 108-2) configured to operate at a second voltage level (e.g., V2) corresponding to the second DC voltage (e.g., +PVDD/2 as a low-rail voltage). In some embodiments, each switch of the circuit (e.g., the circuit 100) comprises a transistor. In some embodiments, the first and second sets of switches (e.g., the sets of switches 106 and 108) comprise one or more MOSFETs (e.g., one or more N-channel MOSFETs and/or P-channel MOSFETs). In some embodiments, the first and second set of switches (e.g., the sets of switches 106 and 108) comprise one or more bipolar junction transistors (BJTs) and/or field-effect transistors (FETs). This is illustrated in, for example, FIGS. 1-4.

(A2) In some embodiments of any of A1, the respective first subset (e.g., the subset of switches 106-1) of the first set of switches (e.g., the set of switches 106) includes a first switch (e.g., switch 151) and the respective first subset (e.g., the subset of switches 108-1) of the second set of switches (e.g., the set of switches 108) includes a second switch (e.g., the switch 152). The circuit (e.g., the circuit 100) is configured to provide a first voltage (e.g., the voltage level of +PVDD), corresponding to the first DC voltage (e.g., +PVDD as a high-rail voltage), at the output interface (e.g., the output interface 114) in accordance with the first switch (e.g., the switch 151) of the respective first subset (e.g., the subset of switches 106-1) of the first set of switches (e.g., the set of switches 106) being active (e.g., turned on) and the respective second subset (e.g., the subset of switches 108-2) of the second set of switches (e.g., the set of switches 108) being active (e.g., turned on). The first voltage (e.g., the voltage level of +PVDD) has a first polarity (e.g., a positive polarity relative to a common ground or reference potential). In this circumstance, all other switches (e.g., the switches 152, 153, 154, 155, and 156) in the circuit (e.g., the circuit 100) are inactive (e.g., in an open state such that current cannot flow through the switches 152, 153, 154, 155, and 156). This is illustrated in, for example, FIG. 2A.

(A3) In some embodiments of any of A1-A2, the circuit (e.g., the circuit 100) is configured to provide a second voltage (e.g., the voltage level of−PVDD), corresponding to the first DC voltage (e.g., +PVDD as a high-rail voltage), at the output interface (e.g., the output interface 114) in accordance with the second switch (e.g., the switch 152) of the respective first subset (e.g., the subset of switches 108-1) of the second set of switches (e.g., the set of switches 108) being active (e.g., turned on) and the respective second subset (e.g., the subset of switches 106-2) of the first set of switches (e.g., the set of switches 106) being active (e.g., turned on). The second voltage (e.g., the voltage level of−PVDD) has a second polarity (e.g., a negative polarity relative to a common ground or reference potential) that is opposite to the first polarity. In this circumstance, all other switches (e.g., the switches 151, 153, 154, 157, and 158) in the circuit (e.g., the circuit 100) are inactive (e.g., in an open state such that current cannot flow through the switches 151, 153, 154, 157, and 158). This is illustrated in, for example, FIG. 2B.

(A4) In some embodiments of any of A1-A3, the second power source (e.g., the power source 112) comprises a capacitor (e.g., the capacitor 124) coupled to the first half-bridge power stage (e.g., the half-bridge power stage 102) via a third switch (e.g., the switch 153) and coupled to the second half-bridge power stage (e.g., the half-bridge power stage 104) via a fourth switch (e.g., the switch 154). In some embodiments, the third switch (e.g., the switch 153) is part of the first half-bridge power stage (e.g., the half-bridge power stage 102). In some embodiments, the fourth switch (e.g., the switch 154) is part of the second half-bridge power stage (e.g., the half-bridge power stage 104). In some circumstances, the capacitor is constrained by an upper bound and a lower bound. In some embodiments, the capacitor (e.g., the capacitor 124) has a capacitance in a range from 1 μF to 30 μF (e.g., 1 μF to 22 μF). For example, a capacitance that is too low can lead to ripples, e.g., significant variations in change in the second DC voltage (e.g., +PVDD/2 as a low-rail voltage). In another example, a capacitance that is too high can lead to extended duration of each cycle (e.g., slow charging effect). Additionally, a capacitance that is too high can result in an increase in size and cost of the capacitor 124. In some embodiments, the capacitance of the capacitor (e.g., the capacitor 124) is determined based on factors including available footprint (e.g., form factor required by design specifications) and cost considerations. This is illustrated in, for example, FIGS. 1-3.

(A5) In some embodiments of any of A1-A4, the respective second subset (e.g., the subset of switches 106-2) of the first set of switches (e.g., the set of switches 106) includes a fifth switch (e.g., the switch 155) and a sixth switch (e.g., the switch 156), and the respective second subset (e.g., the subset of switches 108-2) of the second set of switches (e.g., the set of switches 108) includes a seventh switch (e.g., the switch 157) and an eighth switch (e.g., the switch 158). The circuit (e.g., the circuit 100) is configured to provide a third voltage (e.g., the voltage level of +PVDD/2), corresponding to the second DC voltage (e.g., +PVDD/2 as a low-rail voltage), at the output interface (e.g., the output interface 114) in accordance with the circuit (e.g., the circuit 100) being in a first state (e.g., the operating state 203) in which the first, the fourth and the seventh switches (e.g., the switches 151, 154, and 157) are active (e.g., turned on). The third voltage (e.g., the voltage level of +PVDD/2) has a first polarity (e.g., a positive polarity relative to a common ground or reference potential). In some embodiments, the first state corresponds to the operating state 203 for operating the circuit 100. This is illustrated in, for example, FIG. 2C.

(A6) In some embodiments of any of A1-A5, while in the first state (e.g., the operating state 203), the circuit (e.g., the circuit 100) charges the capacitor (e.g., the capacitor 124) of the second power source (e.g., the power source 112). This is illustrated in, for example, FIG. 2C.

(A7) In some embodiments of any of A1-A6, the circuit (e.g., the circuit 100) is configured to provide a fourth voltage (e.g., the voltage level of −PVDD/2), corresponding to the second DC voltage (e.g., +PVDD/2 as a low-rail voltage), at the output interface (e.g., the output interface 114) in accordance with the circuit (e.g., the circuit 100) being in a second state (e.g., the operating state 204) in which the second, the third, and the fifth switches (e.g., the switches 152, 153, and 155) are active (e.g., turned on). The fourth voltage (e.g., +PVDD/2 as a low-rail voltage) has a second polarity (e.g., a negative polarity relative to a common ground or reference potential) that is opposite to the first polarity. In some embodiments, the second state corresponds to the operating state 204 for operating the circuit 100. This is illustrated in, for example, FIG. 2D.

(A8) In some embodiments of any of A1-A7, while in the second state (e.g., the operating state 204), the circuit (e.g., the circuit 100) charges the capacitor (e.g., the capacitor 124) of the second power source (e.g., the power source 112). This is illustrated in, for example, FIG. 2D.

(A9) In some embodiments of any of A1-A8, the circuit (e.g., the circuit 100) is configured to provide a fifth voltage (e.g., the voltage level of +PVDD/2), corresponding to the second DC voltage (e.g., +PVDD/2 as a low-rail voltage), at the output interface (e.g., the output interface 114) in accordance with the circuit (e.g., the circuit 100) being in a third state (e.g., the operating state 205) in which the third, fifth, seventh, and eighth switches (e.g., the switches 153, 155, 157, and 158) are active (e.g., turned on). The fifth voltage (e.g., the voltage level of +PVDD/2) has the first polarity. In some embodiments, the third state corresponds to the operating state 205 for operating the circuit 100. This is illustrated in, for example, FIG. 2E.

(A10) In some embodiments of any of A1-A9, while in the third state (e.g., the operating state 205), the circuit (e.g., the circuit 100) discharges the capacitor (e.g., the capacitor 124) of the second power source (e.g., the power source 112). This is illustrated in, for example, FIG. 2E.

(A11) In some embodiments of any of A1-A10, the circuit (e.g., the circuit 100) is configured to provide a sixth voltage (e.g., the voltage level of −PVDD/2), corresponding to the second DC voltage (e.g., +PVDD/2 as a low-rail voltage), at the output interface (e.g., the output interface 114) in accordance with the circuit (e.g., the circuit 100) being in a fourth state (e.g., the operating state 206) in which the fourth, fifth, sixth, and seventh switches (e.g., the switches 154, 155, 156, and 157) are active (e.g., turned on). The sixth voltage (e.g., the voltage level of −PVDD/2) has a second polarity (e.g., a negative polarity relative to a common ground or reference potential) that is opposite to the first polarity. In some embodiments, the fourth state corresponds to the operating state 206 for operating the circuit 100. This is illustrated in, for example, FIG. 2F.

(A12) In some embodiments of any of A1-A11, while in the fourth state (e.g., the operating state 206), the circuit (e.g., the circuit 100) discharges the capacitor (e.g., the capacitor 124) of the second power source (e.g., the power source 112). This is illustrated in, for example, FIG. 2F.

(A13) In some embodiments of any of A1-A12, the circuit (e.g., the circuit 100) is configured to provide a seventh voltage (e.g., a voltage level of zero) at the output interface (e.g., the output interface 114) in accordance with the circuit (e.g., the circuit 100) being in a fifth state (e.g., the operating state 207, the operating state 208, or the operating state 209). This is illustrated in, for example, FIGS. 2G-2I.

(A14) In some embodiments of any of A1-A13, the seventh voltage (e.g., a voltage level of zero) is a zero voltage. This is illustrated in, for example, FIGS. 2G-2I.

(A15) In some embodiments of any of A1-A14, in the fifth state (e.g., the operating state 207), the first and second switches (e.g., the switches 151 and 152) are active (e.g., turned on) such that two terminals (e.g., the terminals 116-1 and 116-2) of the output interface (e.g., the output interface 114) are coupled to the first power source (e.g., the power source 110). This is illustrated in, for example, FIG. 2G.

(A16) In some embodiments of any of A1-A15, in the fifth state (e.g., the operating state 208), the third, fourth, fifth, and seventh switches (e.g., the switches 153, 154, 155, and 157) are active (e.g., turned on) such that two terminals (e.g., the terminals 116-1 and 116-2) of the output interface (e.g., output interface 114) are coupled to the second power source (e.g., the power source 112). This is illustrated in, for example, FIG. 2H.

(A17) In some embodiments of any of A1-A16, in the fifth state (e.g., the operating state 209), the fifth, sixth, seventh, and eighth switches (e.g., the switches 155, 156, 157, and 158) are active (e.g., turned on) such that two terminals (e.g., the terminals 116-1 and 116-2) of the output interface (e.g., the output interface 114) are coupled to an electrical ground (e.g., the electrical ground 134 and/or the electrical ground 136). This is illustrated in, for example, FIG. 21.

(A18) In some embodiments of any of A1-A17, the second DC voltage (e.g., +PVDD/2 as a low-rail voltage) is configured to be one-half of the first DC voltage (e.g., +PVDD as a high-rail voltage). In some embodiments, the first DC voltage is maintained at +PVDD (e.g., a high-rail voltage), and the second DC voltage is maintained at +PVDD/2 (e.g., a low-rail voltage). This is illustrated in, for example, FIGS. 1-4.

(A19) In some embodiments of any of A1-A18, the first half-bridge power stage (e.g., the half-bridge power stage 102) and the second half-bridge power stage (e.g., the half-bridge power stage 104) are coupled to different terminals (e.g., the terminals 116-1 and 116-2) of the output interface (e.g., the output interface 114) and comprise a same configuration of switches, e.g., the first and second half-bridge power stages are symmetric. In some embodiments, the switches (e.g., the switches 151, 155, and 156) of the first half-bridge power stage (e.g., the half-bridge power stage 102) have the same parameters as the switches (e.g., the switches 152, 157, and 158) of the second half-bridge power stage (e.g., the half-bridge power stage 104). In some embodiments, the switches (e.g., the switches 151, 155, and 156) of the first half-bridge power stage (e.g., the half-bridge power stage 102) have one or more parameters that are different than parameters of the switches (e.g., the switches 152, 157, and 158) of the second half-bridge power stage (e.g., the half-bridge power stage 104). This is illustrated in, for example, FIGS. 1-3.

(A20) In some embodiments of any of A1-A19, the respective first subsets of switches (e.g., the subsets of switches 106-1 and 108-1) comprise P-channel metal-oxide-semiconductor (PMOS) transistors and the respective second subsets of switches (e.g., the subsets of switches 106-2 and 108-2) comprise N-channel metal-oxide-semiconductor (NMOS) transistors. In some embodiments, the respective first subsets of switches (e.g., the respective subsets of switches 106-1 and 108-1) consist essentially of P-channel MOSFETs. In some embodiments, the respective first subsets of switches (e.g., the respective subsets of switches 106-1 and 108-1) consist essentially of N-channel MOSFETs. In some embodiments, the subsets of second switches (e.g., the respective subsets of switches 106-2 and 108-2) consist essentially of N-channel MOSFETs. In some embodiments, the respective second subsets of switches (e.g., the respective subsets of switches 106-2 and 108-2) consist essentially of P-channel MOSFETs. This is illustrated in, for example, FIGS. 1-3.

In some embodiments, the first voltage level (e.g., the voltage level V1) is 10 V and the second voltage level (e.g., the voltage level V2) is 5 V. In some embodiments, the first voltage level (e.g., the voltage level V1) is 8 V and the second voltage level (e.g., the voltage level V2) is 5 V. In some embodiments, the first and second voltage levels (e.g., the voltage levels V1 and V1) correspond to logic levels of switches. In some embodiments, a switch (e.g., a transistor) of the circuit 100 (e.g., the circuit 100) designed to operate at higher voltage(s) (e.g., 10 V) has a larger footprint (e.g., physical size) compared to another switch (e.g., a transistor) designed to operate at lower voltage(s) (e.g., 5 V). Implementing a combination of switches operating at different voltages can impact overall circuity efficiency. For example, in the absence of a 4 V transistor, a 5 V transistor must be used instead, which induces an efficiency penalty (e.g., increased gate capacitance, higher threshold voltage, etc.). In some embodiments, a voltage level (e.g., V1 and/or V2) is also referred to as a voltage rating (e.g., a voltage rating of a transistor). In some embodiments, a voltage level (e.g., V1 and/or V2) is also referred to as a maximum voltage level, e.g., the highest voltage applied to a switch. In some embodiments, a voltage level (e.g., V1 and/or V2) is also referred to as to a target voltage level, e,g,. a predetermined voltage level to be maintained for a switch.

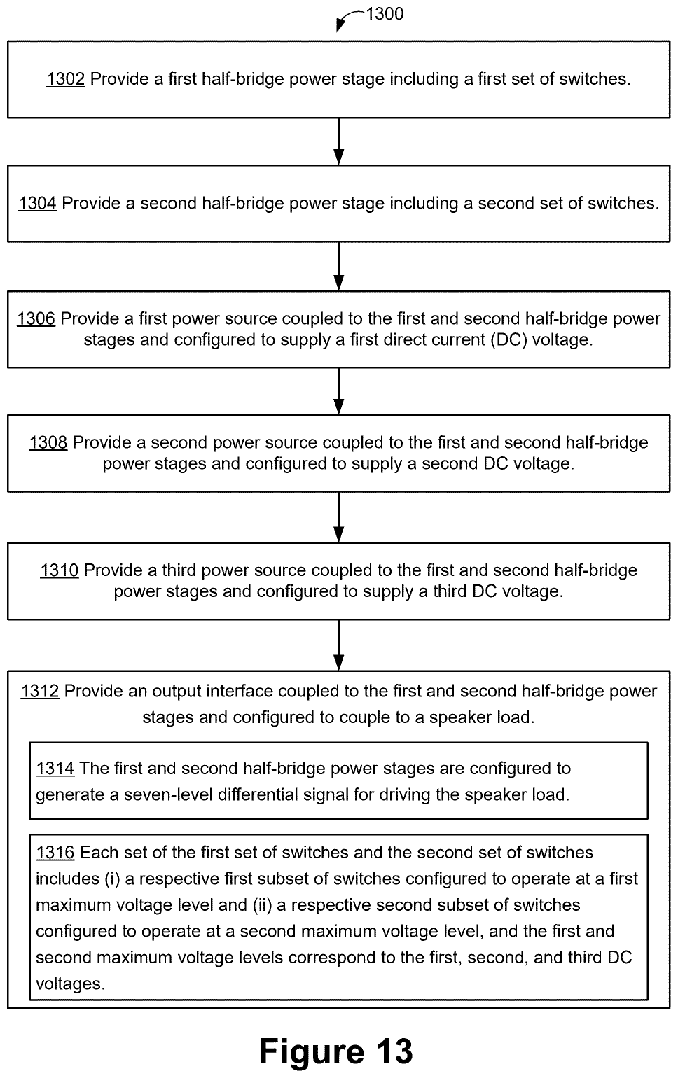

FIG. 13 illustrates a flow diagram of an example method 1300 of operating a multi-level amplification circuit (e.g., the circuit 500), in accordance with some embodiments. Operations (e.g., steps) of the method 1300 can be performed by a multi-level amplification circuit (e.g., a circuit of a device or system such as an XR device). At least some of the operations shown in FIG. 13 correspond to instructions stored in a computer memory or computer-readable storage medium (e.g., storage, RAM, and/or memory). Operations of the method 1300 can be performed by a single device alone or in conjunction with one or more processors and/or hardware components of another communicatively coupled device and/or instructions stored in memory or computer-readable medium of the other device communicatively coupled to the system. In some embodiments, the various operations of the methods described herein are interchangeable and/or optional, and respective operations of the methods are performed by any of the aforementioned devices, systems, or combination of devices and/or systems. For convenience, the method operations will be described below as being performed by particular component or device, but should not be construed as limiting the performance of the operation to the particular device in all embodiments.

(B1) The method 1300 occurs at a circuit (e.g., the circuit 500) configured as a multi-level class D amplifier (e.g., a seven-level class D amplifier). In some embodiments, the method 1300 includes providing (1302) a first half-bridge power stage (e.g., the half-bridge power stage 502) including a first set of switches (e.g., the set of switches 506). The method 1300 further includes providing (1304) a second half-bridge power stage (e.g., the half-bridge power stage 504) including a second set of switches (e.g., the set of switches 508). The method 1300 further includes providing (1306) a first power source (e.g., the power source 110) coupled to the first and second half-bridge power stages (e.g., the half-bridge power stages 502 and 504) and configured to supply a first direct current (DC) voltage (e.g., +PVDD as a high-rail voltage). The method 1300 further includes providing (1308) a second power source (e.g., the power source 112) coupled to the first and second half-bridge power stages (e.g., the half-bridge power stages 502 and 504) and configured to supply a second DC voltage (e.g., +VMID as a mid-rail voltage). The method 1300 further includes providing (1310) a third power source (e.g., the power source 510) coupled to the first and second half-bridge power stages (e.g., the half-bridge power stages 502 and 504) and configured to supply a third DC voltage (e.g., +VBOOST as a boosted rail voltage). The method 1300 further includes providing (1312) an output interface (e.g., the output interface 514 having terminals 516-1 and 516-2) coupled to the first and second half-bridge power stages (e.g., the half-bridge power stages 502 and 504) and configured to couple to a speaker load (e.g., the load 132). The first and second half-bridge power stages (e.g., the half-bridge power stages 502 and 504) are configured to generate (1314) a seven-level differential signal (e.g., +VBOOST, +PVDD, +VMID, 0, −VMID, −PVDD, −VBOOST) for driving the speaker load (e.g., the load 132). Each set of the first set of switches (e.g., the set of switches 506) and the second set of switches (e.g., the set of switches 508) includes (1316) (i) a respective first subset of switches (e.g., the switch 559 of the subset of switches 506-1, or the switch 560 of the subset of switches 508-1) and (ii) a respective second subset of switches (e.g., the switches 551, 555, and 556 of the subset of switches 506-2, or the switches 552, 557 and 558 of the subset of switches 508-2). Each switch of the respective first subset of switches (e.g., the switch 559 of the subset of switches 506-1, or the switch 560 of the subset of switches 508-1) is configured to operate at a first voltage level (e.g., V3). Each switch of the respective second subset of switches (e.g., the switches 551, 555, and 556 of the subset of switches 506-2, or the switches 552, 557 and 558 of the subset of switches 508-2) is configured to operate at a second voltage level (e.g., V4, V5, or V6). The first and second voltage levels (e.g., (i) V3 and (ii) V4, V5, or V6) correspond to the first DC voltage (e.g., +PVDD as a high-rail voltage), the second DC voltage (e.g., +VMID as a mid-rail voltage), the third DC voltage (e.g., +VBOOST as a boosted rail voltage), or a combination thereof. This is illustrated in, for example, FIGS. 5-9.

The devices described above are further detailed below, including wrist-wearable devices, headset devices, systems, and haptic feedback devices. Specific operations described above may occur as a result of specific hardware, such hardware is described in further detail below. The devices described below are not limiting and features on these devices can be removed or additional features can be added to these devices.

### Example Extended-Reality Systems

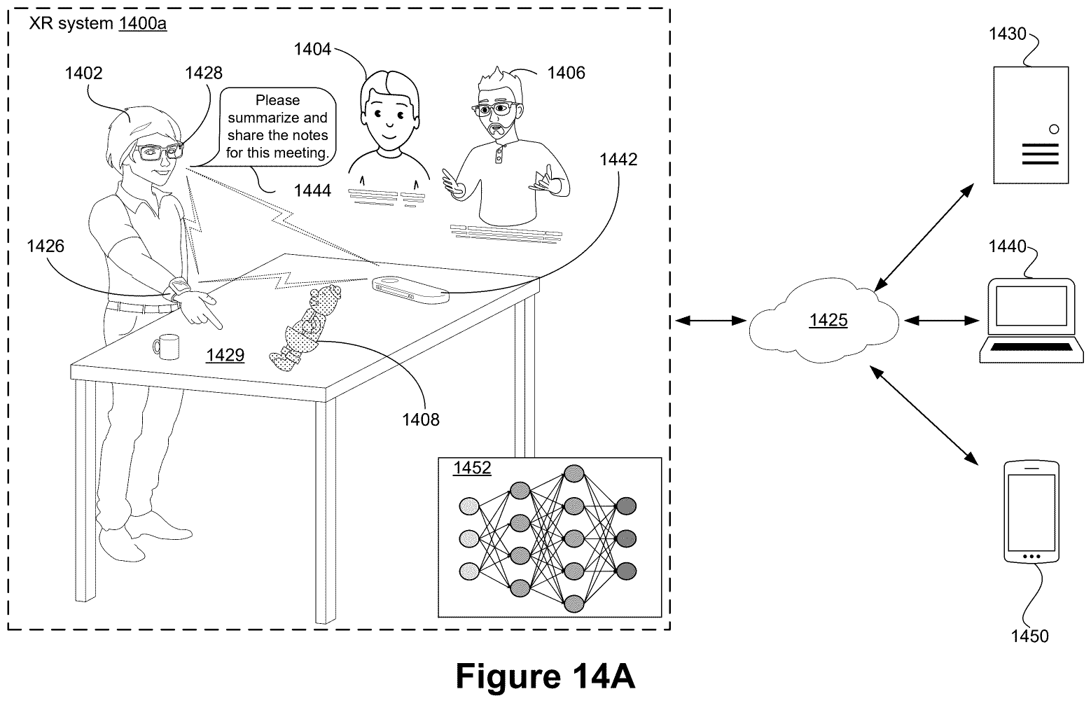

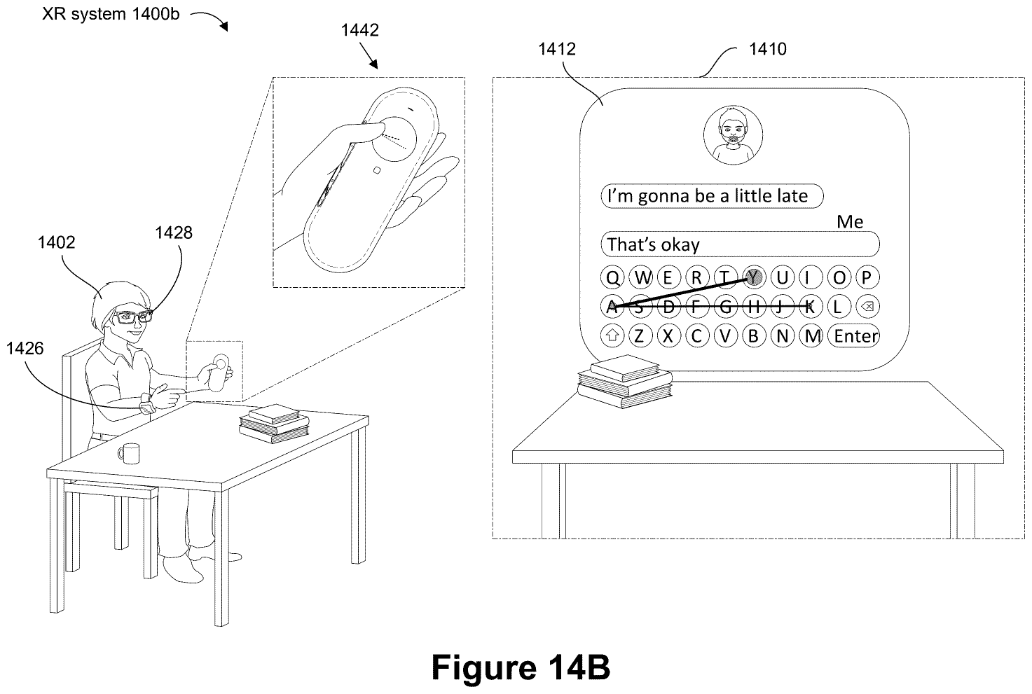

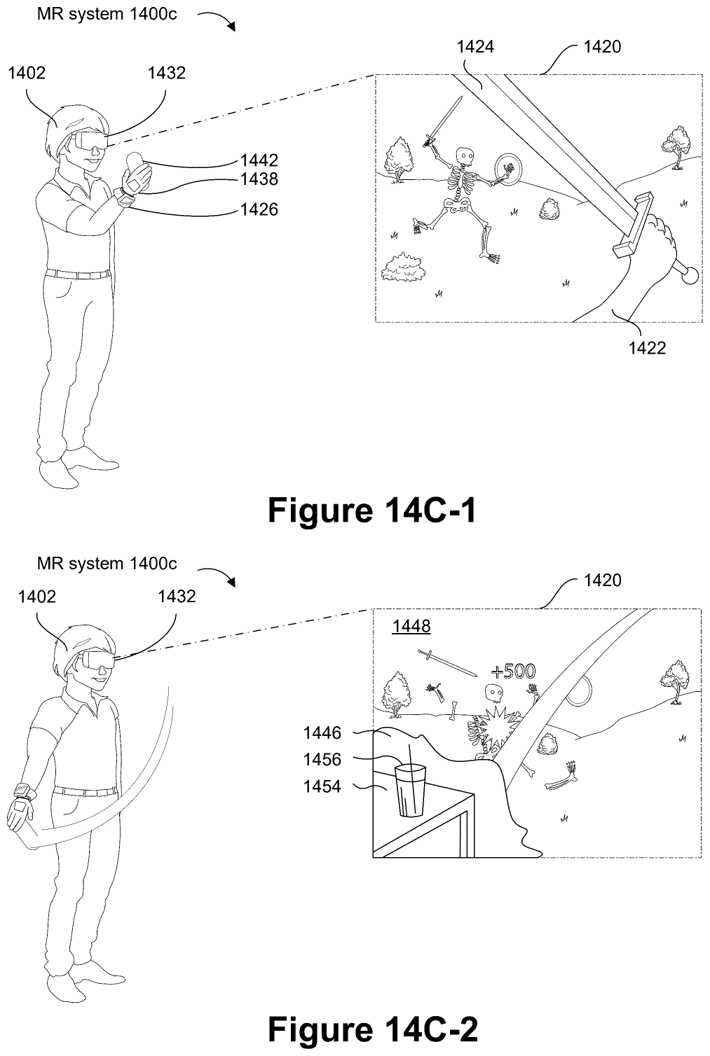

FIGS. 14A 14B, 14C-1, and 14C-2, illustrate example XR systems that include AR and MR systems, in accordance with some embodiments. FIG. 14A shows an XR system 1400a and first example user interactions using a wrist-wearable device 1426, a head-wearable device (e.g., AR device 1428), and/or a HIPD 1442. FIG. 14B shows a XR system 1400b and second example user interactions using a wrist-wearable device 1426, AR device 1428, and/or an HIPD 1442. FIGS. 14C-1 and 14C-2 show an MR system 1400c and third example user interactions using a wrist-wearable device 1426, a head-wearable device (e.g., an MR device such as a VR device), and/or an HIPD 1442. As the skilled artisan will appreciate upon reading the descriptions provided herein, the above-example AR and MR systems (described in detail below) can perform various functions and/or operations.

The wrist-wearable device 1426, the head-wearable devices, and/or the HIPD 1442 can communicatively couple via a network 1425 (e.g., cellular, near field, Wi-Fi, personal area network, wireless LAN). Additionally, the wrist-wearable device 1426, the head-wearable device, and/or the HIPD 1442 can also communicatively couple with one or more servers 1430, computers 1440 (e.g., laptops, computers), mobile devices 1450 (e.g., smartphones, tablets), and/or other electronic devices via the network 1425 (e.g., cellular, near field, Wi-Fi, personal area network, wireless LAN). Similarly, a smart textile-based garment, when used, can also communicatively couple with the wrist-wearable device 1426, the head-wearable device(s), the HIPD 1442, the one or more servers 1430, the computers 1440, the mobile devices 1450, and/or other electronic devices via the network 1425 to provide inputs.

Turning to FIG. 14A, a user 1402 is shown wearing the wrist-wearable device 1426 and the AR device 1428 and having the HIPD 1442 on their desk. The wrist-wearable device 1426, the AR device 1428, and the HIPD 1442 facilitate user interaction with an AR environment. In particular, as shown by the AR system 1400a, the wrist-wearable device 1426, the AR device 1428, and/or the HIPD 1442 cause presentation of one or more avatars 1404, digital representations of contacts 1406, and virtual objects 1408. As discussed below, the user 1402 can interact with the one or more avatars 1404, digital representations of the contacts 1406, and virtual objects 1408 via the wrist-wearable device 1426, the AR device 1428, and/or the HIPD 1442. In addition, the user 1402 is also able to directly view physical objects in the environment, such as a physical table 1429, through transparent lens(es) and waveguide(s) of the AR device 1428. Alternatively, an MR device could be used in place of the AR device 1428 and a similar user experience can take place, but the user would not be directly viewing physical objects in the environment, such as table 1429, and would instead be presented with a virtual reconstruction of the table 1429 produced from one or more sensors of the MR device (e.g., an outward facing camera capable of recording the surrounding environment).

The user 1402 can use any of the wrist-wearable device 1426, the AR device 1428 (e.g., through physical inputs at the AR device and/or built-in motion tracking of a user's extremities), a smart-textile garment, externally mounted extremity tracking device, the HIPD 1442 to provide user inputs, etc. For example, the user 1402 can perform one or more hand gestures that are detected by the wrist-wearable device 1426 (e.g., using one or more EMG sensors and/or IMUs built into the wrist-wearable device) and/or AR device 1428 (e.g., using one or more image sensors or cameras) to provide a user input. Alternatively, or additionally, the user 1402 can provide a user input via one or more touch surfaces of the wrist-wearable device 1426, the AR device 1428, and/or the HIPD 1442, and/or voice commands captured by a microphone of the wrist-wearable device 1426, the AR device 1428, and/or the HIPD 1442. The wrist-wearable device 1426, the AR device 1428, and/or the HIPD 1442 include an artificially intelligent digital assistant to help the user in providing a user input (e.g., completing a sequence of operations, suggesting different operations or commands, providing reminders, confirming a command). For example, the digital assistant can be invoked through an input occurring at the AR device 1428 (e.g., via an input at a temple arm of the AR device 1428). In some embodiments, the user 1402 can provide a user input via one or more facial gestures and/or facial expressions. For example, cameras of the wrist-wearable device 1426, the AR device 1428, and/or the HIPD 1442 can track the user 1402's eyes for navigating a user interface.

The wrist-wearable device 1426, the AR device 1428, and/or the HIPD 1442 can operate alone or in conjunction to allow the user 1402 to interact with the AR environment. In some embodiments, the HIPD 1442 is configured to operate as a central hub or control center for the wrist-wearable device 1426, the AR device 1428, and/or another communicatively coupled device. For example, the user 1402 can provide an input to interact with the AR environment at any of the wrist-wearable device 1426, the AR device 1428, and/or the HIPD 1442, and the HIPD 1442 can identify one or more back-end and front-end tasks to cause the performance of the requested interaction and distribute instructions to cause the performance of the one or more back-end and front-end tasks at the wrist-wearable device 1426, the AR device 1428, and/or the HIPD 1442. In some embodiments, a back-end task is a background-processing task that is not perceptible by the user (e.g., rendering content, decompression, compression, application-specific operations), and a front-end task is a user-facing task that is perceptible to the user (e.g., presenting information to the user, providing feedback to the user). The HIPD 1442 can perform the back-end tasks and provide the wrist-wearable device 1426 and/or the AR device 1428 operational data corresponding to the performed back-end tasks such that the wrist-wearable device 1426 and/or the AR device 1428 can perform the front-end tasks. In this way, the HIPD 1442, which has more computational resources and greater thermal headroom than the wrist-wearable device 1426 and/or the AR device 1428, performs computationally intensive tasks and reduces the computer resource utilization and/or power usage of the wrist-wearable device 1426 and/or the AR device 1428.

In the example shown by the AR system 1400a, the HIPD 1442 identifies one or more back-end tasks and front-end tasks associated with a user request to initiate an AR video call with one or more other users (represented by the avatar 1404 and the digital representation of the contact 1406) and distributes instructions to cause the performance of the one or more back-end tasks and front-end tasks. In particular, the HIPD 1442 performs back-end tasks for processing and/or rendering image data (and other data) associated with the AR video call and provides operational data associated with the performed back-end tasks to the AR device 1428 such that the AR device 1428 performs front-end tasks for presenting the AR video call (e.g., presenting the avatar 1404 and the digital representation of the contact 1406).

In some embodiments, the HIPD 1442 can operate as a focal or anchor point for causing the presentation of information. This allows the user 1402 to be generally aware of where information is presented. For example, as shown in the AR system 1400a, the avatar 1404 and the digital representation of the contact 1406 are presented above the HIPD 1442. In particular, the HIPD 1442 and the AR device 1428 operate in conjunction to determine a location for presenting the avatar 1404 and the digital representation of the contact 1406. In some embodiments, information can be presented within a predetermined distance from the HIPD 1442 (e.g., within five meters). For example, as shown in the AR system 1400a, virtual object 1408 is presented on the desk some distance from the HIPD 1442. Similar to the above example, the HIPD 1442 and the AR device 1428 can operate in conjunction to determine a location for presenting the virtual object 1408. Alternatively, in some embodiments, presentation of information is not bound by the HIPD 1442. More specifically, the avatar 1404, the digital representation of the contact 1406, and the virtual object 1408 do not have to be presented within a predetermined distance of the HIPD 1442. While an AR device 1428 is described working with an HIPD, an MR headset can be interacted with in the same way as the AR device 1428.

User inputs provided at the wrist-wearable device 1426, the AR device 1428, and/or the HIPD 1442 are coordinated such that the user can use any device to initiate, continue, and/or complete an operation. For example, the user 1402 can provide a user input to the AR device 1428 to cause the AR device 1428 to present the virtual object 1408 and, while the virtual object 1408 is presented by the AR device 1428, the user 1402 can provide one or more hand gestures via the wrist-wearable device 1426 to interact and/or manipulate the virtual object 1408. While an AR device 1428 is described working with a wrist-wearable device 1426, an MR headset can be interacted with in the same way as the AR device 1428.

### Integration of Artificial Intelligence With XR Systems

FIG. 14A illustrates an interaction in which an artificially intelligent virtual assistant can assist in requests made by a user 1402. The AI virtual assistant can be used to complete open-ended requests made through natural language inputs by a user 1402. For example, in FIG. 14A the user 1402 makes an audible request 1444 to summarize the conversation and then share the summarized conversation with others in the meeting. In addition, the AI virtual assistant is configured to use sensors of the XR system (e.g., cameras of an XR headset, microphones, and various other sensors of any of the devices in the system) to provide contextual prompts to the user for initiating tasks.

FIG. 14A also illustrates an example neural network 1452 used in Artificial Intelligence applications. Uses of Artificial Intelligence (AI) are varied and encompass many different aspects of the devices and systems described herein. AI capabilities cover a diverse range of applications and deepen interactions between the user 1402 and user devices (e.g., the AR device 1428, an MR device 1432, the HIPD 1442, the wrist-wearable device 1426). The AI discussed herein can be derived using many different training techniques. While the primary AI model example discussed herein is a neural network, other AI models can be used. Non-limiting examples of AI models include artificial neural networks (ANNs), deep neural networks (DNNs), convolution neural networks (CNNs), recurrent neural networks (RNNs), large language models (LLMs), long short-term memory networks, transformer models, decision trees, random forests, support vector machines, k-nearest neighbors, genetic algorithms, Markov models, Bayesian networks, fuzzy logic systems, and deep reinforcement learnings, etc. The AI models can be implemented at one or more of the user devices, and/or any other devices described herein. For devices and systems herein that employ multiple AI models, different models can be used depending on the task. For example, for a natural-language artificially intelligent virtual assistant, an LLM can be used and for the object detection of a physical environment, a DNN can be used instead.

In another example, an AI virtual assistant can include many different AI models and based on the user's request, multiple AI models may be employed (concurrently, sequentially or a combination thereof). For example, an LLM-based AI model can provide instructions for helping a user follow a recipe and the instructions can be based in part on another AI model that is derived from an ANN, a DNN, an RNN, etc. that is capable of discerning what part of the recipe the user is on (e.g., object and scene detection).

As AI training models evolve, the operations and experiences described herein could potentially be performed with different models other than those listed above, and a person skilled in the art would understand that the list above is non-limiting.

A user 1402 can interact with an AI model through natural language inputs captured by a voice sensor, text inputs, or any other input modality that accepts natural language and/or a corresponding voice sensor module. In another instance, input is provided by tracking the eye gaze of a user 1402 via a gaze tracker module. Additionally, the AI model can also receive inputs beyond those supplied by a user 1402. For example, the AI can generate its response further based on environmental inputs (e.g., temperature data, image data, video data, ambient light data, audio data, GPS location data, inertial measurement (i.e., user motion) data, pattern recognition data, magnetometer data, depth data, pressure data, force data, neuromuscular data, heart rate data, temperature data, sleep data) captured in response to a user request by various types of sensors and/or their corresponding sensor modules. The sensors' data can be retrieved entirely from a single device (e.g., AR device 1428) or from multiple devices that are in communication with each other (e.g., a system that includes at least two of an AR device 1428, an MR device 1432, the HIPD 1442, the wrist-wearable device 1426, etc.). The AI model can also access additional information (e.g., one or more servers 1430, the computers 1440, the mobile devices 1450, and/or other electronic devices) via a network 1425.

A non-limiting list of AI-enhanced functions includes but is not limited to image recognition, speech recognition (e.g., automatic speech recognition), text recognition (e.g., scene text recognition), pattern recognition, natural language processing and understanding, classification, regression, clustering, anomaly detection, sequence generation, content generation, and optimization. In some embodiments, AI-enhanced functions are fully or partially executed on cloud-computing platforms communicatively coupled to the user devices (e.g., the AR device 1428, an MR device 1432, the HIPD 1442, the wrist-wearable device 1426) via the one or more networks. The cloud-computing platforms provide scalable computing resources, distributed computing, managed AI services, interference acceleration, pre-trained models, APIs and/or other resources to support comprehensive computations required by the AI-enhanced function.

Example outputs stemming from the use of an AI model can include natural language responses, mathematical calculations, charts displaying information, audio, images, videos, texts, summaries of meetings, predictive operations based on environmental factors, classifications, pattern recognitions, recommendations, assessments, or other operations. In some embodiments, the generated outputs are stored on local memories of the user devices (e.g., the AR device 1428, an MR device 1432, the HIPD 1442, the wrist-wearable device 1426), storage options of the external devices (servers, computers, mobile devices, etc.), and/or storage options of the cloud-computing platforms.

The AI-based outputs can be presented across different modalities (e.g., audio-based, visual-based, haptic-based, and any combination thereof) and across different devices of the XR system described herein. Some visual-based outputs can include the displaying of information on XR augments of an XR headset, user interfaces displayed at a wrist-wearable device, laptop device, mobile device, etc. On devices with or without displays (e.g., HIPD 1442), haptic feedback can provide information to the user 1402. An AI model can also use the inputs described above to determine the appropriate modality and device(s) to present content to the user (e.g., a user walking on a busy road can be presented with an audio output instead of a visual output to avoid distracting the user 1402).

### Example Augmented Reality Interaction

FIG. 14B shows the user 1402 wearing the wrist-wearable device 1426 and the AR device 1428 and holding the HIPD 1442. In the AR system 1400b, the wrist-wearable device 1426, the AR device 1428, and/or the HIPD 1442 are used to receive and/or provide one or more messages to a contact of the user 1402. In particular, the wrist-wearable device 1426, the AR device 1428, and/or the HIPD 1442 detect and coordinate one or more user inputs to initiate a messaging application and prepare a response to a received message via the messaging application.

In some embodiments, the user 1402 initiates, via a user input, an application on the wrist-wearable device 1426, the AR device 1428, and/or the HIPD 1442 that causes the application to initiate on at least one device. For example, in the AR system 1400b the user 1402 performs a hand gesture associated with a command for initiating a messaging application (represented by messaging user interface 1412); the wrist-wearable device 1426 detects the hand gesture; and, based on a determination that the user 1402 is wearing the AR device 1428, causes the AR device 1428 to present a messaging user interface 1412 of the messaging application. The AR device 1428 can present the messaging user interface 1412 to the user 1402 via its display (e.g., as shown by user 1402's field of view 1410). In some embodiments, the application is initiated and can be run on the device (e.g., the wrist-wearable device 1426, the AR device 1428, and/or the HIPD 1442) that detects the user input to initiate the application, and the device provides another device operational data to cause the presentation of the messaging application. For example, the wrist-wearable device 1426 can detect the user input to initiate a messaging application, initiate and run the messaging application, and provide operational data to the AR device 1428 and/or the HIPD 1442 to cause presentation of the messaging application. Alternatively, the application can be initiated and run at a device other than the device that detected the user input. For example, the wrist-wearable device 1426 can detect the hand gesture associated with initiating the messaging application and cause the HIPD 1442 to run the messaging application and coordinate the presentation of the messaging application.

Further, the user 1402 can provide a user input provided at the wrist-wearable device 1426, the AR device 1428, and/or the HIPD 1442 to continue and/or complete an operation initiated at another device. For example, after initiating the messaging application via the wrist-wearable device 1426 and while the AR device 1428 presents the messaging user interface 1412, the user 1402 can provide an input at the HIPD 1442 to prepare a response (e.g., shown by the swipe gesture performed on the HIPD 1442). The user 1402's gestures performed on the HIPD 1442 can be provided and/or displayed on another device. For example, the user 1402's swipe gestures performed on the HIPD 1442 are displayed on a virtual keyboard of the messaging user interface 1412 displayed by the AR device 1428.

In some embodiments, the wrist-wearable device 1426, the AR device 1428, the HIPD 1442, and/or other communicatively coupled devices can present one or more notifications to the user 1402. The notification can be an indication of a new message, an incoming call, an application update, a status update, etc. The user 1402 can select the notification via the wrist-wearable device 1426, the AR device 1428, or the HIPD 1442 and cause presentation of an application or operation associated with the notification on at least one device. For example, the user 1402 can receive a notification that a message was received at the wrist-wearable device 1426, the AR device 1428, the HIPD 1442, and/or other communicatively coupled device and provide a user input at the wrist-wearable device 1426, the AR device 1428, and/or the HIPD 1442 to review the notification, and the device detecting the user input can cause an application associated with the notification to be initiated and/or presented at the wrist-wearable device 1426, the AR device 1428, and/or the HIPD 1442.

While the above example describes coordinated inputs used to interact with a messaging application, the skilled artisan will appreciate upon reading the descriptions that user inputs can be coordinated to interact with any number of applications including, but not limited to, gaming applications, social media applications, camera applications, web-based applications, financial applications, etc. For example, the AR device 1428 can present to the user 1402 game application data and the HIPD 1442 can use a controller to provide inputs to the game. Similarly, the user 1402 can use the wrist-wearable device 1426 to initiate a camera of the AR device 1428, and the user can use the wrist-wearable device 1426, the AR device 1428, and/or the HIPD 1442 to manipulate the image capture (e.g., zoom in or out, apply filters) and capture image data.

While an AR device 1428 is shown being capable of certain functions, it is understood that an AR device can be an AR device with varying functionalities based on costs and market demands. For example, an AR device may include a single output modality such as an audio output modality. In another example, the AR device may include a low-fidelity display as one of the output modalities, where simple information (e.g., text and/or low-fidelity images/video) is capable of being presented to the user. In yet another example, the AR device can be configured with face-facing light emitting diodes (LEDs) configured to provide a user with information, e.g., an LED around the right-side lens can illuminate to notify the wearer to turn right while directions are being provided or an LED on the left-side can illuminate to notify the wearer to turn left while directions are being provided. In another embodiment, the AR device can include an outward-facing projector such that information (e.g., text information, media) may be displayed on the palm of a user's hand or other suitable surface (e.g., a table, whiteboard). In yet another embodiment, information may also be provided by locally dimming portions of a lens to emphasize portions of the environment in which the user's attention should be directed. Some AR devices can present AR augments either monocularly or binocularly (e.g., an AR augment can be presented at only a single display associated with a single lens as opposed presenting an AR augmented at both lenses to produce a binocular image). In some instances, an AR device capable of presenting AR augments binocularly can optionally display AR augments monocularly as well (e.g., for power-saving purposes or other presentation considerations). These examples are non-exhaustive and features of one AR device described above can be combined with features of another AR device described above. While features and experiences of an AR device have been described generally in the preceding sections, it is understood that the described functionalities and experiences can be applied in a similar manner to an MR headset, which is described below in the proceeding sections.

### Example Mixed Reality Interaction

Turning to FIGS. 14C-1 and 14C-2, the user 1402 is shown wearing the wrist-wearable device 1426 and an MR device 1432 (e.g., a device capable of providing either an entirely VR experience or an MR experience that displays object(s) from a physical environment at a display of the device) and holding the HIPD 1442. In the AR system 1400c, the wrist-wearable device 1426, the MR device 1432, and/or the HIPD 1442 are used to interact within an MR environment, such as a VR game or other MR/VR application. While the MR device 1432 presents a representation of a VR game (e.g., MR game environment 1420) to the user 1402, the wrist-wearable device 1426, the MR device 1432, and/or the HIPD 1442 detect and coordinate one or more user inputs to allow the user 1402 to interact with the VR game.

In some embodiments, the user 1402 can provide a user input via the wrist-wearable device 1426, the MR device 1432, and/or the HIPD 1442 that causes an action in a corresponding MR environment. For example, the user 1402 in the MR system 1400c (shown in FIG. 14C-1) raises the HIPD 1442 to prepare for a swing in the MR game environment 1420. The MR device 1432, responsive to the user 1402 raising the HIPD 1442, causes the MR representation of the user 1422 to perform a similar action (e.g., raise a virtual object, such as a virtual sword 1424). In some embodiments, each device uses respective sensor data and/or image data to detect the user input and provide an accurate representation of the user 1402's motion. For example, image sensors (e.g., SLAM cameras or other cameras) of the HIPD 1442 can be used to detect a position of the HIPD 1442 relative to the user 1402's body such that the virtual object can be positioned appropriately within the MR game environment 1420; sensor data from the wrist-wearable device 1426 can be used to detect a velocity at which the user 1402 raises the HIPD 1442 such that the MR representation of the user 1422 and the virtual sword 1424 are synchronized with the user 1402's movements; and image sensors of the MR device 1432 can be used to represent the user 1402's body, boundary conditions, or real-world objects within the MR game environment 1420.

In FIG. 14C-2, the user 1402 performs a downward swing while holding the HIPD 1442. The user 1402's downward swing is detected by the wrist-wearable device 1426, the MR device 1432, and/or the HIPD 1442 and a corresponding action is performed in the MR game environment 1420. In some embodiments, the data captured by each device is used to improve the user's experience within the MR environment. For example, sensor data of the wrist-wearable device 1426 can be used to determine a speed and/or force at which the downward swing is performed and image sensors of the HIPD 1442 and/or the MR device 1432 can be used to determine a location of the swing and how it should be represented in the MR game environment 1420, which, in turn, can be used as inputs for the MR environment (e.g., game mechanics, which can use detected speed, force, locations, and/or aspects of the user 1402's actions to classify a user's inputs (e.g., user performs a light strike, hard strike, critical strike, glancing strike, miss) or calculate an output (e.g., amount of damage)).

FIG. 14C-2 further illustrates that a portion of the physical environment is reconstructed and displayed at a display of the MR device 1432 while the MR game environment 1420 is being displayed. In this instance, a reconstruction of the physical environment 1446 is displayed in place of a portion of the MR game environment 1420 when object(s) in the physical environment are potentially in the path of the user (e.g., a collision with the user and an object in the physical environment are likely). Thus, this example MR game environment 1420 includes (i) an immersive VR portion 1448 (e.g., an environment that does not have a corollary counterpart in a nearby physical environment) and (ii) a reconstruction of the physical environment 1446 (e.g., table 1454 and cup 1456). While the example shown here is an MR environment that shows a reconstruction of the physical environment to avoid collisions, other uses of reconstructions of the physical environment can be used, such as defining features of the virtual environment based on the surrounding physical environment (e.g., a virtual column can be placed based on an object in the surrounding physical environment (e.g., a tree)).

While the wrist-wearable device 1426, the MR device 1432, and/or the HIPD 1442 are described as detecting user inputs, in some embodiments, user inputs are detected at a single device (with the single device being responsible for distributing signals to the other devices for performing the user input). For example, the HIPD 1442 can operate an application for generating the MR game environment 1420 and provide the MR device 1432 with corresponding data for causing the presentation of the MR game environment 1420, as well as detect the user 1402's movements (while holding the HIPD 1442) to cause the performance of corresponding actions within the MR game environment 1420. Additionally or alternatively, in some embodiments, operational data (e.g., sensor data, image data, application data, device data, and/or other data) of one or more devices is provided to a single device (e.g., the HIPD 1442) to process the operational data and cause respective devices to perform an action associated with processed operational data.

In some embodiments, the user 1402 can wear a wrist-wearable device 1426, wear an MR device 1432, wear smart textile-based garments 1438 (e.g., wearable haptic gloves), and/or hold an HIPD 1442 device. In this embodiment, the wrist-wearable device 1426, the MR device 1432, and/or the smart textile-based garments 1438 are used to interact within an MR environment (e.g., any AR or MR system described above in reference to FIGS. 14A-14B). While the MR device 1432 presents a representation of an MR game (e.g., MR game environment 1420) to the user 1402, the wrist-wearable device 1426, the MR device 1432, and/or the smart textile-based garments 1438 detect and coordinate one or more user inputs to allow the user 1402 to interact with the MR environment.

In some embodiments, the user 1402 can provide a user input via the wrist-wearable device 1426, an HIPD 1442, the MR device 1432, and/or the smart textile-based garments 1438 that causes an action in a corresponding MR environment. In some embodiments, each device uses respective sensor data and/or image data to detect the user input and provide an accurate representation of the user 1402's motion. While four different input devices are shown (e.g., a wrist-wearable device 1426, an MR device 1432, an HIPD 1442, and a smart textile-based garment 1438) each one of these input devices entirely on its own can provide inputs for fully interacting with the MR environment. For example, the wrist-wearable device can provide sufficient inputs on its own for interacting with the MR environment. In some embodiments, if multiple input devices are used (e.g., a wrist-wearable device and the smart textile-based garment 1438) sensor fusion can be utilized to ensure inputs are correct. While multiple input devices are described, it is understood that other input devices can be used in conjunction or on their own instead, such as but not limited to external motion-tracking cameras, other wearable devices fitted to different parts of a user, apparatuses that allow for a user to experience walking in an MR environment while remaining substantially stationary in the physical environment, etc.

As described above, the data captured by each device is used to improve the user's experience within the MR environment. Although not shown, the smart textile-based garments 1438 can be used in conjunction with an MR device and/or an HIPD 1442.

While some experiences are described as occurring on an AR device and other experiences are described as occurring on an MR device, one skilled in the art would appreciate that experiences can be ported over from an MR device to an AR device, and vice versa.

Some definitions of devices and components that can be included in some or all of the example devices discussed are defined here for ease of reference. A skilled artisan will appreciate that certain types of the components described may be more suitable for a particular set of devices, and less suitable for a different set of devices. But subsequent reference to the components defined here should be considered to be encompassed by the definitions provided.

In some embodiments example devices and systems, including electronic devices and systems, will be discussed. Such example devices and systems are not intended to be limiting, and one of skill in the art will understand that alternative devices and systems to the example devices and systems described herein may be used to perform the operations and construct the systems and devices that are described herein.

As described herein, an electronic device is a device that uses electrical energy to perform a specific function. It can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device is a device that sits between two other electronic devices, and/or a subset of components of one or more electronic devices and facilitates communication, and/or data processing and/or data transfer between the respective electronic devices and/or electronic components.

The foregoing descriptions of FIGS. 14A-14C-2 provided above are intended to augment the description provided in reference to FIGS. 1-13. While terms in the following description may not be identical to terms used in the foregoing description, a person having ordinary skill in the art would understand these terms to have the same meaning.

Any data collection performed by the devices described herein and/or any devices configured to perform or cause the performance of the different embodiments described above in reference to any of the Figures, hereinafter the “devices,” is done with user consent and in a manner that is consistent with all applicable privacy laws. Users are given options to allow the devices to collect data, as well as the option to limit or deny collection of data by the devices. A user is able to opt in or opt out of any data collection at any time. Further, users are given the option to request the removal of any collected data.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” can be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” can be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A circuit, comprising:
a first half-bridge power stage including a first set of switches;
a second half-bridge power stage including a second set of switches;
a first power source coupled to the first and second half-bridge power stages and configured to supply a first direct current (DC) voltage;
a second power source coupled to the first and second half-bridge power stages and configured to supply a second DC voltage; and
an output interface coupled to the first and second half-bridge power stages and configured to couple to a speaker load, wherein:
the first and second half-bridge power stages are configured to generate a five-level differential signal for driving the speaker load; and
each set of the first set of switches and the second set of switches includes a respective first subset of switches configured to operate at a first voltage level corresponding to the first DC voltage and a respective second subset of switches configured to operate at a second voltage level corresponding to the second DC voltage.

2. The circuit of claim 1, wherein the respective first subset of the first set of switches includes a first switch and the respective first subset of the second set of switches includes a second switch; and
wherein the circuit is configured to provide a first voltage, corresponding to the first DC voltage, at the output interface in accordance with the first switch of the respective first subset of the first set of switches being active and the respective second subset of the second set of switches being active, wherein the first voltage has a first polarity.

3. The circuit of claim 2, wherein the circuit is configured to provide a second voltage, corresponding to the first DC voltage, at the output interface in accordance with the second switch of the respective first subset of the second set of switches being active and the respective second subset of the first set of switches being active, wherein the second voltage has a second polarity that is opposite to the first polarity.

4. The circuit of claim 1, wherein the second power source comprises a capacitor coupled to the first half-bridge power stage via a third switch and coupled to the second half-bridge power stage via a fourth switch.

5. The circuit of claim 4, wherein the respective second subset of the first set of switches includes a fifth switch and a sixth switch, and the respective second subset of the second set of switches includes a seventh switch and an eighth switch; and
wherein the circuit is configured to provide a third voltage, corresponding to the second DC voltage, at the output interface in accordance with the circuit being in a first state in which the first, the fourth and the seventh switches are active, wherein the third voltage has a first polarity.

6. The circuit of claim 5, wherein, while in the first state, the circuit charges the capacitor of the second power source.

7. The circuit of claim 5, wherein the circuit is configured to provide a fourth voltage, corresponding to the second DC voltage, at the output interface in accordance with the circuit being in a second state in which the second, the third, and the fifth switches are active, wherein the fourth voltage has a second polarity that is opposite to the first polarity.

8. The circuit of claim 7, wherein, while in the second state, the circuit charges the capacitor of the second power source.

9. The circuit of claim 5, wherein the circuit is configured to provide a fifth voltage, corresponding to the second DC voltage, at the output interface in accordance with the circuit being in a third state in which the third, fifth, seventh, and eighth switches are active, wherein the fifth voltage has the first polarity.

10. The circuit of claim 9, wherein, while in the third state, the circuit discharges the capacitor of the second power source.

11. The circuit of claim 5, wherein the circuit is configured to provide a sixth voltage, corresponding to the second DC voltage, at the output interface in accordance with the circuit being in a fourth state in which the fourth, fifth, sixth, and seventh switches are active, wherein the sixth voltage has a second polarity that is opposite to the first polarity.

12. The circuit of claim 11, wherein, while in the fourth state, the circuit discharges the capacitor of the second power source.

13. The circuit of claim 5, wherein the circuit is configured to provide a seventh voltage at the output interface in accordance with the circuit being in a fifth state.

14. The circuit of claim 13, wherein the seventh voltage is a zero voltage.

15. The circuit of claim 13, wherein, in the fifth state, the first and second switches are active such that two terminals of the output interface are coupled to the first power source.

16. The circuit of claim 13, wherein, in the fifth state, the third, fourth, fifth, and seventh switches are active such that two terminals of the output interface are coupled to the second power source.

17. The circuit of claim 13, wherein, in the fifth state, the fifth, sixth, seventh, and eighth switches are active such that two terminals of the output interface are coupled to an electrical ground.

18. (canceled)

19. The circuit of claim 1, wherein the first half-bridge power stage and the second half-bridge power stage are coupled to different terminals of the output interface and comprise a same configuration of switches.

20. (canceled)

21. A method of operating an amplifier, comprising:
providing a first half-bridge power stage including a first set of switches;
providing a second half-bridge power stage including a second set of switches;
providing a first power source coupled to the first and second half-bridge power stages and configured to supply a first direct current (DC) voltage;
providing a second power source coupled to the first and second half-bridge power stages and configured to supply a second DC voltage; and
providing an output interface coupled to the first and second half-bridge power stages and configured to couple to a speaker load, wherein:
the first and second half-bridge power stages are configured to generate a five-level differential signal for driving the speaker load; and
each set of the first set of switches and the second set of switches includes a respective first subset of switches configured to operate at a first voltage level corresponding to the first DC voltage and a respective second subset of switches configured to operate at a second voltage level corresponding to the second DC voltage.

22. An electronic device, comprising:
a speaker component;
an amplification circuit coupled to the speaker component, the amplification circuit comprising:
a first half-bridge power stage including a first set of switches;
a second half-bridge power stage including a second set of switches;
a first power source coupled to the first and second half-bridge power stages and configured to supply a first direct current (DC) voltage;
a second power source coupled to the first and second half-bridge power stages and configured to supply a second DC voltage; and
an output interface coupled to the first and second half-bridge power stages and configured to couple to the speaker component, wherein:
the first and second half-bridge power stages are configured to generate a five-level differential signal for driving the speaker component; and
each set of the first set of switches and the second set of switches includes a respective first subset of switches configured to operate at a first voltage level corresponding to the first DC voltage and a respective second subset of switches configured to operate at a second voltage level corresponding to the second DC voltage.
